(19) United States
(12) Patent Application Publication
(10) Pub. No.: US 2024/0172521 A1
(43) Pub. Date: May 23, 2024

(54) Semiconductor Device And Electronic Apparatus

(71) Applicant: Semiconductor Energy Laboratory Co., Ltd., Kanagawa-kan (JP)

(72) Inventors: Hajime Kimura, Atsugi, Kanagawa (JP); Yshiaki OIKAWA, Atsugi, Kanagawa (JP)

(73) Assignee: Semiconductor Energy Laboratory Co., Ltd., Kanagawa-kan (JP)

(21) Appl. No.: 18/283,079

(22) PCT Filed: Mar. 11, 2022
(86) PCT No.: PCT/IB2022/052185

§ 371 Date: Sep. 20, 2023

(30) Foreign Application Priority Data
Mar. 25, 2021 (JP) 2021-051402
Apr. 25, 2021 (JP) 2021-077295

(51) Int. Cl. H10K 59/65; G09G 3/3233; H04N 25/77; H04N 25/78

(52) U.S. Cl. CPC H10K 59/65; G09G 3/3233; H04N 25/77; G09G 2300/0452; G09G 2300/0842; G09G 2320/0626; H04N 25/78

(57) ABSTRACT

A novel semiconductor device is provided. The semiconductor device includes an imaging unit and a display unit and includes a first layer, a second layer over the first layer, and a third layer over the second layer. The first layer includes a plurality of photoelectric conversion elements, the second layer includes a plurality of display pixel circuits, and the third layer includes a plurality of display elements. The imaging unit includes the plurality of photoelectric conversion elements. The display unit includes the plurality of display pixel circuits and the plurality of display elements and one of the plurality of display pixel circuits is electrically connected to one of the plurality of display elements.

### TECHNICAL FIELD

One embodiment of the present invention relates to a semiconductor device and an electronic apparatus.

Note that one embodiment of the present invention is not limited to the above technical field. Examples of the technical field of one embodiment of the present invention disclosed in this specification and the like include a semiconductor device, a display apparatus, a light-emitting apparatus, a power storage device, a storage device, an electronic apparatus, a lighting device, an input device, an input/output device, a driving method thereof, and a manufacturing method thereof.

In this specification and the like, a semiconductor device refers to a device that utilizes semiconductor characteristics, and means a circuit including a semiconductor element (a transistor, a diode, a photodiode, or the like), a device including the circuit, and the like. In addition, the semiconductor device also refers to all devices that can function by utilizing semiconductor characteristics. For example, an integrated circuit, a chip including an integrated circuit, and an electronic component including a chip in a package are examples of the semiconductor device. Moreover, a storage device, a display apparatus, a light-emitting apparatus, a lighting device, an electronic apparatus, and the like themselves may be semiconductor devices and may each include a semiconductor device.

### BACKGROUND ART

In recent years, higher resolution of display apparatuses have been desired. For example, apparatuses for virtual reality (VR), augmented reality (AR), substitutional reality (SR), or mixed reality (MR), and the like are given as apparatuses requiring high-resolution display apparatuses and have been actively developed in recent years. Display apparatuses used as these apparatuses are required to be downsized as well as to increase resolution.

Typical examples of the display apparatuses include a liquid crystal display apparatus; a light-emitting apparatus including a light-emitting element such as an organic EL (Electro-Luminescence) element or a light-emitting diode (LED); and electronic paper performing display by an electrophoretic method or the like.

For example, the basic structure of an organic EL element is a structure in which a layer containing a light-emitting organic compound is interposed between a pair of electrodes. By applying voltage to this element, light emission can be obtained from the light-emitting organic compound. A display apparatus using such an organic EL element does not need a backlight that is necessary for a liquid crystal display apparatus and the like; thus, a thin, lightweight, high-contrast, and low-power display apparatus can be achieved. Patent Document 1, for example, discloses an example of a display apparatus using an organic EL element.

### REFERENCE

### Patent Document

[Patent Document 1] Japanese Published Patent Application No. 2002-324673

### SUMMARY OF THE INVENTION

### Problems to be Solved by the Invention

A small and high-resolution display apparatus is also used as an electrical viewfinder (EVF) in a mirrorless camera or the like. A mirrorless camera including an EVF has advantages as follows: an image projected onto an imaging unit (image sensor) matches a captured image; necessary information can be displayed on a display apparatus; and the like.

Meanwhile, the mirrorless camera including an EVF generally has a problem in that a time lag (signal delay) between taking an image and displaying the image easily occurs because a signal is read out from an image sensor and then a captured image is displayed on the EVF. In particular, when a moving subject is photographed, proper photographing timing is not gained and having an accurate framework is difficult, which is a problem.

An object of one embodiment of the present invention is to provide a semiconductor device or display apparatus with a small time lag between taking an image of a subject and displaying the image. Another object of one embodiment of the present invention is to provide a downsized semiconductor device or display apparatus. Another object of one embodiment of the present invention is to provide a semiconductor device or display apparatus in which high color reproducibility is achieved. Another object of one embodiment of the present invention is to provide a high-resolution semiconductor device or display apparatus. Another object of one embodiment of the present invention is to provide a highly reliable semiconductor device or display apparatus. Another object of one embodiment of the present invention is to provide a semiconductor device or display apparatus with reduced power consumption. Another object of one embodiment of the present invention is to provide a novel semiconductor device or display apparatus.

Note that the description of these objects does not preclude the existence of other objects. Note that one embodiment of the present invention does not have to achieve all the objects. Objects other than these can be derived from the description of the specification, the drawings, the claims, and the like.

### Means for Solving the Problems

One embodiment of the present invention is a semiconductor device including an imaging unit and a display unit; the imaging unit includes a plurality of photoelectron conversion elements arranged in a matrix; the display unit includes a plurality of display pixel circuits arranged in a matrix and a plurality of display elements arranged in a matrix; the plurality of photoelectric conversion elements are provided in a first layer; the plurality of display pixel circuits are provided in a second layer over the first layer; the plurality of display elements are provided in a third layer over the second layer; and one of the plurality of display pixel circuits is electrically connected to one of the plurality of display elements.

The above semiconductor device may have a function of obtaining imaging data using the plurality of photoelectric conversion elements and a function of supplying the image data of all columns to the display unit row by row. Furthermore, the semiconductor device may have a function of adjusting a voltage of the imaging data and supplying the imaging data to the display unit.

The above display pixel circuit has a function of controlling emission luminance of the display element, for example. Any of a variety of elements can be used as the display element. An organic EL element can be used as the display element, for example.

The display pixel circuit may include a transistor including an oxide semiconductor. The first layer and the second layer may be connected to each other, for example, by an adhesive layer and a bump.

Another embodiment of the present invention is an electronic apparatus including the above semiconductor device and at least one of an antenna, a battery, and a microphone. Another embodiment of the present invention is an electronic apparatus including the above semiconductor device and at least one of a mounting unit, a lens, a main body, and a cable, and has a function of obtaining user information through the lens.

### Effect of the Invention

According to one embodiment of the present invention, a semiconductor device or display apparatus with a small time lag between taking an image of a subject and displaying the image can be provided. Alternatively, a downsized semiconductor device or display apparatus can be provided. Alternatively, a semiconductor device or display apparatus in which high color reproducibility is achieved can be provided. Alternatively, a high-resolution semiconductor device or display apparatus can be provided. Alternatively, a highly reliable semiconductor device or display apparatus can be provided. Alternatively, a semiconductor device or display apparatus with reduced power consumption can be provided. Alternatively, a novel semiconductor device or display apparatus can be provided.

Note that the description of these effects does not preclude the existence of other effects. Note that one embodiment of the present invention does not need to have all the effects. Effects other than these can be derived from the description of the specification, the drawings, the claims, and the like.

### BRIEF DESCRIPTION OF THE DRAWINGS

FIG. 1A and FIG. 1B are perspective views of a semiconductor device.

FIG. 2 is a perspective view of a semiconductor device.

FIG. 3 is a block diagram of a semiconductor device.

FIG. 4A and FIG. 4B are diagrams illustrating a circuit configuration example of an imaging pixel 12.

FIG. 5A and FIG. 5B1 to FIG. 5B7 are diagrams illustrating structure examples of a layer 20.

FIG. 6A to FIG. 6D are diagrams illustrating circuit configuration examples of a display pixel 230.

FIG. 7A to FIG. 7D are diagrams illustrating structure examples of a light-emitting element.

FIG. 8A to FIG. 8D are diagrams illustrating structure examples of a display apparatus.

FIG. 9A to FIG. 9D are diagrams illustrating structure examples of a display apparatus.

FIG. 10 is a cross-sectional view illustrating a structure example of a semiconductor device.

FIG. 11A and FIG. 11B are diagrams illustrating an application example of a semiconductor device.

FIG. 12A and FIG. 12B are perspective views of a semiconductor device.

FIG. 13 is a perspective view of a semiconductor device.

FIG. 14 is a cross-sectional view illustrating a structure example of a semiconductor device.

FIG. 15A and FIG. 15B are perspective views of a semiconductor device.

FIG. 16 is a perspective view of a semiconductor device.

FIG. 17A is a diagram illustrating a circuit configuration example of a display pixel.

FIG. 17B is a diagram illustrating a structure example of a semiconductor device.

FIG. 18 is a cross-sectional view illustrating a structure example of a semiconductor device.

FIG. 19 is a perspective view of a semiconductor device.

FIG. 20 is a cross-sectional view illustrating a structure example of a semiconductor device.

FIG. 21 is a perspective view of a semiconductor device.

FIG. 22 is a perspective view illustrating a structure example of a semiconductor device.

FIG. 23 is a diagram illustrating a structure example of a semiconductor device.

FIG. 24 is a perspective view illustrating a structure example of a semiconductor device.

FIG. 25 is a diagram illustrating a structure example of a semiconductor device.

FIG. 26 is a diagram illustrating a structure example of a semiconductor device.

FIG. 27 is a perspective view illustrating a structure example of a semiconductor device.

FIG. 28 is a diagram illustrating a structure example of a semiconductor device.

FIG. 29 is a perspective view illustrating a structure example of a semiconductor device.

FIG. 30 is a diagram illustrating a structure example of a semiconductor device.

FIG. 31 is a perspective view illustrating a structure example of a semiconductor device.

FIG. 32 is a diagram illustrating a structure example of a semiconductor device.

FIG. 33 is a diagram illustrating a structure example of a semiconductor device.

FIG. 34 is a diagram illustrating a structure example of a semiconductor device.

FIG. 35 is a diagram illustrating a structure example of a semiconductor device.

FIG. 36A is a top view illustrating a structure example of a transistor. FIG. 36B and FIG. 36C are cross-sectional views illustrating the structure example of the transistor.

FIG. 37A is a table showing classifications of crystal structures of IGZO. FIG. 37B is a graph showing an XRD spectrum of a CAAC-IGZO film. FIG. 37C is an image showing nanobeam electron diffraction patterns of a CAAC-IGZO film.

FIG. 38A to FIG. 38F are each a diagram illustrating an example of an electronic apparatus.

FIG. 39A to FIG. 39F are each a diagram illustrating an example of an electronic apparatus.

### MODE FOR CARRYING OUT THE INVENTION

Hereinafter, embodiments are described with reference to the drawings. Note that the embodiments can be implemented in many different modes, and it will be readily understood by those skilled in the art that modes and details thereof can be changed in various ways without departing from the spirit and scope thereof. Thus, the present invention should not be construed as being limited to the following description of the embodiments.

In the case where there is description “X and Y are connected” in this specification and the like, the case where X and Y are electrically connected, the case where X and Y are functionally connected, and the case where X and Y are directly connected are regarded as being disclosed in this specification and the like. Accordingly, without being limited to a predetermined connection relationship, for example, a connection relationship shown in drawings or texts, a connection relationship other than one shown in drawings or texts is regarded as being disclosed in the drawings or the texts. Each of X and Y denotes an object (e.g., a device, an element, a circuit, a wiring, an electrode, a terminal, a conductive film, or a layer).

For example, in the case where X and Y are electrically connected, one or more elements that allow electrical connection between X and Y (e.g., a switch, a transistor, a capacitor, an inductor, a resistor, a diode, a display device, a light-emitting device, and a load) can be connected between X and Y. Note that a switch is controlled to be in an on state or an off state. That is, a switch has a function of controlling whether or not current flows by being in a conduction state (on state) or a non-conduction state (off state).

For example, in the case where X and Y are functionally connected, one or more circuits that allow functional connection between X and Y (e.g., a logic circuit (an inverter, a NAND circuit, a NOR circuit, or the like); a signal converter circuit (a digital-analog converter circuit, an analog-digital converter circuit, a gamma correction circuit, or the like); a potential level converter circuit (a power supply circuit (a step-up circuit, a step-down circuit, or the like), a level shifter circuit for changing the potential level of a signal, or the like); a voltage source; a current source; a switching circuit; an amplifier circuit (a circuit that can increase signal amplitude, the amount of current, or the like, an operational amplifier, a differential amplifier circuit, a source follower circuit, a buffer circuit, or the like); a signal generation circuit; a storage circuit; a control circuit; or the like) can be connected between X and Y. Note that for example, even when another circuit is interposed between X and Y, X and Y are functionally connected when a signal output from X is transmitted to Y.

Note that an explicit description that X and Y are electrically connected includes the case where X and Y are electrically connected (i.e., the case where X and Y are connected with another element or another circuit interposed therebetween) and the case where X and Y are directly connected (i.e., the case where X and Y are connected without another element or another circuit interposed therebetween).

It can be expressed as, for example, “X, Y, a source (or a first terminal or the like) of a transistor, and a drain (or a second terminal or the like) of the transistor are electrically connected to one another, and X, the source (or the first terminal or the like) of the transistor, the drain (or the second terminal or the like) of the transistor, and Y are electrically connected to one another in this order”. Alternatively, it can be expressed as “a source (or a first terminal or the like) of a transistor is electrically connected to X, a drain (or a second terminal or the like) of the transistor is electrically connected to Y, and X, the source (or the first terminal or the like) of the transistor, the drain (or the second terminal or the like) of the transistor, and Y are electrically connected to one another in this order”. Alternatively, it can be expressed as “X is electrically connected to Y through a source (or a first terminal or the like) and a drain (or a second terminal or the like) of a transistor, and X, the source (or the first terminal or the like) of the transistor, the drain (or the second terminal or the like) of the transistor, and Y are provided in this connection order”. When the connection order in a circuit configuration is defined by an expression similar to the above examples, a source (or a first terminal or the like) and a drain (or a second terminal or the like) of a transistor can be distinguished from each other to specify the technical scope. Note that these expressions are examples and the expression is not limited to these expressions. Here, X and Y each denote an object (e.g., a device, an element, a circuit, a wiring, an electrode, a terminal, a conductive film, or a layer).

Note that even when a circuit diagram shows that independent components are electrically connected to each other, one component has functions of a plurality of components in some cases. For example, when part of a wiring also functions as an electrode, one conductive film has functions of both components: a function of the wiring and a function of the electrode. Thus, electrical connection in this specification includes, in its category, such a case where one conductive film has functions of a plurality of components.

In this specification and the like, a “capacitor” can be, for example, a circuit element having an electrostatic capacitance value higher than 0 F, a region of a wiring having an electrostatic capacitance value higher than 0 F, parasitic capacitance, or gate capacitance of a transistor. Therefore, in this specification and the like, a “capacitor” includes not only a circuit element that has a pair of electrodes and a dielectric between the electrodes, but also parasitic capacitance generated between wirings, gate capacitance generated between a gate and one of a source and a drain of a transistor, and the like. The terms “capacitor”, “parasitic capacitance”, “gate capacitance”, and the like can be replaced with the term “capacitance” and the like; conversely, the term “capacitance” can be replaced with the terms “capacitor”, “parasitic capacitance”, “gate capacitance”, and the like. The term “a pair of electrodes” of a “capacitance” can be replaced with “a pair of conductors”, “a pair of conductive regions”, “a pair of regions”, and the like. Note that the electrostatic capacitance value can be higher than or equal to 0.05 fF and lower than or equal to 10 pF, for example. As another example, the electrostatic capacitance value may be higher than or equal to 1 pF and lower than or equal to 10 pF.

In this specification and the like, a transistor includes three terminals called a gate, a source, and a drain. The gate is a control terminal for controlling the conduction state of the transistor. Two terminals functioning as the source and the drain are input/output terminals of the transistor. One of the two input/output terminals serves as the source and the other serves as the drain depending on the conductivity type (n-channel type or p-channel type) of the transistor and the levels of potentials applied to the three terminals of the transistor. Thus, the terms “source” and “drain” can be replaced with each other in this specification and the like. Furthermore, in this specification and the like, expressions “one of a source and a drain” (or a first electrode or a first terminal) and “the other of the source and the drain” (or a second electrode or a second terminal) are used in the description of the connection relation of a transistor. Depending on the transistor structure, a transistor may include a back gate in addition to the above three terminals. In that case, in this specification and the like, one of the gate and the back gate of the transistor may be referred to as a first gate and the other of the gate and the back gate of the transistor may be referred to as a second gate. Moreover, the terms “gate” and “back gate” can be replaced with each other in one transistor in some cases. In the case where a transistor includes three or more gates, the gates may be referred to as a first gate, a second gate, and a third gate, for example, in this specification and the like.

In this specification and the like, “node” can be referred to as a terminal, a wiring, an electrode, a conductive layer, a conductor, an impurity region, or the like depending on a circuit structure, a device structure, or the like. Furthermore, a terminal, a wiring, or the like can be referred to as “node”.

In addition, ordinal numbers such as “first”, “second”, and “third” in this specification and the like are used to avoid confusion among components. Thus, the ordinal numbers do not limit the number of components. Furthermore, the ordinal numbers do not limit the order of components. For example, a “first” component in one embodiment in this specification and the like can be referred to as a “second” component in other embodiments, the SCOPE OF CLAIMS, or the like. Furthermore, for example, a “first” component in one embodiment in this specification and the like can be omitted in other embodiments, the SCOPE OF CLAIMS, or the like.

In this specification and the like, terms for describing arrangement, such as “over”, “under”, “above”, and “below” are sometimes used as convenience to describe the positional relation between components with reference to drawings. Furthermore, the positional relation between components is changed as appropriate in accordance with a direction in which each component is described. Thus, the positional relation is not limited to the terms described in the specification and the like, and can be described with another term as appropriate depending on the situation. For example, the expression “an insulator positioned over (on) a top surface of a conductor” can be replaced with the expression “an insulator positioned under (on) a bottom surface of a conductor” when the direction of a drawing showing these components is rotated by 180°.

The term “over” or “under” does not necessarily mean that a component is placed directly over or directly under and directly in contact with another component. For example, the expression “electrode B over insulating layer A” does not necessarily mean that the electrode B is formed on and in direct contact with the insulating layer A, and does not exclude the case where another component is provided between the insulating layer A and the electrode B.

In addition, the term “overlap”, for example, in this specification and the like does not limit a state such as the stacking order of components. For example, the expression “electrode B overlapping with insulating layer A” does not necessarily mean the state where “electrode B is formed over insulating layer A”, and does not exclude the state where “electrode B is formed under insulating layer A” and the state where “electrode B is formed on the right side (or the left side) of insulating layer A”.

The term “adjacent” or “proximity” in this specification and the like does not necessarily mean that a component is directly in contact with another component. For example, the expression “electrode B adjacent to insulating layer A” does not necessarily mean that the electrode B is formed in direct contact with the insulating layer A and does not exclude the case where another component is provided between the insulating layer A and the electrode B.

In this specification and the like, the terms “film”, “layer”, and the like can be interchanged with each other depending on the situation. For example, the term “conductive layer” can be changed into the term “conductive film” in some cases. As another example, the term “insulating film” can be changed into the term “insulating layer” in some cases. Alternatively, the term “film,” “layer,” or the like is not used and can be interchanged with another term depending on the case or the situation. For example, the term “conductive layer” or “conductive film” can be changed into the term “conductor” in some cases. Furthermore, the term “conductor” can be changed into the term “conductive layer” or “conductive film” in some cases. For example, the term “insulating layer” or “insulating film” can be changed into the term “insulator” in some cases. Furthermore, the term “insulator” can be changed into the term “insulating layer” or “insulating film” in some cases.

In addition, in this specification and the like, the term such as “electrode,” “wiring,” or “terminal” does not limit the function of a component. For example, an “electrode” is used as part of a “wiring” in some cases, and vice versa. Furthermore, the term “electrode” or “wiring” also includes the case where a plurality of “electrodes” or “wirings” are formed in an integrated manner, for example. For example, a “terminal” is used as part of a “wiring” or an “electrode” in some cases, and vice versa. Furthermore, the term “terminal” also includes the case where a plurality of “electrodes”, “wirings”, “terminals”, or the like are formed in an integrated manner, for example. Therefore, for example, an “electrode” can be part of a “wiring” or a “terminal”, and a “terminal” can be part of a “wiring” or an “electrode”. Moreover, the term “electrode”, “wiring”, “terminal”, or the like is sometimes replaced with the term “region”, for example.

In addition, in this specification and the like, the term such as “wiring,” “signal line,” or “power supply line” can be interchanged with each other depending on the case or the situation. For example, the term “wiring” can be changed into the term “signal line” in some cases. Furthermore, for example, the term “wiring” can be changed into the term “power supply line” or the like in some cases. Conversely, the term such as “signal line” or “power supply line” can be changed into the term “wiring” in some cases. The term “power supply line” or the like can be changed into the term “signal line” or the like in some cases. Conversely, the term “signal line” or the like can be changed into the term “power supply line” or the like in some cases. Moreover, the term “potential” that is applied to a wiring can be sometimes changed into the term such as “signal” depending on the case or the situation. Conversely, the term “signal” or the like can be changed into the term “potential” in some cases.

In this specification, “parallel” indicates a state where two straight lines are placed at an angle greater than or equal to −10° and less than or equal to 10°. Accordingly, the case where the angle is greater than or equal to −5° and less than or equal to 5° is also included. In addition, “approximately parallel” or “substantially parallel” indicates a state where two straight lines are placed at an angle greater than or equal to −30° and less than or equal to 30°. In addition, “perpendicular” indicates a state where two straight lines are placed at an angle greater than or equal to 80° and less than or equal to 100°. Accordingly, the case where the angle is greater than or equal to 850 and less than or equal to 950 is also included. Furthermore, “approximately perpendicular” or “substantially perpendicular” indicates a state where two straight lines are placed at an angle greater than or equal to 60° and less than or equal to 120°.

Note that in this specification and the like, the terms “identical”, “the same”, “equal”, “uniform”, or the like (including synonyms thereof) used in describing calculation values and measurement values contain an error of ±20% unless otherwise specified.

Embodiments described in this specification are described with reference to the drawings. Note that the embodiments can be implemented in many different modes, and it will be readily understood by those skilled in the art that the modes and details can be changed in various ways without departing from the spirit and scope thereof. Therefore, the present invention should not be construed as being limited to the description in the embodiments. Note that in the structures of the invention in the embodiments, the same reference numerals are used in common for the same units or units having similar functions in different drawings, and repeated description thereof is omitted in some cases. Furthermore, the same hatch pattern is used as the units having similar functions, and the units are not especially denoted by reference numerals in some cases. Moreover, some components are omitted in a perspective view, a top view, and the like for easy understanding of the diagrams in some cases.

In addition, in the drawings and the like of this specification, the size, the layer thickness, or the region is exaggerated for clarity in some cases. Therefore, embodiments of the present invention are not limited to the size, aspect ratio, and the like illustrated in the drawings. Note that the drawings schematically illustrate ideal examples, and embodiments of the present invention are not limited to shapes, values, and the like illustrated in the drawings. For example, variation in signal, voltage, or current due to noise or variation in signal, voltage, or current due to difference in timing can be included.

In addition, in the drawings and the like of this specification, arrows indicating the X direction, the Y direction, and the Z direction are illustrated in some cases. In this specification and the like, the “X direction” is a direction along the X-axis, and the forward direction and the reverse direction are not distinguished in some cases, unless otherwise specified. The same applies to the “Y direction” and the “Z direction”. The X direction, the Y direction, and the Z direction are directions intersecting with each other. More specifically, the X direction, the Y direction, and the Z direction are directions orthogonal to each other. In this specification and the like, one of the X direction, the Y direction, and the Z direction is referred to as a “first direction” in some cases. Another one of the directions is referred to as a “second direction” in some cases. The remaining one of the directions is referred to as a “third direction” in some cases.

In this specification and the like, when a plurality of components are denoted by the same reference numerals, and in particular need to be distinguished from each other, an identification sign such as “A”, “b”, “_1”, “[n]”, or “[m,n]” are sometimes added to the reference numerals.

### Embodiment 1

A semiconductor device of one embodiment of the present invention is described. Note that the semiconductor device of one embodiment of the present invention has a function of operating as an imaging device and a function of operating as a display apparatus.

### <Structure Example of Semiconductor Device 100A>

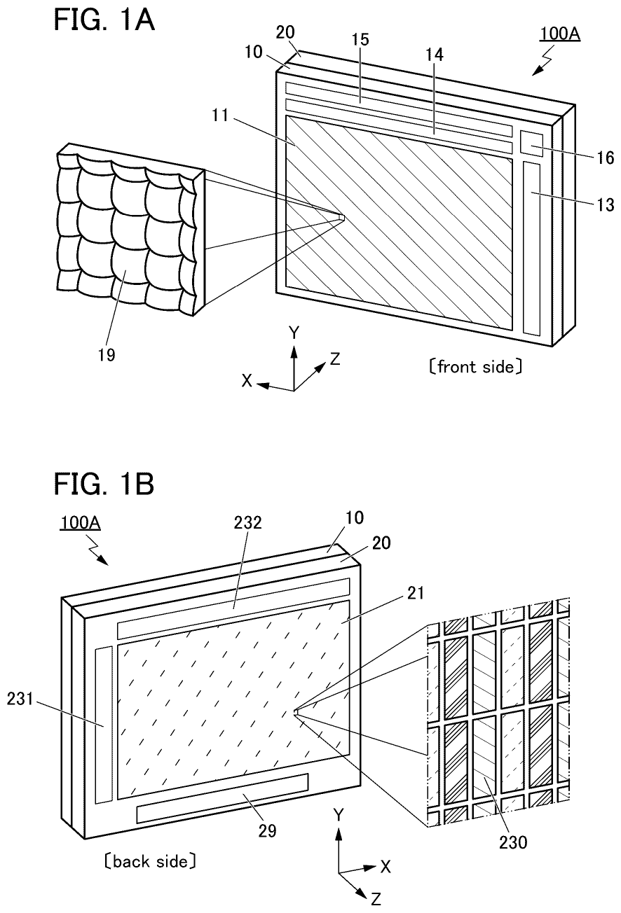

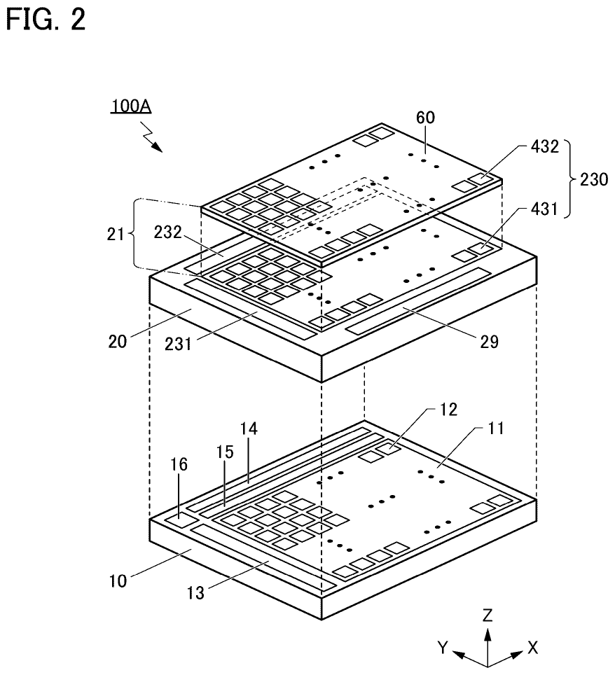

FIG. 1 and FIG. 2 are perspective views of a semiconductor device 100A of one embodiment of the present invention. FIG. 1A is a perspective view of the front side of the semiconductor device 100A and FIG. 1B is a perspective view of the back side of the semiconductor device 100A. In FIG. 2, a layer 10 and a layer 20 and the like are separated and illustrated from each other for easy understanding of a structure of the semiconductor device 100A.

The semiconductor device 100A includes the layer 10 and the layer 20. The layer 10 and the layer 20 overlap with each other. Note that in FIG. 1 and the like, a direction in which the layer 10 and the layer 20 overlap with each other is the Z direction.

The layer 10 includes an imaging unit 11, a first driver circuit unit 13, a second driver circuit unit 14, a reading circuit unit 15, and a control circuit unit 16. Furthermore, the layer 10 includes a microlens array including a plurality of microlenses 19 and overlapping with the imaging unit 11. The microlens 19 is provided on the side opposite to the layer 20 with the layer 10 therebetween. The imaging unit 11 includes a plurality of imaging pixels 12 arranged in a matrix.

The layer 20 includes a display unit 21, a first driver circuit unit 231, a second driver circuit unit 232, and an input/output terminal unit 29. The display unit 21 includes a plurality of display pixels 230 arranged in a matrix. Furthermore, a layer 60 is provided to overlap with a plurality of display pixel circuits 431 arranged in a matrix. The layer 60 includes a plurality of display elements 432 arranged in a matrix.

One display pixel circuit 431 and one display element 432 constitute one display pixel 230. Accordingly, the display unit 21 includes a plurality of display pixels 230 arranged in a matrix.

As an example of the display element 432, an EL element (an EL element including an organic material and an inorganic material, an organic EL element, or an inorganic EL element), an LED (a white LED, a red LED, a green LED, a blue LED, or the like), a micro-LED, a QLED (Quantum-dot Light Emitting Diode), a transistor (a transistor that emits light depending on current), an electron-emissive element, a liquid crystal element, electronic ink, an electrophoretic element, a grating light valve (GLV), a plasma display panel (PDP), a display element using MEMS (micro electro mechanical systems), a digital micromirror device (DMD), a DMS (digital micro shutter), an IMOD (interferometric modulation) element, a shutter-type MEMS display element, an optical-interference-type MEMS display element, an electrowetting element, a piezoelectric ceramic display, a display element using a carbon nanotube, or the like, which may include display media whose contrast, luminance, reflectivity, transmittance, or the like is changed by electric or magnetic action can be given.

The layer 10 has a function of converting a subject image projected onto the imaging unit 11 into an electric signal. The layer 20 has a function of displaying a video corresponding to an inputted electric signal on the display unit 21. Since the layer 10 and the layer 20 are provided to overlap each other in the semiconductor device 100A of one embodiment of the present invention, a subject image taken by the layer 10 can be immediately displayed on the display unit 21 included in the layer 20. That is, a time lag between taking an image of a subject and displaying the image can be reduced. One embodiment of the present invention has an excellent effect when a moving subject is photographed.

The semiconductor device 100A is supplied with electricity, signals required to operate the imaging unit 11, signals required to operate the display unit 21, and the like through the input/output terminal unit 29. Furthermore, the semiconductor device 100A can output imaging data (also referred to as “image data”) obtained by the layer 10 to the outside through the input/output terminal unit 29. In addition, the semiconductor device 100A can display an image corresponding to a video signal supplied through the input/output terminal unit 29 on the display unit 21.

Note that at least part of circuits or the like included in the layer 10 may be provided in the layer 20. At least part of circuits or the like included in the layer 20 may be provided in the layer 10.

### <Structure Example of Layer 10>

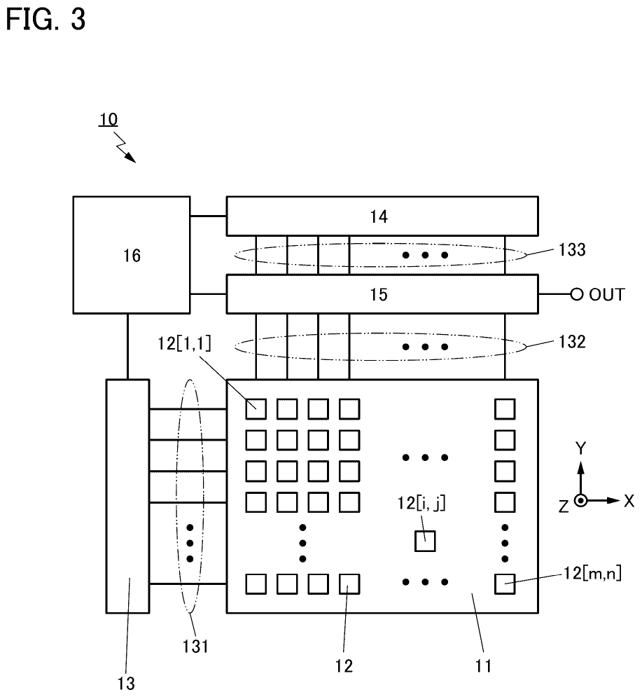

FIG. 3 illustrates a block diagram illustrating a structure of the layer 10. As described above, the layer 10 includes the imaging unit 11, the first driver circuit unit 13, the second driver circuit unit 14, the reading circuit unit 15, and the control circuit unit 16. Note that the first driver circuit unit 13, the second driver circuit unit 14, the reading circuit unit 15, and the control circuit unit 16 are collectively referred to as a “functional circuit” in some cases. Any of a variety of circuits such as a shift register, a level shifter, an inverter, a latch, an analog switch, or a logic circuit can be used as a functional circuit.

Transistors used in the imaging unit 11 and the functional circuit which are provided in the layer 10 can be either n-channel transistors or p-channel transistors. Both n-channel transistors and p-channel transistors can be used. A CMOS structure in which n-channel transistors and p-channel transistors are combined may be employed for the imaging unit 11 and the functional circuit.

The imaging unit 11 includes the imaging pixels 12 arranged in a matrix of m rows and n columns (each of m and n is an integer greater than or equal to 1). The imaging unit 11 is electrically connected to the first driver circuit unit 13 through a plurality of wirings 131. The imaging unit 11 is electrically connected to the reading circuit unit 15 through a plurality of wirings 132. The reading circuit unit 15 is electrically connected to the second driver circuit unit 14 through a plurality of wirings 133. For example, the imaging pixels 12 in the i-th row (here, i is a given number; in this embodiment and the like, i is an integer greater than or equal to 1 and less than or equal to m) are electrically connected to the first driver circuit unit 13 through the i-th wiring 131. The imaging pixels 12 in the j-th column (here, j is a given number; in this embodiment and the like, j is an integer greater than or equal to 1 and less than or equal to n) are electrically connected to the reading circuit unit 15 through the j-th wiring 132.

In FIG. 3, the imaging pixel 12 placed in the first row and the first column is denoted as the imaging pixel 12[1, 1], and the imaging pixel 12 placed in the m-th row and the n-th column is denoted as the imaging pixel 12[m, n]. The imaging pixel 12 placed in the i-th row and the j-th column is denoted as the imaging pixel 12[i,j].

Note that wirings connected to one imaging pixel 12 are not limited to the wiring 131 and the wiring 132. A wiring other than the wiring 131 and the wiring 132 may be connected to the imaging pixel 12.

The pixel density (also referred to as “resolution”) of the imaging unit 11 is preferably higher than or equal to 100 ppi and lower than or equal to 10000 ppi, further preferably higher than or equal to 1000 ppi and lower than or equal to 10000 ppi. For example, the pixel density can be higher than or equal to 2000 ppi and lower than or equal to 6000 ppi, or higher than or equal to 3000 ppi and lower than or equal to 5000 ppi.

Note that there is no particular limitation on the aspect ratio of the imaging unit 11. The imaging unit 11 in the semiconductor device 100A can have various aspect ratios, such as 1:1 (a square), 4:3, 16:9, and 16:10.

The diagonal size of the imaging unit 11 is at least greater than or equal to 0.1 inches and less than or equal to 100 inches and may be greater than or equal to 100 inches.

The control circuit unit 16 has a function of controlling the operation of a circuit included in the layer 10. The first driver circuit unit 13 has a function of selecting the imaging pixels 12 row by row. The imaging pixels 12 in the row selected by the first driver circuit unit 13 output imaging data to the reading circuit unit 15 through the wirings 132.

The reading circuit unit 15 holds imaging data supplied from the imaging pixels 12 in each column, and performs noise removal and the like. As the noise removal, for example, CDS (Correlated Double Sampling) treatment may be performed. The reading circuit unit 15 may have a function of amplifying imaging data, an AD conversion function of imaging data, or the like.

The second driver circuit unit 14 has functions of sequentially selecting imaging data stored in the reading circuit unit 15, and outputting the imaging data from an output terminal OUT to the outside.

### <Circuit Configuration Example of Imaging Pixel 12>

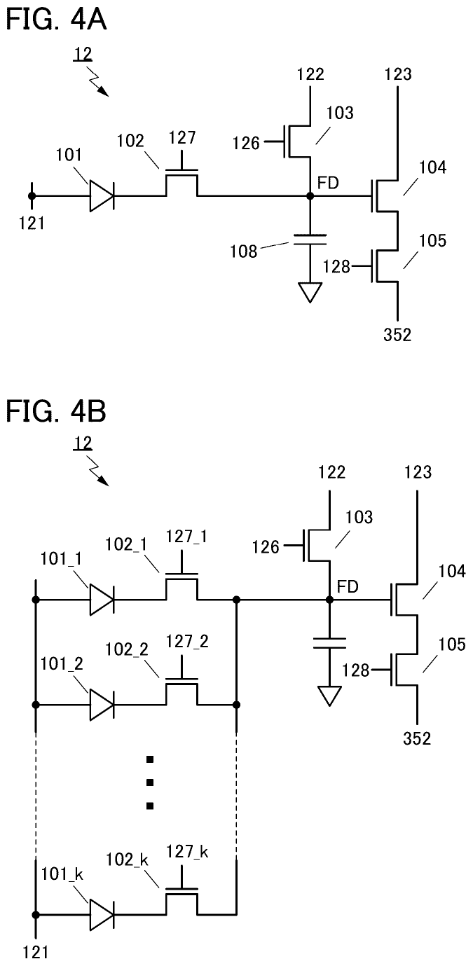

FIG. 4A is a circuit diagram illustrating a circuit configuration example of the imaging pixel 12. The imaging pixel 12 includes a photoelectric conversion device 101 (also referred to as a “photoelectric conversion element” or “imaging element”), a transistor 102, a transistor 103, a transistor 104, a transistor 105, and a capacitor 108. Note that the capacitor 108 is not necessarily provided. In this specification and the like, at least one of a configuration in which the photoelectric conversion device 101 is removed from the above components is referred to as an “imaging pixel circuit” in some cases.

One electrode (cathode) of the photoelectric conversion device 101 is electrically connected to one of a source and a drain of the transistor 102. The other of the source and the drain of the transistor 102 is electrically connected to one of a source and a drain of the transistor 103. The one of the source and the drain of the transistor 103 is electrically connected to one electrode of the capacitor 108. The one electrode of the capacitor 108 is electrically connected to a gate of the transistor 104. One of a source and a drain of the transistor 104 is electrically connected to one of a source and a drain of the transistor 105.

A wiring that connects the other of the source and the drain of the transistor 102, the one of the source and the drain of the transistor 103, the one electrode of the capacitor 108, and the gate of the transistor 104 is a node FD. The node FD can function as a charge detection unit.

The other electrode (anode) of the photoelectric conversion device 101 is electrically connected to a wiring 121. A gate of the transistor 102 is electrically connected to a wiring 127. The other of the source and the drain of the transistor 103 is electrically connected to a wiring 122. The other of the source and the drain of the transistor 104 is electrically connected to a wiring 123. A gate of the transistor 103 is electrically connected to a wiring 126. A gate of the transistor 105 is electrically connected to a wiring 128. The other electrode of the capacitor 108 is electrically connected to a reference potential line such as a GND wiring, for example. The other of the source and the drain of the transistor 105 is electrically connected to the wiring 352.

The wiring 127, the wiring 126, and the wiring 128 each have a function of a signal line controlling on and off states of the corresponding transistor. The wiring 352 has a function as an output line.

The wiring 121, the wiring 122, and the wiring 123 each have a function of a power supply line. In the configuration illustrated in FIG. 4A, the cathode side of the photoelectric conversion device 101 is electrically connected to the transistor 102 and high potential is supplied to the node FD at the time of reset. Thus, the wiring 122 is at a high potential (a potential higher than that of the wiring 121).

Although the cathode of the photoelectric conversion device 101 is electrically connected to the node FD in FIG. 4A, the anode side of the photoelectric conversion device 101 may be electrically connected to the one of the source and the drain of the transistor 102. In that case, since low potential is supplied to the node FD at the time of reset, the wiring 122 may be set to a low potential (lower potential than that of the wiring 121).

The transistor 102 has a function of controlling the potential of the node FD. The transistor 102 is also referred to as a “transfer transistor”. The transistor 103 has a function of resetting the potential of the node FD. The transistor 103 is also referred to as a “reset transistor”. The transistor 104 functions as a source follower circuit and can output the potential of the node FD as imaging data to the wiring 352. The transistor 105 has a function of selecting a pixel to which the imaging data is output. The transistor 104 is also referred to as an “amplifier transistor”. The transistor 105 is also referred to as a “selection transistor”.

The photoelectric conversion device 101 and the transistor 102 are regarded as one set as illustrated in FIG. 4B, and a plurality of sets each including the photoelectric conversion device 101 and the transistor 102 may be connected to the node FD. With the circuit configuration illustrated in FIG. 4B, the area occupied by one imaging pixel 12 can be reduced. Thus, the packing density of the imaging pixels 12 can be increased.

In FIG. 4B, the photoelectric conversion device 101 and the transistor 102 of the first set are denoted as a photoelectric conversion device 101_1 and a transistor 1021, respectively. A gate of the transistor 102_1 is electrically connected to a wiring 1271. The photoelectric conversion device 101 and the transistor 102 of the second set are denoted as a photoelectric conversion device 101_2 and a transistor 1022, respectively. A gate of the transistor 102_2 is electrically connected to the wiring 127_2. The photoelectric conversion device 101 and the transistor 102 of the k-th set (k is an integer greater than or equal to 1) are denoted as a photoelectric conversion device 101_k and a transistor 102_k, respectively. A gate of the transistor 102_k is electrically connected to the wiring 127_k.

All transistors included in the layer 10 can be fabricated in the same step.

Note that the functional circuit included in the layer 10 does not necessarily include all the components described in this embodiment and the like, and can include components other than these.

### <Structure Example of Layer 20>

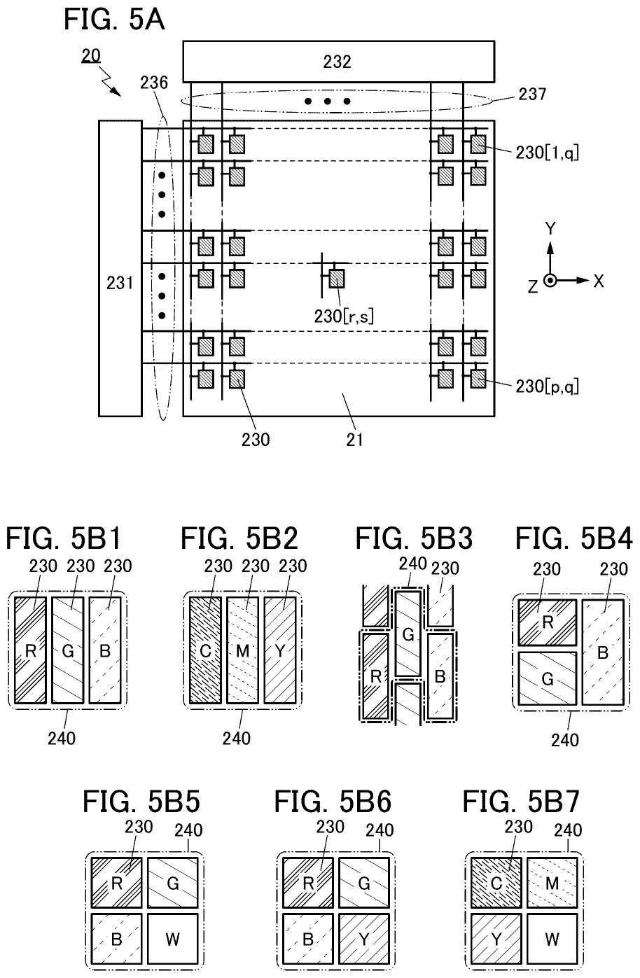

FIG. 5A is a block diagram illustrating the structure of the layer 20. As described above, the layer 20 includes the display unit 21, the first driver circuit unit 231, and the second driver circuit unit 232.

Note that similarly to the layer 10, the first driver circuit unit 231, the second driver circuit unit 232, and the like included in the layer 20 are collectively referred to as a “functional circuit” in some cases.

A circuit included in the first driver circuit unit 231 functions as, for example, a scan line driver circuit. A circuit included in the second driver circuit unit 232 functions as, for example, a signal line driver circuit. Some sort of circuit may be provided to face the first driver circuit unit 231 with the display unit 21 placed therebetween. Some sort of circuit may be provided to face the second driver circuit unit 232 with the display unit 21 placed therebetween. Note that circuits included in the first driver circuit unit 231 and the second driver circuit unit 232 are collectively referred to as a “peripheral driver circuit” in some cases.

Various circuits such as a shift register, a level shifter, an inverter, a latch, an analog switch, and a logic circuit can be used as the peripheral driver circuit. In the peripheral driver circuit, a transistor, a capacitor, and the like can be used. A transistor included in the peripheral driver circuit can be formed in the same steps as the transistors included in the display pixels 230.

Transistors used in the display unit 21 and the peripheral driver circuit and provided in the layer 20 can be either n-channel transistors or p-channel transistors. Both n-channel transistors and p-channel transistors may be used. A CMOS structure in which n-channel transistors and p-channel transistors are combined may be employed for the display unit 21 and the peripheral driver circuit.

The layer 20 includes p wirings 236 (p is an integer greater than or equal to 1) which are arranged substantially parallel to each other and whose potentials are controlled by the circuit included in the first driver circuit unit 231, and q wirings 237 (q is an integer greater than or equal to 1) which are arranged substantially parallel to each other and whose potentials are controlled by the circuit included in the second driver circuit unit 232.

FIG. 5A illustrates an example in which the wiring 236 and the wiring 237 are connected to the display pixel 230. Note that the wiring 236 and the wiring 237 is an example, and the wirings connected to the display pixel 230 are not limited to the wiring 236 and the wiring 237.

The display unit 21 includes a plurality of display pixels 230 arranged in a matrix of p rows and q columns. For example, the display pixels 230 placed in the r-th row (r is a given number; in this embodiment and the like, r is an integer greater than or equal to 1 and less than or equal top) are electrically connected to the first driver circuit unit 231 through the r-th wiring 236. In addition, the imaging pixels 12 placed in the s-th column (s is a given number; in this embodiment and the like, s is an integer greater than or equal to 1 and less than or equal to q) are electrically connected to the second driver circuit unit 232 through the s-th wiring 237.

In FIG. 5A, the display pixel 230 placed in the first low and the q-th column is denoted as the display pixel 230[1, q], and the display pixel 230 placed in the p-th row and the q-th column is denoted as the display pixel 230[p, q]. The display pixel 230 placed in the r-th row and the s-th column is denoted as the display pixel 230[r, s].

For example, transistors each including a metal oxide in a channel formation region (hereinafter also referred to as “OS transistor”) may be used as the transistors included in the display pixel 230, and transistors each including silicon in a channel formation region (hereinafter also referred to as “Si transistor”) may be used as the transistors included in the peripheral driver circuit. Since an OS transistor has a low leakage current between a source and a drain in an off state (hereinafter, also referred to as an “off-state current”), power consumption can be reduced. Since a Si transistor operates faster than an OS transistor, the Si transistor is preferably used in the peripheral driver circuit. Note that both the transistors included in the display pixel 230 and the transistors included in the peripheral driver circuit may be OS transistors. Both the transistors included in the display pixel 230 and the transistors included in the peripheral driver circuit may be Si transistors. Furthermore, Si transistors may be used as the transistors included in the display pixel 230, and OS transistors may be used as the transistors included in the peripheral driver circuit.

Both a Si transistor and an OS transistor may be used as the transistors included in the display pixel 230. Both a Si transistor and an OS transistor may be used as the transistors included in the peripheral driver circuit.

Note that as examples of materials used as a Si transistor, single crystal silicon, polycrystalline silicon, amorphous silicon, and the like can be given. In particular, a transistor containing low-temperature polysilicon (LTPS) in its semiconductor layer (hereinafter also referred to as an LTPS transistor) can be used. An LTPS transistor has high field-effect mobility and favorable frequency characteristics.

With the use of Si transistors such as LTPS transistors, a circuit required to be driven at a high frequency (e.g., a source driver circuit) can be formed on the same substrate as the display unit. Thus, external circuits mounted on the semiconductor device can be simplified, and costs of parts and mounting costs can be reduced.

An OS transistor has extremely higher field-effect mobility than a transistor containing amorphous silicon. An OS transistor has an extremely low off-state current and enables charge stored in a capacitor that is series-connected to the transistor to be retained for a long time. Furthermore, power consumption of the semiconductor device can be reduced when an OS transistor is used.

The off-state current value per micrometer of channel width of the OS transistor at room temperature can be lower than or equal to 1 aA (1×10⁻¹⁸ A), lower than or equal to 1 zA (1×10⁻²¹ A), or lower than or equal to 1 yA (1×10⁻²⁴ A). Note that the off-state current value per micrometer of channel width of a Si transistor at room temperature is higher than or equal to 1 fA (1×10⁻¹⁵ A) and lower than or equal to 1 pA (1×10⁻¹² A). In other words, the off-state current of an OS transistor is lower than that of a Si transistor by approximately ten orders of magnitude.

Full-color display can be achieved by making the display pixel 230 that controls red light, the display pixel 230 that controls green light, and the display pixel 230 that controls blue light collectively function as one pixel 240 and by controlling the amount of light (emission luminance) emitted from each display pixel 230. Thus, the three display pixels 230 each function as a subpixel. That is, three subpixels each control the emission amount or the like of red light, green light, and blue light (see FIG. 5B1). Note that the light colors controlled by the three subpixels are not limited to a combination of red (R), green (G), and blue (B) and may be cyan (C), magenta (M), and yellow (Y) (see FIG. 5B2).

Three display pixels 230 constituting one pixel 240 may be arranged in a delta pattern (see FIG. 5B3). Specifically, three display pixels 230 constituting one pixel 240 may be arranged such that the lines connecting the center points of the three display pixels 230 form a triangle.

The areas of three subpixels (the pixels 230) are not necessarily the same as one another. When the emission efficiency, the reliability, and the like are different depending on emission colors, the areas of subpixels may be different depending on emission colors (see FIG. 5B4). Note that the arrangement of the subpixels illustrated in FIG. 5B4 may be called “S-stripe arrangement.”

Furthermore, four subpixels may collectively function as one pixel. For example, a subpixel that controls white light may be added to the three subpixels that control red light, green light, and blue light (see FIG. 5B5). The addition of the subpixel that controls white light can increase the luminance of a display region. Alternatively, a subpixel that controls yellow light may be added to the three subpixels that control red light, green light, and blue light (see FIG. 5B6). Alternatively, a subpixel that controls white light may be added to the three subpixels that control cyan light, magenta light, and yellow light (see FIG. 5B7).

When the number of subpixels functioning as one pixel is increased and subpixels that control light of red, green, blue, cyan, magenta, yellow, and the like are used in an appropriate combination, the reproducibility of halftones can be increased. Thus, display quality can be increased.

The semiconductor device of one embodiment of the present invention can reproduce the color gamut of various standards. For example, the display apparatus of one embodiment of the present invention can reproduce the color gamut of the PAL (Phase Alternating Line) standard and the NTSC (National Television System Committee) standard used as TV broadcasting; the sRGB (standard RGB) standard and the Adobe RGB standard widely used as display apparatuses used in electronic apparatuses such as personal computers, digital cameras, and printers; the ITU-R BT.709 (International Telecommunication Union Radiocommunication Sector Broadcasting Service (Television) 709) standard used as HDTV (High Definition Television, also referred to Hi-Vision); the DCI-P3 (Digital Cinema Initiatives P3) standard used as digital cinema projection; the ITU-R BT.2020 (REC.2020 (Recommendation 2020)) standard used as UHDTV (Ultra High Definition Television, also referred to as Super Hi-Vision); and the like.

When the pixels 240 are arranged in a matrix of 1920×1080, the display unit 21 can achieve full color display with a resolution of what is called full hi-vision (also referred to as 2K resolution, 2K1K, 2K, and the like). Alternatively, for example, when the pixels 240 are arranged in a matrix of 3840×2160, the display unit 21 that can perform full-color display with a resolution of what is called ultra high definition (also referred to as “4K resolution,” “4K2K,” “4K,” or the like) can be achieved. Alternatively, for example, when the pixels 240 are arranged in a matrix of 7680×4320, the display unit 21 that can perform full-color display with a resolution of what is called super high definition (also referred to as “8K resolution,” “8K4K,” “8K,” or the like) can be achieved. By increasing the number of pixels 240, the display unit 21 that can perform full-color display with 16K or 32K resolution can also be achieved.

The pixel density of the display unit 21 is preferably higher than or equal to 100 ppi and lower than or equal to 10000 ppi, and further preferably higher than or equal to 1000 ppi and lower than or equal to 10000 ppi. For example, the pixel density can be higher than or equal to 2000 ppi and lower than or equal to 6000 ppi, or higher than or equal to 3000 ppi and lower than or equal to 5000 ppi. The pixel density of the display unit 21 can be the same as or different from the pixel density of the imaging unit 11.

Note that there is no particular limitation on the aspect ratio of the display unit 21. The display unit 21 in the semiconductor device 100A can have various aspect ratios, such as 1:1 (a square), 4:3, 16:9, and 16:10. The aspect ratio of the display unit 21 can be the same as or different from the aspect ratio of the imaging unit 11.

The diagonal size of the display unit 21 is at least greater than or equal to 0.1 inches and less than or equal to 100 inches and may be greater than or equal to 100 inches. The diagonal size of the display unit 21 can be the same as or different from the diagonal size of the imaging unit 11.

In the case where the semiconductor device 100A is used as a display apparatus for xR, the diagonal size of the display unit 21 can be greater than or equal to 0.1 inches and less than or equal to 5.0 inches, preferably greater than or equal to 0.5 inches and less than or equal to 2.0 inches, further preferably greater than or equal to 1 inch and less than or equal to 1.7 inches. For example, the diagonal size of the display unit 21 may be 1.5 inches or around 1.5 inches. When the diagonal size of the display unit 21 is less than or equal to 2.0 inches, preferably around 1.5 inches, the number of times of light exposure treatment using a light exposure apparatus (typified by a scanner apparatus) can be one; thus, the productivity of a manufacturing process can be improved.

The refresh rate of the display unit 21 included in the semiconductor device of one embodiment of the present invention can be variable. For example, the refresh rate is adjusted (in the range from 0.01 Hz to 240 Hz inclusive, for example) in accordance with contents displayed on the display unit 21, whereby power consumption can be reduced. Moreover, driving with a lowered refresh rate that enables the power consumption of the display unit 21 may be referred to as idling stop (IDS) driving.

A touch sensor or a near-touch sensor may be provided in the display unit 21. In addition, the drive frequency of a touch sensor or a near-touch sensor may be changed depending on the above refresh rate. In the case where the refresh rate of the display unit 21 is 120 Hz, for example, the drive frequency of a touch sensor or a near-touch sensor can be higher than 120 Hz (typically 240 Hz). With this structure, low power consumption can be achieved, and the response speed of the touch sensor or the near-touch sensor can be increased.

Here, a touch sensor or a non-contact sensor has a function of sensing the approach or contact of an object (e.g., a finger, a hand, or a pen). The touch sensor can detect the object when the object come in direct contact with the sensor. Furthermore, the non-contact sensor can detect the object even when the object does not come in direct contact with the sensor. For example, the sensor is preferably capable of sensing an object positioned in the range of 0.1 mm to 300 mm inclusive, further preferably 3 mm to 50 mm inclusive from the semiconductor device (or the display unit 21). This structure enables the semiconductor device to be operated without direct contact of an object; in other words, the semiconductor device can be operated in a non-contact (touchless) manner. With the above-described structure, the semiconductor device can have a reduced risk of being dirty or damaged, or can be controlled without the object directly touching a dirt (e.g., dust, bacteria, or a virus) attached to the semiconductor device.

Note that the non-contact sensor function can also be referred to as a hover sensor function, a hover touch sensor function, a near-touch sensor function, a touchless sensor function, or the like. The touch sensor function can also be referred to as a direct touch sensor function or the like.

### <Circuit Configuration Example of Display Pixel 230>

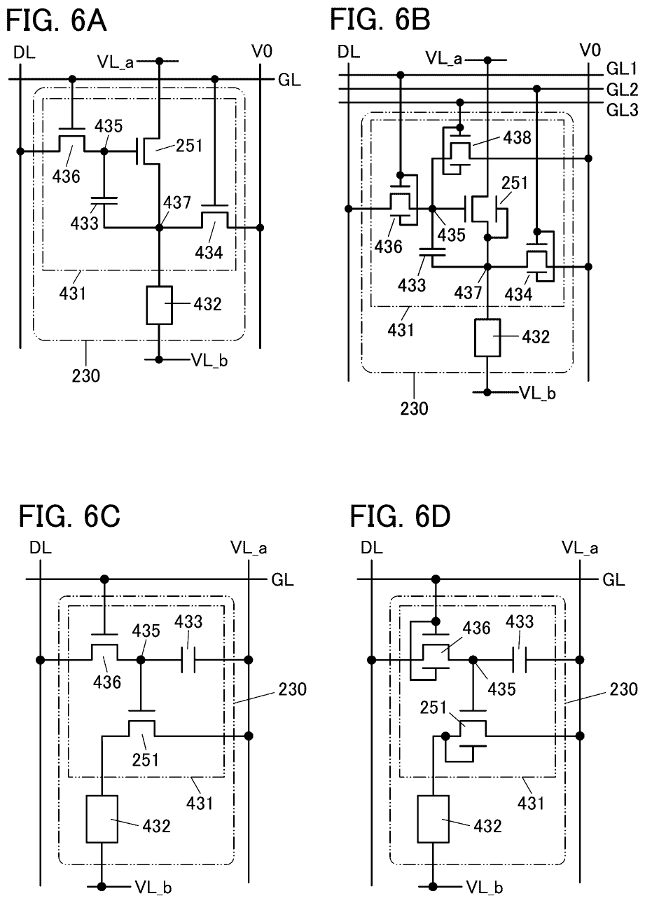

FIG. 6A is a diagram illustrating a circuit configuration example of the display pixel 230. The display pixel 230 includes the display pixel circuit 431 and the display element 432.

Accordingly, each of the wirings 236 is electrically connected to the q display pixel circuits 431 arranged in a given row among the display pixel circuits 431 arranged in p rows and q columns in the display unit 21. Each of the wirings 237 is electrically connected to the p display pixel circuits 431 arranged in a given column among the display pixel circuits 431 arranged in p rows and q columns.

The pixel circuit 431 includes a transistor 436, a capacitor 433, a transistor 251, and a transistor 434. The display pixel circuit 431 is electrically connected to the display element 432.

One of a source electrode and a drain electrode of the transistor 436 is electrically connected to a wiring to which a data signal (also referred to as a “video signal”) is supplied (hereinafter referred to as a signal line DL). A gate electrode of the transistor 436 is electrically connected to a wiring to which a gate signal is supplied (hereinafter referred to as a scan line GL). The signal line DL and the scan line GL correspond to the wiring 237 and the wiring 236, respectively. The transistor 436 has a function of controlling the writing of the data signal to a node 435.

One of a pair of electrodes of the capacitor 433 is electrically connected to the node 435, and the other is electrically connected to a node 437. The other of the source electrode and the drain electrode of the transistor 436 is electrically connected to the node 435.

The capacitor 433 has a function of a storage capacitor for storing data signal written to the node 435.

One of a source electrode and a drain electrode of the transistor 251 is electrically connected to a potential supply line VL_a, and the other is electrically connected to the node 437. Furthermore, a gate electrode of the transistor 251 is electrically connected to the node 435.

One of a source electrode and a drain electrode of the transistor 434 is electrically connected to a potential supply line V0, and the other is electrically connected to the node 437. Furthermore, a gate electrode of the transistor 434 is electrically connected to the scan line GL.

One of an anode and a cathode of the display element 432 is electrically connected to a potential supply line VL_b, and the other is electrically connected to the node 437.

As the display element 432, a light-emitting element (also referred to as a “light-emitting device”) such as an organic electroluminescent element (also referred to as an “organic EL element”) can be used. However, the display element 432 is not limited thereto, and an inorganic EL element formed of an inorganic material may be used, for example. Note that an “organic EL element” and an “inorganic EL element” are collectively referred to as “EL element” in some cases.

The emission color of the EL element can be white, red, green, blue, cyan, magenta, yellow, or the like depending on materials included in the EL element.

Examples of a method for achieving color display include a method in which the display element 432 whose emission color is white is combined with a coloring layer and a method in which the display element 432 with a different emission color is provided in each pixel. The former method is more productive than the latter method. In contrast, the latter method, which requires separate formation of the display element 432 pixel by pixel, is less productive than the former method. However, the latter method can provide higher color purity of the emission color than the former method. When the display element 432 has a microcavity structure in addition to the latter method, the color purity can be further increased.

The display element 432 can contain either a low-molecular compound or a high-molecular compound, and may contain an inorganic compound. The layers included in the display element 432 can each be formed by a method such as an evaporation method (including a vacuum evaporation method), a transfer method, a printing method, an inkjet method, or a coating method.

The display element 432 may contain an inorganic compound such as quantum dots. For example, when used in the light-emitting layer, the quantum dots can function as a light-emitting material.

As a power supply potential, a potential on the relatively high potential side or a potential on the relatively low potential side can be used, for example. A power supply potential on the high potential side is referred to as a high power supply potential (also referred to as “VDD”), and a power supply potential on the low potential side is referred to as a low power supply potential (also referred to as “VSS”). A ground potential can be used as the high power supply potential or the low power supply potential. For example, in the case where a ground potential is used as the high power supply potential, the low power supply potential is a potential lower than the ground potential, and in the case where a ground potential is used as the low power supply potential, the high power supply potential is a potential higher than the ground potential.

A high power supply potential VDD is supplied to one of the potential supply line VL_a and the potential supply line VL_b, and a low power supply potential VSS is supplied to the other, for example.

In the layer 20 including the display pixel circuits 431, the display pixel circuits 431 are sequentially selected row by row by the circuit included in the peripheral driver circuit, whereby the transistors 436 and the transistors 434 are turned on and a data signal is written to the nodes 435.

The display pixel circuit 431 in which data signal has been written to the node 435 is brought into a holding state when the transistor 436 and the transistor 434 are turned off. Furthermore, the amount of current flowing between the source electrode and the drain electrode of the transistor 251 is controlled in accordance with the potential of the data signal written to the node 435, and the display element 432 emits light with a luminance corresponding to the amount of current flow. This operation is sequentially performed row by row; thus, an image can be displayed. The transistor 251 is also referred to as a “driving transistor”.

To increase the emission luminance of the light-emitting device included in the display pixel 230, the amount of current fed through the light-emitting device needs to be increased. For that purpose, it is necessary to increase the source-drain voltage of a driving transistor included in the display pixel circuit 431. Since an OS transistor has a higher withstand voltage between the source and the drain than a Si transistor, a high voltage can be applied between the source and the drain of the OS transistor. Accordingly, when an OS transistor is used as the driving transistor in the display pixel circuit 431, the amount of current flowing through the light-emitting device can be increased, so that the emission luminance of the light-emitting device can be increased.

When the transistor operates in a saturation region, a change in the amount of the source-drain current, with respect to a fluctuation in the gate-source voltage, in the OS transistor is smaller than that in the Si transistor. Accordingly, when an OS transistor is used as the driving transistor included in the display pixel circuit 431, a current flowing between the source and the drain can be set minutely by a change in a gate-source voltage; hence, the amount of current flowing through the light-emitting device can be minutely controlled. Consequently, the number of gray levels expressed by the display pixel 230 can be increased.

Regarding saturation characteristics of a current flowing when transistors operate in a saturation region, even in the case where the source-drain voltage of an OS transistor increases gradually, a more stable current (saturation current) can be fed through the OS transistor than through a Si transistor. Thus, by using an OS transistor as the driving transistor, a stable current can be fed through light-emitting devices that contain an EL material even when the current-voltage characteristics of the light-emitting devices vary, for example. In other words, when the OS transistor operates in the saturation region, the source-drain current hardly changes with an increase in the source-drain voltage; hence, the emission luminance of the light-emitting device can be stable.

As described above, with the use of an OS transistor as a driving transistor included in the pixel circuit, it is possible to achieve “inhibition of black floating”, “increase in emission luminance”, “increase in gray level”, “inhibition of variation in light-emitting devices”, and the like.

FIG. 6B illustrates a modification example of the circuit configuration of the display pixel 230 in FIG. 6A. In the circuit configuration illustrated in FIG. 6B, the gate electrode of the transistor 436 is electrically connected to a wiring to which a first scan signal is supplied (hereinafter referred to as a scan line GL1). The gate electrode of the transistor 434 is electrically connected to a wiring to which a second scan signal is supplied (hereinafter referred to as a scan line GL2).

The circuit configuration illustrated in FIG. 6B includes a transistor 438 in addition to the circuit configuration illustrated in FIG. 6A. One of a source electrode and a drain electrode of the transistor 438 is electrically connected to a potential supply line V0, and the other is electrically connected to the node 435. A gate electrode of the transistor 438 is electrically connected to a wiring to which a third scan signal is supplied (hereinafter referred to as a scan line GL3).

The scan line GL1 corresponds to the wiring 236 illustrated in FIG. 5A. In FIG. 5A, although the wirings corresponding to the scan line GL2 and the scan line GL3 are not illustrated, the scan line GL2 and the scan line GL3 are electrically connected to the first driver circuit unit 231.

For example, in the case where the display pixel 230 is to display black, both the transistor 434 and the transistor 438 are turned on. Thus, the potential of the source electrode of the transistor 251 is equal to that of the gate electrode thereof. In this manner, the gate voltage of the transistor 251 is set to 0 V, so that current flowing through the display element 432 can be blocked.

Furthermore, some or all of the transistors included in the display pixel circuit 431 may be transistors having a back gate. Transistors with a back gate are used as transistors in the circuit configuration illustrated in FIG. 6B. For example, agate and aback gate is electrically connected to each other in each of the transistor 434, the transistor 436, and the transistor 438. In addition, in the transistor 251 illustrated in FIG. 6B, the back gate is electrically connected to the node 437.

FIG. 6C illustrates a modification example of a circuit configuration of the display pixel 230 illustrated in FIG. 6A. The circuit configuration illustrated in FIG. 6C is a configuration excluding the transistor 434 and the potential supply line V0 in the circuit configuration illustrated in FIG. 6A. For understanding of other components, description of the circuit configuration illustrated in FIG. 6A can be referred to. Therefore, the detailed description of the circuit configuration in FIG. 6C is omitted to reduce repetitive description.

Furthermore, as described above, some or all of the transistors included in the display pixel circuit 431 may be transistors having a back gate. For example, the transistor 436 may be a transistor having a back gate, and the back gate and the gate thereof may be electrically connected to each other as illustrated in FIG. 6D. Alternatively, the transistor 251 may be a transistor having a back gate, and the back gate and one of the source and the drain may be electrically connected to each other as illustrated in FIG. 6D.

### <Structure Example of Light-Emitting Element>

A light-emitting element that can be used in the display apparatus of one embodiment of the present invention will be described. A light-emitting element can be used in the display element 432.

### <Structure Example of Light-Emitting Element>

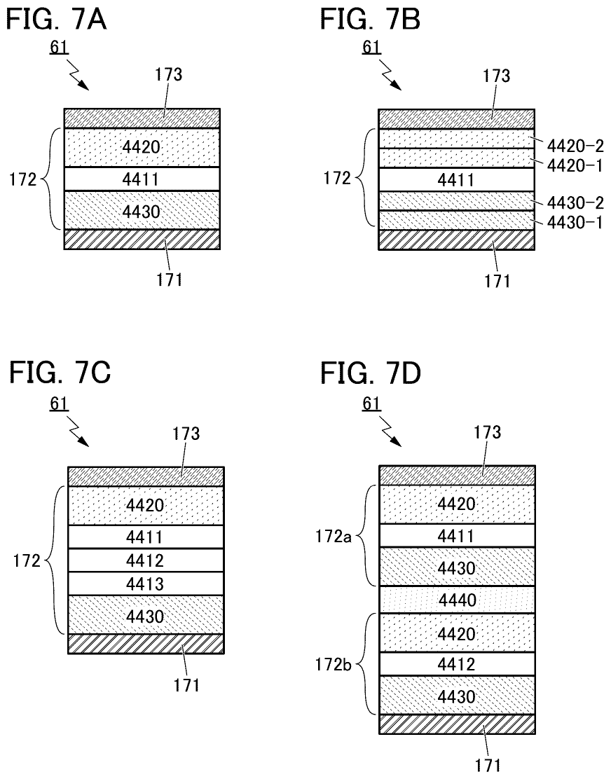

As illustrated in FIG. 7A, a light-emitting element 61 includes an EL layer 172 between a pair of electrodes (a conductive layer 171 and a conductive layer 173). The EL layer 172 can include a plurality of layers such as a layer 4420, a light-emitting layer 4411, and a layer 4430. The layer 4420 can include, for example, a layer containing a substance with a high electron-injection property (an electron-injection layer) and a layer containing a substance with a high electron-transport property (an electron-transport layer). The light-emitting layer 4411 contains a light-emitting compound, for example. The layer 4430 can include, for example, a layer containing a substance with a high hole-injection property (a hole-injection layer) and a layer containing a substance with a high hole-transport property (a hole-transport layer).

The structure including the layer 4420, the light-emitting layer 4411, and the layer 4430, which are provided between the pair of electrodes, can function as a single light-emitting unit, and the structure in FIG. 7A is referred to as a single structure in this specification and the like.

FIG. 7B is a modification example of the EL layer 172 included in the light-emitting element 61 illustrated in FIG. 7A. Specifically, the light-emitting element 61 illustrated in FIG. 7B includes a layer 4430-1 over the conductive layer 171, a layer 4430-2 over the layer 4430-1, the light-emitting layer 4411 over the layer 4430-2, a layer 4420-1 over the light-emitting layer 4411, a layer 4420-2 over the layer 4420-1, and the conductive layer 173 over the layer 4420-2. For example, when the conductive layer 171 is a positive electrode and the conductive layer 173 is a negative electrode, the layer 4430-1 functions as a hole-injection layer, the layer 4430-2 functions as a hole-transport layer, the layer 4420-1 functions as an electron-transport layer, and the layer 4420-2 functions as an electron-injection layer. Alternatively, when the conductive layer 171 is a negative electrode and the conductive layer 173 is a positive electrode, the layer 4430-1 functions as an electron-injection layer, the layer 4430-2 functions as an electron-transport layer, the layer 4420-1 functions as a hole-transport layer, and the layer 4420-2 functions as a hole-injection layer. With such a layer structure, carriers can be efficiently injected to the light-emitting layer 4411, and the efficiency of the recombination of carriers in the light-emitting layer 4411 can be enhanced.

Note that the structure in which a plurality of light-emitting layers (the light-emitting layer 4411, the light-emitting layer 4412, and the light-emitting layer 4413) are provided between the layer 4420 and the layer 4430 as illustrated in FIG. 7C is another example of the single structure.

The structure in which a plurality of light-emitting units (an EL layer 172a and an EL layer 172b) are connected in series with an intermediate layer (charge-generation layer) 4440 therebetween as illustrated in FIG. 7D is referred to as a tandem structure or a stack structure in this specification. Note that the tandem structure enables a light-emitting element capable of high-luminance light emission.

In the case where the light-emitting element 61 has the tandem structure illustrated in FIG. 7D, the EL layer 172a and the EL layer 172b may emit light of the same color. For example, both the EL layer 172a and the EL layer 172b may emit green light. Note that in the case where the display unit 21 includes three subpixels of R, G, and B and each of the subpixels includes a light-emitting element, the tandem structure may be employed for the light-emitting element of each subpixels. Specifically, the EL layer 172a and the EL layer 172b in the subpixel of R each contain a material capable of emitting red light, the EL layer 172a and the EL layer 172b in the subpixel of G each contain a material capable of emitting green light, and the EL layer 172a and the EL layer 172b in the subpixel of B each contain a material capable of emitting blue light. In other words, the light-emitting layer 4411 and the light-emitting layer 4412 may contain the same material. When the EL layer 172a and the EL layer 172b emit light of the same color, the current density per unit emission luminance can be reduced. Thus, the reliability of the light-emitting element 61 can be increased.

The emission color of the light-emitting element can be red, green, blue, cyan, magenta, yellow, white, or the like depending on the material contained in the EL layer 172. Furthermore, the color purity can be further increased when the light-emitting element has a microcavity structure.

The light-emitting layer may contain two or more of light-emitting substances that emit light of R (red), G (green), B (blue), Y (yellow), O (orange), and the like. The light-emitting element that emits white light preferably contains two or more kinds of light-emitting substances in the light-emitting layer. In the case of obtaining white light emission with the use of two kinds of light-emitting substances, the two light-emitting substances may be selected such that their emission colors have a relationship of complementary colors. For example, when an emission color of a first light-emitting layer and an emission color of a second light-emitting layer have a relationship of complementary colors, it is possible to obtain a light-emitting element which emits white light as a whole. This is similar in a light-emitting element including three or more light-emitting layers.

The light-emitting layer preferably contains two or more of light-emitting substances that emit light of R (red), G (green), B (blue), Y (yellow), O (orange), and the like. Alternatively, the light-emitting layer preferably contains two or more light-emitting substances that emit light containing two or more of spectral components of R, G, and B.

As a light-emitting substance, a substance that emits fluorescent light (a fluorescent material), a substance that emits phosphorescent light (a phosphorescent material), an inorganic compound (a quantum dot material or the like), a substance that emits thermally activated delayed fluorescent light (a Thermally Activated Delayed Fluorescence (TADF) material), and the like can be given. Note that as a TADF material, a material that has a thermal equilibrium state between a singlet excited state and a triplet excited state may be used. Since such a TADF material enables a long emission lifetime (excitation lifetime), an efficiency decrease of a light-emitting element in a high-luminance region can be inhibited.

### <Formation Method of Light-Emitting Element>

A formation method of the light-emitting element 61 that can be used as the display element 432 is described below.

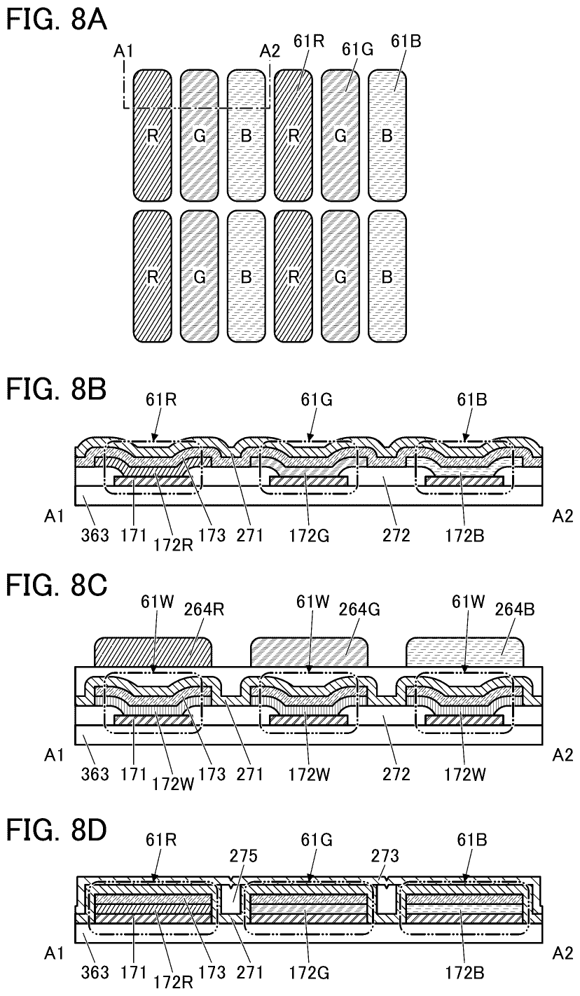

FIG. 8A is a schematic top view of the light-emitting element 61. In FIG. 8A and the like, the light-emitting element 61 emitting red light is denoted as a light-emitting element 61R, the light-emitting element 61 emitting green light is denoted as a light-emitting element 61G, and the light-emitting element 61 emitting blue light is denoted as a light-emitting element 61B. In FIG. 8A, light-emitting regions of the light-emitting elements are denoted as R, G, and B to easily differentiate the light-emitting elements. Note that the structure of the light-emitting element 61 illustrated in FIG. 8A may be referred to as an SBS (Side By Side) structure. Although the structure illustrated in FIG. 8A has three colors of red (R), green (G), and blue (B), one embodiment of the present invention is not limited thereto. For example, the structure may have four or more colors.

The light-emitting elements 61R, the light-emitting elements 61G, and the light-emitting elements 61B are arranged in a matrix. FIG. 8A illustrates what is called a stripe arrangement, in which the light-emitting elements of the same color are arranged in one direction. Note that the arrangement method of the light-emitting elements is not limited thereto; another arrangement method such as a delta arrangement, a zigzag arrangement may be applied, or a PenTile arrangement may also be used.

As the light-emitting element 61R, the light-emitting element 61G, and the light-emitting element 61B, an organic EL device such as an OLED (Organic Light Emitting Diode) or a QOLED (Quantum-dot Organic Light Emitting Diode) is preferably used. As a light-emitting substance contained in the light-emitting element, a substance that emits fluorescent light (a fluorescent material), a substance that emits phosphorescent light (a phosphorescent material), an inorganic compound (e.g., a quantum dot material), a substance that exhibits thermally activated delayed fluorescence (a Thermally Activated Delayed Fluorescent (TADF) material), and the like can be given.

FIG. 8B is a cross-sectional schematic view taken along dashed-dotted line A1-A2 in FIG. 8A. FIG. 8B illustrates a cross section of the light-emitting element 61R, the light-emitting element 61G, and the light-emitting element 61B. The light-emitting element 61R, the light-emitting element 61G, and the light-emitting element 61B are provided over an insulating layer 363, and include the conductive layer 171 functioning as a pixel electrode and the conductive layer 173 functioning as a common electrode. As the insulating layer 363, one or both of an inorganic insulating film and an organic insulating film can be used. An inorganic insulating film is preferably used as the insulating layer 363. As the inorganic insulating film, for example, an oxide insulating film and a nitride insulating film such as a silicon oxide film, a silicon oxynitride film, a silicon nitride oxide film, a silicon nitride film, an aluminum oxide film, an aluminum oxynitride film, or a hafnium oxide film can be given.

The light-emitting element 61R includes the conductive layer 171 functioning as a pixel electrode, the conductive layer 173 functioning as a common electrode, and an EL layer 172R therebetween. The EL layer 172R contains at least a light-emitting organic compound that emits light with intensity in the red wavelength range. An EL layer 172G included in the light-emitting element 61G contains at least a light-emitting organic compound that emits light with intensity in a green wavelength range. An EL layer 172B included in the light-emitting element 61B contains at least a light-emitting organic compound that emits light with intensity in a blue wavelength range.

The EL layer 172R, the EL layer 172G, and the EL layer 172B may each include one or more of an electron-injection layer, an electron-transport layer, a hole-injection layer, and a hole-transport layer in addition to the layer containing a light-emitting organic compound (light-emitting layer).

The conductive layer 171 functioning as a pixel electrode is provided for each of the light-emitting elements. The conductive layer 173 functioning as a common electrode is provided as a continuous layer shared by the light-emitting elements. A conductive film that transmits visible light is used as either the conductive layer 171 functioning as a pixel electrode or the conductive layer 173 functioning as a common electrode, and a reflective conductive film is used as the other. When the conductive layer 171 functioning as a pixel electrode has a light-transmitting property and the conductive layer 173 functioning as a common electrode has a reflective property, a bottom-emission display apparatus can be obtained, whereas when the conductive layer 171 functioning as a pixel electrode has a reflective property and the conductive layer 173 functioning as a common electrode has a light-transmitting property, a top-emission display apparatus can be obtained. Note that when both the conductive layer 171 functioning as a pixel electrode and the conductive layer 173 functioning as a common electrode have a light-transmitting property, a dual-emission display apparatus can be obtained.

An insulating layer 272 is provided to cover an end portion of the conductive layer 171 functioning as a pixel electrode. An end portion of the insulating layer 272 is preferably tapered. For the insulating layer 272, a material similar to the material that can be used for the insulating layer 363 can be used.

The EL layer 172R, the EL layer 172G, and the EL layer 172B each include a region in contact with the top surface of the conductive layer 171 functioning as a pixel electrode and a region in contact with a surface of the insulating layer 272. End portions of the EL layer 172R, the EL layer 172G, and the EL layer 172B are positioned over the insulating layer 272.

As illustrated in FIG. 8B, there is a gap between the two EL layers of the light-emitting elements that emit two different colors. In this manner, the EL layer 172R, the EL layer 172G, and the EL layer 172B are preferably provided not to be in contact with each other. This can suitably prevent unintentional light emission (also referred to as crosstalk) due to current flowing through the two adjacent EL layers. As a result, the contrast can be increased to achieve a display apparatus with high display quality.

The EL layer 172R, the EL layer 172G, and the EL layer 172B can be formed separately by a vacuum evaporation method or the like using a shadow mask such as a metal mask. Alternatively, these layers may be formed separately by a photolithography method. The use of the photolithography method achieves a display apparatus with high resolution, which is difficult to obtain in the case of using a metal mask.

In this specification and the like, a device fabricated using a metal mask or an FMM (a fine metal mask, a high-resolution metal mask) may be referred to as a device having an MM (a metal mask) structure. Note that in this specification and the like, a device fabricated using an FMM is sometimes referred to as a device having an FMM structure. In this specification and the like, a device fabricated without using a metal mask or an FMM may be referred to as a device having an MML (metal maskless) structure. A display apparatus having an MML structure is fabricated without using a metal mask and thus has higher flexibility in designing the pixel arrangement, the pixel shape, and the like than a display apparatus having an FMM structure or an MM structure.

Note that in the method for fabricating a display apparatus having an MML structure, an island-shaped EL layer is formed not by patterning with the use of a metal mask but by processing an EL layer formed over an entire surface. Accordingly, a high-resolution display apparatus or a display apparatus with a high aperture ratio, which has been difficult to be fabricated so far, can be achieved. Moreover, EL layers of different colors can be formed separately, which enables the display apparatus to perform extremely clear display with high contrast and high display quality. Moreover, providing a sacrificial layer over the EL layer can reduce damage to the EL layer in the fabricating process of the display apparatus, resulting in an increase in reliability of the light-emitting device.

In the case where a display apparatus has a fine metal mask (FMM) structure, the pixel arrangement structure or the like is restricted in some cases. Here, the FMM structure will be described below.

In a fabrication of the FMM structure, a metal mask (also referred to as an FMM) provided with an opening so that an EL material can be deposited to a desired region at the time of EL evaporation is set to be opposed to a substrate. Then, the EL material is deposited to the desired region by EL evaporation through the FMM. When the size of the substrate at the time of EL evaporation is larger, the size of the FMM is increased and accordingly the weight thereof is also increased. In addition, heat or the like is applied to the FMM at the time of EL evaporation and may change the shape of the FMM. Furthermore, there is a method in which EL evaporation is performed while a certain level of tension is applied to the FMM; therefore, the weight and strength of the FMM are important parameters.

Therefore, a configuration of pixel arrangement in a device having the FMM structure needs to be designed under certain restrictions; for example, the above-described parameters and the like need to be considered. Meanwhile, the display apparatus of one embodiment of the present invention, which is fabricated using the MML structure, has an excellent effect of a higher degree of freedom in a configuration of pixel arrangement and the like than in the case of employing the FMM structure, for example. This structure is highly compatible with a flexible device or the like, for example, and thus one or both of a pixel and a driver circuit can have a variety of circuit arrangements.

A protective layer 271 is provided over the conductive layer 173 functioning as a common electrode to cover the light-emitting element 61R, the light-emitting element 61G, and the light-emitting element 61B. The protective layer 271 has a function of preventing diffusion of impurities such as water into the light-emitting elements from the above.

The protective layer 271 can have, for example, a single-layer structure or a stacked-layer structure at least including an inorganic insulating film. As the inorganic insulating film, for example, an oxide film or a nitride film such as a silicon oxide film, a silicon oxynitride film, a silicon nitride oxide film, a silicon nitride film, an aluminum oxide film, an aluminum oxynitride film, or a hafnium oxide film can be given. Alternatively, a semiconductor material such as indium gallium oxide or indium gallium zinc oxide (IGZO) may be used for the protective layer 271. Note that the protective layer 271 may be formed by an atomic layer deposition (ALD) method, a chemical vapor deposition (CVD) method, or a sputtering method. Although the protective layer 271 includes an inorganic insulating film in this example, one embodiment of the present invention is not limited thereto. For example, the protective layer 271 may have a stacked-layer structure of an inorganic insulating film and an organic insulating film.

Note that in this specification, a nitride oxide refers to a compound that contains more nitrogen than oxygen. An oxynitride refers to a compound that contains more oxygen than nitrogen. The content of each element can be measured by Rutherford backscattering spectrometry (RBS), for example.

In the case where an indium gallium zinc oxide is used as the protective layer 271, the indium gallium zinc oxide can be processed by a wet etching method or a dry etching method. For example, in the case where IGZO is used as the protective layer 271, a chemical solution of oxalic acid, phosphoric acid, a mixed chemical solution (e.g., a mixed chemical solution of phosphoric acid, acetic acid, nitric acid, and water, which is also referred to as a mixed acid aluminum etchant), or the like can be used. Note that the volume ratio of phosphoric acid, acetic acid, nitric acid, and water mixed in the mixed acid aluminum etchant can be 53.3:6.7:3.3:36.7 or in the neighborhood thereof.

FIG. 8C illustrates an example different from the above. Specifically, a light-emitting element 61W emitting white light is provided in FIG. 8C. The light-emitting element 61W includes the conductive layer 171 functioning as a pixel electrode, the conductive layer 173 functioning as a common electrode, and an EL layer 172W emitting white light therebetween.

The EL layer 172W can have, for example, a stacked-layer structure of two light-emitting layers selected such that their emission colors have a relationship of complementary colors. It is also possible to use a stacked EL layer in which a charge-generation layer is interposed between light-emitting layers. The EL layer 172W may include three or more light-emitting layers.

FIG. 8C illustrates three light-emitting elements 61W side by side. A coloring layer 264R is provided above the left light-emitting element 61W. The coloring layer 264R functions as a band path filter transmitting red light. Similarly, a coloring layer 264G transmitting green light is provided above the middle light-emitting element 61W, and a coloring layer 264B transmitting blue light is provided above the right light-emitting element 61W. Thus, the display apparatus can display color images.

In the two adjacent light-emitting elements 61W, the EL layer 172W and the conductive layer 173 functioning as a common electrode of one of the light-emitting elements 61W are isolated from those of the other. This can prevent unintentional light emission from being caused by current flowing through the EL layers 172W of the two adjacent light-emitting elements 61W. In particular, when a stacked EL layer in which a charge-generation layer is provided between two light-emitting layers is used for the EL layer 172W, the effect of crosstalk is more significant as the resolution increases, i.e., as the distance between adjacent pixels decreases, leading to lower contrast. Thus, the above structure can achieve a display apparatus having both high resolution and high contrast.

The EL layer 172W and the conductive layer 173 functioning as a common electrode are preferably isolated by a photolithography method. This can reduce an interval between light-emitting elements, achieving a display apparatus with a higher aperture ratio than that formed using, for example, a shadow mask such as a metal mask.

Note that in the case of a bottom-emission light-emitting element, a coloring layer may be provided between the conductive layer 171 functioning as a pixel electrode and the insulating layer 363.

FIG. 8D illustrates an example different from the above. Specifically, in FIG. 8D, the insulating layers 272 covering the end portions of the conductive layers 171 are not provided between the light-emitting element 61R, the light-emitting element 61G, and the light-emitting element 61B. In other words, an insulator is not provided between the conductive layer 171 and the EL layer 172. With such a structure, light can be efficiently extracted from the EL layer, and thus viewing angle dependence is extremely reduced. For example, in the display apparatus of one embodiment of the present invention, the viewing angle (the maximum angle with a certain contrast ratio maintained when the screen is seen from an oblique direction) can be greater than or equal to 100° and less than 180°, preferably greater than or equal to 1500 and less than or equal to 170°. Note that the viewing angle refers to that in both the vertical direction and the horizontal direction. The display apparatus of one embodiment of the present invention can have reduced viewing angle dependence and high image visibility.

When the insulating layer 272 is not provided, a display apparatus with a high aperture ratio can be achieved. The protective layer 271 covers side surfaces of the EL layer 172R, the EL layer 172G, and the EL layer 172B. With this structure, impurities (typically, water or the like) can be inhibited from entering the EL layer 172R, the EL layer 172G, and the EL layer 172B through their side surfaces. In the structure illustrated in FIG. 8D, the conductive layer 171, the EL layer 172R, and the conductive layer 173 have substantially the same top surface shape. This structure can be formed in such a manner that the conductive layer 171, the EL layer 172R, and the conductive layer 173 are formed and collectively processed using a resist mask or the like. In this process, the EL layer 172R and the conductive layer 173 are processed using the conductive layer 173 as a mask, and thus this process can be called self-alignment patterning. Although the EL layer 172R is described here, the EL layer 172G and the EL layer 172B can each have a similar structure.

In FIG. 8D, a protective layer 273 is further provided over the protective layer 271. For example, the protective layer 271 is formed with an apparatus that can deposit a film with excellent coverage (typically, an ALD apparatus), and the protective layer 273 is formed with an apparatus that can deposit a film with coverage inferior to that of the protective layer 271 (typically, a sputtering apparatus), whereby a region 275 can be provided between the protective layer 271 and the protective layer 273. In other words, the regions 275 are positioned between the EL layer 172R and the EL layer 172G and between the EL layer 172G and the EL layer 172B.

Note that the region 275 includes, for example, one or more selected from air, nitrogen, oxygen, carbon dioxide, and Group 18 elements (typically, helium, neon, argon, xenon, and krypton). Furthermore, for example, a gas used during the deposition of the protective layer 273 is sometimes included in the region 275. For example, in the case where the protective layer 273 is deposited using a sputtering method, any one or more of the above-described Group 18 elements is sometimes included in the region 275. In the case where a gas is included in the region 275, the gas can be identified with a gas chromatography method or the like, for example. Alternatively, in the case where the protective layer 273 is deposited using a sputtering method, a gas used in the sputtering is sometimes contained in the protective layer 273. In that case, an element such as argon is sometimes detected when the protective layer 273 is analyzed by an energy dispersive X-ray analysis (EDX analysis) or the like.

In the case where the refractive index of the region 275 is lower than the refractive index of the protective layer 271, light emitted from the EL layer 172R, the EL layer 172G, or the EL layer 172B is reflected at the interface between the protective layer 271 and the region 275. Thus, light emitted from the EL layer 172R, the EL layer 172G, or the EL layer 172B can be inhibited from entering an adjacent pixel in some cases. This can inhibit color mixture of light emitted from adjacent pixels and thus can improve the display quality of the display apparatus.

In the case of the structure illustrated in FIG. 8D, a region between the light-emitting element 61R and the light-emitting element 61G or a region between the light-emitting element 61G and the light-emitting element 61B (hereinafter simply referred to as a distance between the light-emitting elements) can be small. Specifically, the distance between the light-emitting elements can be less than or equal to 1 μm, preferably less than or equal to 500 nm, further preferably less than or equal to 200 nm, less than or equal to 100 nm, less than or equal to 90 nm, less than or equal to 70 nm, less than or equal to 50 nm, less than or equal to 30 nm, less than or equal to 20 nm, less than or equal to 15 nm, or less than or equal to 10 nm. In other words, the display apparatus includes a region in which an interval between the side surface of the EL layer 172R and the side surface of the EL layer 172G or an interval between the side surface of the EL layer 172G and the side surface of the EL layer 172B is less than or equal to 1 μm, preferably less than or equal to 0.5 μm (500 nm), further preferably less than or equal to 100 nm.

In the case where the region 275 includes a gas, for example, the light-emitting elements can be isolated from each other and color mixture of light from the light-emitting elements, crosstalk, or the like can be inhibited.

Alternatively, the region 275 may be filled with a filler. As the filler, an epoxy resin, an acrylic resin, a silicone resin, a phenol resin, a polyimide resin, a polyamide resin, a polyimide-amide resin, a siloxane resin, a benzocyclobutene-based resin, a PVC (polyvinyl chloride) resin, a PVB (polyvinyl butyral) resin, an EVA (ethylene vinyl acetate) resin, and the like can be given. A photosensitive resin (e.g., a resist material) may be used as the filler. The photosensitive resin used as the filler can be either positive type or negative type.

With the use of a photosensitive resin as the filler, the region 275 can be filled by only light exposure and developing steps. The region 275 may be filled with the use of a negative photosensitive resin as the filler. A material that absorbs visible light is suitably used as the filler. When the region 275 is filled with a material that absorbs visible light, light emitted by the EL layer can be absorbed by the region 275, whereby light that might leak to an adjacent EL layer (stray light) can be reduced. Accordingly, a display apparatus that has high display quality can be provided.

When the white-light-emitting device (having a single structure or a tandem structure) and a light-emitting device having an SBS structure are compared to each other, the light-emitting device having an SBS structure can have lower power consumption than the white-light-emitting device. To reduce power consumption, the light-emitting device having an SBS structure is suitably used. Meanwhile, the white-light-emitting device is suitable in terms of lower manufacturing cost or higher manufacturing yield because the manufacturing process of the white-light-emitting device is simpler than that of the light-emitting device having an SBS structure.

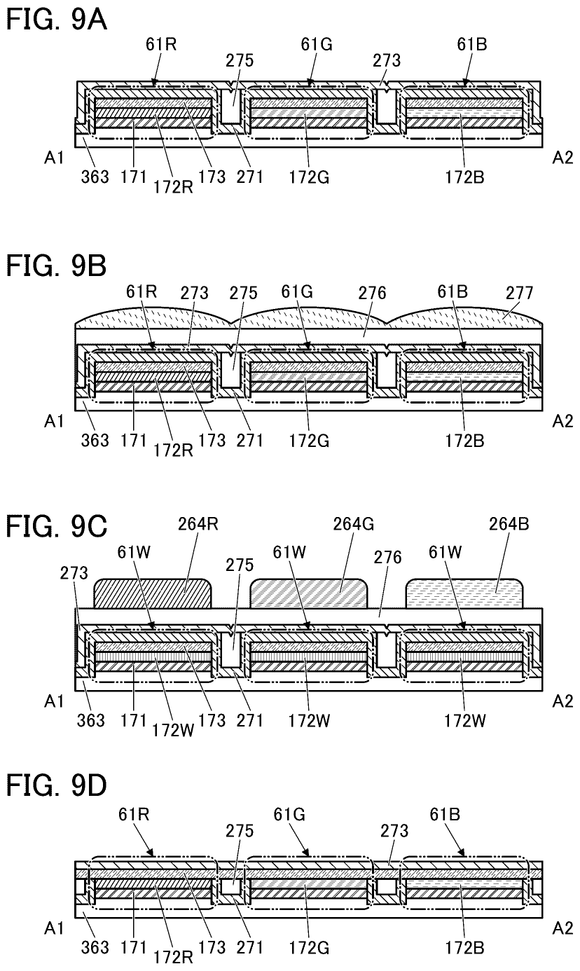

FIG. 9A illustrates an example different from the above. Specifically, the structure illustrated in FIG. 9A is different from the structure illustrated in FIG. 8D in the structure of the insulating layer 363. The insulating layer 363 has a recessed portion in its top surface that is formed by being partially etched when the light-emitting element 61R, the light-emitting element 61G, and the light-emitting element 61B are processed. In addition, the protective layer 271 is formed in the recessed portion. In other words, in the cross-sectional view, a region is provided, in which the bottom surface of the protective layer 271 is positioned below the bottom surface of the conductive layer 171. With the region, impurities (typically, water or the like) can be suitably inhibited from entering the light-emitting element 61R, the light-emitting element 61G, and the light-emitting element 61B from the bottom. The recessed portion can be formed when impurities (also referred to as residue) that could be attached to the side surfaces of the light-emitting element 61R, the light-emitting element 61G, and the light-emitting element 61B in processing of the light-emitting elements are removed by e.g., wet etching. After the residue is removed, the side surfaces of the light-emitting elements are covered with the protective layer 271, whereby a highly reliable display apparatus can be provided.

FIG. 9B illustrates an example different from the above. Specifically, the structure illustrated in FIG. 9B includes an insulating layer 276 and a microlens array 277 in addition to the structure illustrated in FIG. 9A. The insulating layer 276 functions as an adhesive layer. Note that when the refractive index of the insulating layer 276 is lower than that of the microlens array 277, the microlens array 277 can condense light emitted from the light-emitting element 61R, the light-emitting element 61G, and the light-emitting element 61B. This can increase the light extraction efficiency of the display apparatus. In particular, this is suitable, because a user can see bright images when the user sees the display surface from the front of the display apparatus. As the insulating layer 276, a variety of curable adhesives, e.g., a photocurable adhesive such as an ultraviolet curable adhesive, a reactive curable adhesive, a thermosetting adhesive, and an anaerobic adhesive can be used. As the adhesives, an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin can be given. In particular, a material with low moisture permeability, such as an epoxy resin, is preferred. A two-component-mixture-type resin may be used. An adhesive sheet or the like may be used.

FIG. 9C illustrates an example different from the above. Specifically, the structure illustrated in FIG. 9C includes three light-emitting elements 61W instead of the light-emitting element 61R, the light-emitting element 61G, and the light-emitting element 61B in the structure illustrated in FIG. 9A. In addition, the insulating layer 276 is provided over the three light-emitting elements 61W, and the coloring layer 264R, the coloring layer 264G, and the coloring layer 264B are provided over the insulating layer 276. Specifically, the coloring layer 264R transmitting red light is provided at a position overlapping with the left light-emitting element 61W, the coloring layer 264G transmitting green light is provided at a position overlapping with the middle light-emitting element 61W, and the coloring layer 264B transmitting blue light is provided at a position overlapping with the right light-emitting element 61W. Thus, the display apparatus can display color images. The structure illustrated in FIG. 9C is a modification example of the structure illustrated in FIG. 8C. Note that a coloring layer is referred to as a “color filter” in some cases.

Note that the light-emitting element 61W illustrated in FIG. 9C can have the above-described structure (a single structure or a tandem structure) that can emit white light. The tandem structure is suitable because high-luminance light emission can be obtained.

Furthermore, a display apparatus with a high contrast ratio can be obtained by combining the above-described structure (one or both of a single structure and a tandem structure) that can emit white light, a color filter, and the MIML structure of one embodiment of the present invention.

FIG. 9D illustrates an example different from the above. Specifically, in the structure illustrated in FIG. 9D, the protective layer 271 is provided to be adjacent to the side surfaces of the conductive layer 171 and the EL layer 172. The conductive layer 173 is provided as a continuous layer shared by the light-emitting elements. In the structure illustrated in FIG. 9D, the region 275 is preferably filled with a filler.

A color purity of the emission color can be increased when the light-emitting element 61 has a micro-optical resonator (microcavity) structure. In order that the light-emitting element 61 has a microcavity structure, a product of a distance d between the conductive layer 171 and the conductive layer 173 and a refractive index n of the EL layer 172 (optical path length) is set to m times greater than the half of a wavelength λ (m is an integer more than or equal to 1). The distance d can be obtained by Formula 1.

d=m×λ(2×n) Formula 1

According to Formula 1, in the light-emitting element 61 having the microcavity structure, the distance d is determined in accordance with the wavelength (emission color) of emitted light. The distance d corresponds to the thickness of the EL layer 172. Thus, the EL layer 172G is provided to have a larger thickness than the EL layer 172B, and the EL layer 172R is provided to have a larger thickness than the EL layer 172G in some cases.

To be exact, the distance d is a distance from a reflection region in the conductive layer 171 functioning as a reflective electrode to a reflection region in the conductive layer 173 functioning as a semi-transmissive and semi-reflective electrode. For example, in the case where the conductive layer 171 is a stack of silver and ITO that is a transparent conductive film and the ITO is positioned on the EL layer 172 side, the distance d suitable for the emission color can be set by adjusting the thickness of the ITO. That is, even when the EL layer 172R, the EL layer 172G, and the EL layer 172B have the same thickness, the distance d suitable for the emission color can be obtained by adjusting the thickness of the ITO.

However, it is sometimes difficult to determine the exact position of the reflection region in each of the conductive layer 171 and the conductive layer 173. In that case, it is assumed that the effect of the microcavity structure can be obtained sufficiently with a certain position in each of the conductive layer 171 and the conductive layer 173 being supposed as the reflective region.

The light-emitting element 61 includes a hole-injection layer, a hole-transport layer, a light-emitting layer, an electron-transport layer, an electron-injection layer, and the like. In order to increase the light extraction efficiency in the microcavity structure, the optical path length from the conductive layer 171 functioning as a reflective electrode to the light-emitting layer is preferably set to an odd multiple of λ/4. In order to achieve this optical path length, the thicknesses of the layers included in the light-emitting element 61 are preferably adjusted as appropriate.

In the case where light is extracted from the conductive layer 173 side, the reflectance of the conductive layer 173 is preferably higher than the transmittance thereof. The transmittance of the conductive layer 173 is preferably higher than or equal to 2% and lower than or equal to 50%, further preferably higher than or equal to 2% and lower than or equal to 30%, still further preferably higher than or equal to 2% and lower than or equal to 10%. When the transmittance of the conductive layer 173 is set low (the reflectance is set high), the effect of the microcavity structure can be enhanced.

### <Example of Stacked-Layer Structure>

Next, an example of a stacked-layer structure of the semiconductor device 100A is described with reference to a cross-sectional view.

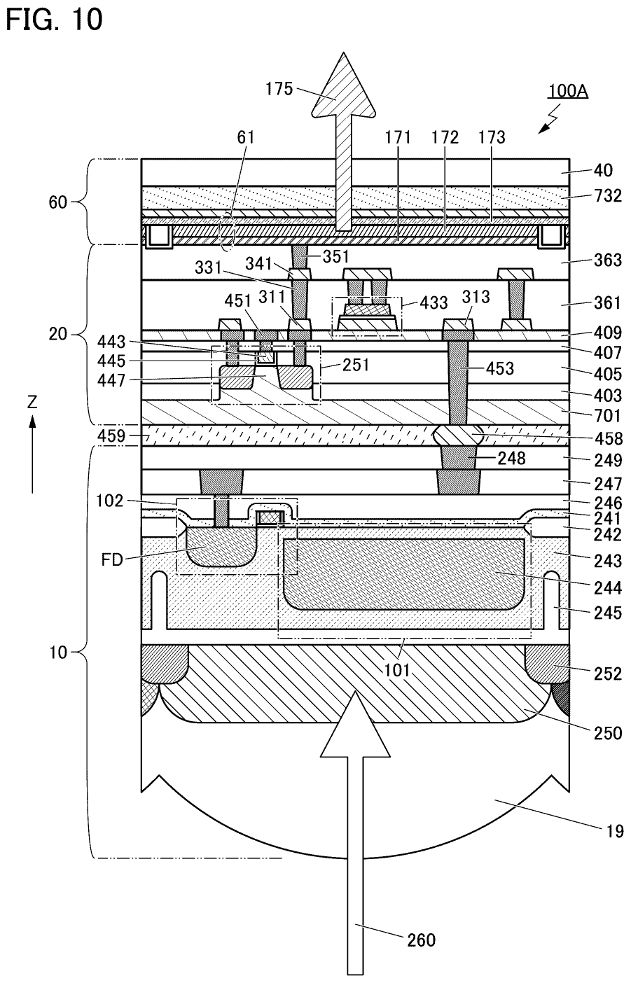

FIG. 10 is a cross-sectional view of part of the semiconductor device 100A. The semiconductor device 100A includes a bonding surface between the layer 10 and the layer 20. The layer 10 includes a light-blocking layer 252, an optical conversion layer 250 (a color filter), the microlens 19, the photoelectric conversion device 101, an insulating layer 241, an insulating layer 242, an insulating layer 245, an insulating layer 246, an insulating layer 247, and an insulating layer 249. A conductive layer 248 is embedded in the insulating layer 249. Here, the top surface of the conductive layer 248 and the top surface of the insulating layer 249 can be substantially level with each other.

The photoelectric conversion device 101 is a pn-junction photodiode formed in a silicon substrate and includes a p-type region 243 and an n-type region 244. The photoelectric conversion device 101 is a pinned photodiode, which can suppress dark current and reduce noise with the thin p-type region 243 provided on the surface side (current extraction side) of the n-type region 244.

The insulating layer 241 has a function of a blocking layer. The insulating layer 242 has a function of an element isolation layer. The insulating layer 245 has a function of suppressing carrier leakage.

The silicon substrate is provided with a groove that separates pixels, and the insulating layer 245 is provided on the top surface of the silicon substrate and in the groove. The insulating layer 245 can suppress leakage of carriers generated in the photoelectric conversion device 101 to an adjacent pixel. The insulating layer 245 also has a function of suppressing entry of stray light. Therefore, color mixture can be suppressed with the insulating layer 245. Note that an anti-reflection film may be provided between the top surface of the silicon substrate and the insulating layer 245.

The element isolation layer can be formed by a LOCOS (LOCal Oxidation of Silicon) method, an STI (Shallow Trench Isolation) method, or the like. As the insulating layer 245, for example, an inorganic insulating film of silicon oxide, silicon nitride, or the like or an organic insulating film of polyimide, an acrylic resin, or the like can be used. The insulating layer 245 may have a multilayer structure.

The layer 10 includes the transistor 102. The transistor 102 is a Si transistor. One of the source and the drain of the transistor 102 is directly connected to the photoelectric conversion device 101 and the other of the source and the drain of the transistor 102 functions as the node FD.

The transistor 102 is provided on a silicon substrate included in the layer 10. The transistor 102 is one of transistors included in the imaging pixel 12. Furthermore, another transistor included in the imaging pixel 12, and transistors included in the first driver circuit unit 13, the second driver circuit unit 14, the reading circuit unit 15, and the control circuit unit 16 are also provided on the silicon substrate.

As the first driver circuit unit 13, the second driver circuit unit 14, the reading circuit unit 15, and the control circuit unit 16, various circuits such as a shift register, a level shifter, an inverter, an analog switch, and a logic circuit can be used.

The n-type region 244 (corresponding to a cathode) of the photoelectric conversion device 101 is electrically connected to one of the source and the drain of the transistor 102 in the layer 10 through the thin p-type region. The p-type region 243 (anode) is electrically connected to a wiring functioning as a power supply line (not illustrated).

The light-blocking layer 252 can suppress entry of light into an adjacent pixel. As the light-blocking layer 252, a layer of a metal such as aluminum and tungsten can be used. The metal layer and a dielectric film functioning as an anti-reflection film may be stacked.

As the optical conversion layer 250, a color filter can be used. When color filters of R (red), G (green), B (blue), Y (yellow), C (cyan), M (magenta), and the like are assigned to different pixels, a color image can be obtained.

When a wavelength cut filter is used as the optical conversion layer 250, images in various wavelength regions can be obtained with the semiconductor device.

For example, when a filter that blocks light having a wavelength shorter than or equal to that of visible light is used as the optical conversion layer 250, an infrared imaging device can be obtained. When a filter that blocks light having a wavelength shorter than or equal to that of near infrared light is used as the optical conversion layer 250, a far-infrared imaging device can be obtained. When a filter that blocks light having a wavelength longer than or equal to that of visible light is used as the optical conversion layer 250, an ultraviolet imaging device can be obtained.

Furthermore, when a scintillator is used as the optical conversion layer 250, an imaging device that obtains an image visualizing the intensity of radiation, which is used as an X-ray imaging device or the like, can be obtained. When radiation such as X-rays passing through an object enters the scintillator, a photoluminescence phenomenon causes conversion into light (fluorescent light) such as visible light and/or ultraviolet light. Then, the photoelectric conversion device 101 detects the light to obtain imaging data. Furthermore, the imaging device having this structure may be used in a radiation detector or the like.

The scintillator contains a substance that absorbs energy of the radiation to emit visible light and/or ultraviolet light when the substance is irradiated with radiation such as X-rays and/or gamma-rays. For example, a resin or ceramics in which Gd₂O₂S:Tb, Gd₂O₂S:Pr, Gd₂O₂S:Eu, BaFCl:Eu, NaI, CsI, CaF₂, BaF₂, CeF₃, LiF, LiI, ZnO, or the like is dispersed can be used.

The microlens 19 is provided to overlap with the photoelectric conversion device 101. The photoelectric conversion device 101 is irradiated with light 260, which is entered from the outside and passes through the microlens 19 and the optical conversion layer 250. The microlens 19 enables the light 260 to be condensed and enter the photoelectric conversion device 101; thus, photoelectric conversion can be efficiently performed. The microlens 19 is preferably formed using a resin, glass, or the like with a high visible-light-transmitting property.

The layer 20 includes a substrate 701 and the transistor 251 is provided over the substrate 701. The transistor 251 is a transistor included in the display pixel circuit 431, for example.

As the substrate 701, for example, a single crystal semiconductor substrate such as a single crystal silicon substrate can be used. Note that a semiconductor substrate other than a single crystal semiconductor substrate may be used as the substrate 701. As the substrate 701, for example, an insulator substrate or a semiconductor substrate can be used. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate of silicon, germanium, or the like and a compound semiconductor substrate of silicon carbide, silicon germanium, gallium arsenide, indium phosphide, zinc oxide, or gallium oxide. Another example is a semiconductor substrate in which an insulator region is included in the semiconductor substrate, e.g., an SOI (Silicon On Insulator) substrate. There is no limitation on the crystallinity of the semiconductor substrate. A semiconductor substrate used as the substrate 701 may be a single crystal semiconductor substrate, a polycrystalline semiconductor substrate, or an amorphous semiconductor substrate. As the substrate 701, a printed wiring board (PWB) may be used.

In the case where a silicon substrate is used as the substrate 701, the transistor 251 is a Si transistor.

The transistor 251 is electrically isolated from other transistors by an element isolation layer 403. FIG. 10 illustrates the case where the transistor 251 and other transistors are electrically isolated from each other by the element isolation layer 403. The element isolation layer 403 can be formed by a LOCOS method, an STI method, or the like.

Here, in the transistor 251, a semiconductor region 447 has a projecting shape. Moreover, a conductive layer 443 is provided to cover a side surface and the top surface of the semiconductor region 447 with an insulating layer 445 therebetween. Note that FIG. 10 does not illustrate the state where the conductive layer 443 covers the side surface of the semiconductor region 447. A material adjusting the work function can be used for the conductive layer 443.

A transistor having a semiconductor region with a projecting shape, like the transistor 251, can be referred to as a fin-type transistor because a projecting portion of a semiconductor substrate is used. An insulator having a function of a mask for forming the projecting portion may be provided in contact with an upper portion of the projecting portion. Although FIG. 10 illustrates the structure in which the projecting portion is formed by processing part of the substrate 701, a semiconductor having a projecting shape may be formed by processing an SOI substrate.

Note that the structure of the transistor 251 illustrated in FIG. 10 is an example; the structure of the transistor 251 is not limited thereto and can be changed as appropriate in accordance with the circuit configuration, an operation method of the circuit, or the like. For example, the transistor 251 may be a planar transistor.

Over the substrate 701, an insulating layer 405, an insulating layer 407, an insulating layer 409, an insulating layer 361, and an insulating layer 363 are provided in addition to the element isolation layer 403 and the transistor 251. A conductive layer 451 is embedded in the insulating layer 409. Here, the top surface of the conductive layer 451 and the top surface of the insulating layer 409 can be substantially level with each other.

A conductive layer 453 is embedded in the insulating layer 407, the insulating layer 405, the element isolation layer 403, and the substrate 701. The conductive layer 453 functions as a Si through electrode (TSV: Through Silicon Via).

A conductive layer 311, a conductive layer 313, a conductive layer 331, and the capacitor 433 are embedded in the insulating layer 361. The conductive layer 311 and the conductive layer 313 each have a function as a wiring. The conductive layer 311 and the conductive layer 331 are electrically connected to the transistor 251.

Although FIG. 10 illustrates an example in which the capacitor 433 is provided over the insulating layer 409, the capacitor 433 may be provided over an insulator different from the insulating layer 409.

A conductive layer 341 and a conductive layer 351 are embedded in the insulating layer 363. Here, the top surface of the conductive layer 351 and the top surface of the insulating layer 363 can be substantially level with each other.

The insulating layer 405, the insulating layer 407, the insulating layer 409, the insulating layer 361, and the insulating layer 363 may each have a function as an interlayer film, and may each have a function as a planarization film that covers an uneven shape therebelow. For example, the top surface of the insulating layer 363 may be planarized by planarization treatment using a chemical mechanical polishing (CMP) method or the like to have the increased planarity.

The layer 10 and the layer 20 are connected to each other by an adhesive layer 459. Specifically, the adhesive layer 459 is provided between the insulating layer 249 and the substrate 701. Note that a bump 458 is embedded in the adhesive layer 459. The bump 458 has conductivity. Part of the bump 458 is electrically connected to the conductive layer 248 and another part thereof is electrically connected to the conductive layer 453. Thus, the layer 10 and the layer 20 are electrically connected to each other through the bump 458.

In this specification and the like, a structure in which two layers are bonded to each other with the use of a Si through electrode or bonding treatment thereof is referred to as a “TSV connection” or a “TSV junction” in some cases. Although the layer 10 and the layer 20 are bonded to each other by the TSV junction in this embodiment, the layers may be bonded to each other by a Cu—Cu junction described later.

The bonding between the layer 10 and the layer 20 is not limited to a bonding between flat surfaces of the layer 10 and the layer 20 and may be a bonding between a flat surface of one of the layers and a side surface of the other. The bonding between the side surfaces of the layers may be employed. The layer 10 and the layer 20 are not necessarily bonded to each other.

The layer 60 is provided over the layer 20. The layer 60 includes the light-emitting element 61. The light-emitting element 61 includes the conductive layer 171, the EL layer 172, and the conductive layer 173. The EL layer 172 contains an organic compound or an inorganic compound such as a quantum dot.

As an example of materials that can be used as an organic compound, a fluorescent material or a phosphorescent material can be given. As an example of materials that can be used as quantum dots, a colloidal quantum dot material, an alloyed quantum dot material, a core-shell quantum dot material, or a core quantum dot material can be given.

The conductive layer 171 is electrically connected to one of the source and the drain of the transistor 251 through the conductive layer 351, the conductive layer 341, and the conductive layer 311. The conductive layer 171 is formed over the insulating layer 363 and has a function of a pixel electrode.

A material that transmits visible light or a material that reflects visible light can be used for the conductive layer 171. As a light-transmitting material, for example, an oxide material containing indium and zinc; an oxide material containing indium, gallium, and zinc (also referred to as “IGZO”); an oxide material containing indium and tin (also referred to as “ITO”); an oxide material containing indium, tin, and silicon (also referred to as “ITSO”), or the like may be used. As a reflective material, for example, a material containing aluminum, silver, or the like may be used.

For example, in the case where light 175 emitted from the light-emitting element 61 is extracted from the conductive layer 173 side, the conductive layer 171 preferably contains a reflective material. The conductive layer 171 can have either a single-layer structure or a stacked-layer structure of a plurality of layers. For example, in the case where the conductive layer 171 is used as an anode, a three-layer structure in which silver is interposed between two ITO layers may be employed.

In the case where silicon nitride is contained in a formation surface with which the conductive layer 171 is in contact, a three-layer structure in which aluminum, titanium oxide, and ITO (or ITSO) are stacked in this order from the formation surface side may be employed for the conductive layer 171. In the case where silicon nitride is contained in a formation surface with which the conductive layer 171 is in contact, a two-layer structure in which aluminum and IGZO are stacked in this order from the formation surface side may be employed for the conductive layer 171.

Note that the semiconductor device 100A may be provided with an optical member such as a polarizing member, a retardation member, or an anti-reflection member in addition to the microlens 19.

The light-emitting element 61 illustrated in FIG. 10 can be a top-emission light-emitting element in which the light 175 is extracted from the conductive layer 173 side by using a reflective material for the conductive layer 171 and using a light-transmitting material for the conductive layer 173.

The semiconductor device 100A illustrated in FIG. 10 includes a filler layer 732 and a sealing substrate 40 which overlap with the light-emitting element 61. Although a solid sealing structure in which the filler layer 732 is provided between the light-emitting element 61 and the sealing substrate 40 is illustrated in this embodiment, a hollow sealing structure without the filling layer 732 may be employed. In the case where the semiconductor device 100A has a hollow sealing structure, part corresponding to the filler layer 732 may be filled with an inert gas containing one or both of a Group 18 element (a rare gas (a noble gas)) and nitrogen or the like. In the case where light emitted from the light-emitting element 61 is extracted to the sealing substrate 40 side, a light-transmitting material is preferably used for the adhesive layer 732.

Note that as the transistor included in the semiconductor device of one embodiment of the present invention, a transistor including a variety of semiconductors can be used. For example, a transistor including a single crystal semiconductor, a polycrystalline semiconductor, a microcrystalline semiconductor, or an amorphous semiconductor in a channel formation region can be used. Furthermore, a compound semiconductor (e.g., SiGe or GaAs), an oxide semiconductor, or the like can be used, as well as a single-element semiconductor including mainly a single element.

Note that as the transistor included in the semiconductor device of one embodiment of the present invention, a transistor with any of a variety of structures can be used. For example, a transistor with a variety of structures such as a planar type, a FIN-type, a TRI-GATE type, a top-gate type, a bottom-gate type, and a double-gate type (with gates placed above and below a channel) can be used. A MOS transistor, a junction transistor, a bipolar transistor, or the like can be used as the transistor included in the semiconductor device of one embodiment of the present invention.

### Application Example

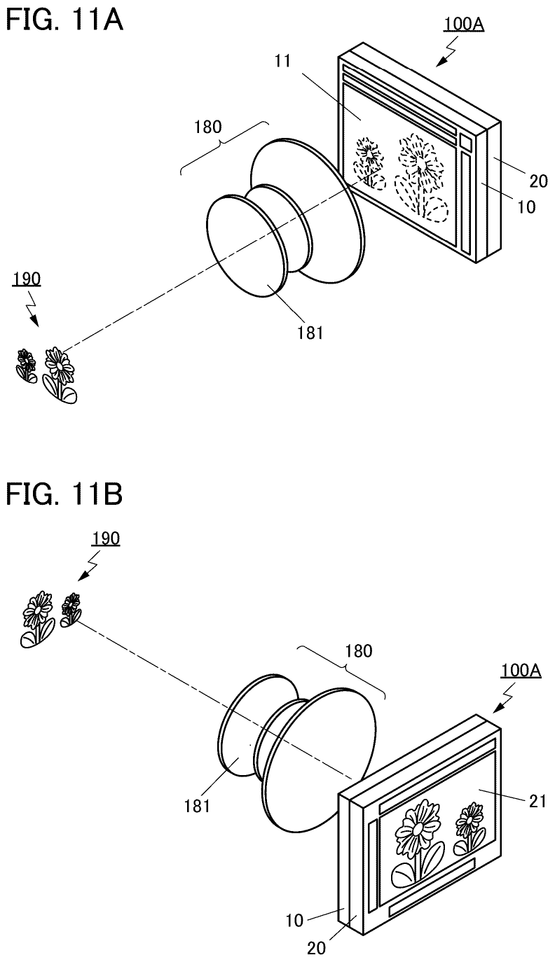

The semiconductor device of one embodiment of the present invention can shorten the time from taking an image of a subject to displaying the image. An application example of the semiconductor device of one embodiment of the present invention is illustrated in FIG. 11. FIG. 11A and FIG. 11B illustrate an example in which an image of the object 190 is taken by the semiconductor device 100A.

The subject image is projected onto the imaging unit 11 included in the layer 10 of the semiconductor device 100A through an optical member 180 including a lens 181 (see FIG. 11A). As the optical member 180, one or a plurality of a lens, a prism, a total-reflection mirror, a semi-transmission mirror (a half mirror), a polarizing member, a retardation member, an anti-reflection member, a shutter, and the like can be used.

A subject image projected onto the imaging unit 11 is converted into an electric signal in the imaging unit 11. The electric signal is transmitted to the layer 20 including the display unit 21. The electric signal transmitted to the layer 20 is reconstructed as a video and the video is displayed on the display unit 21 (see FIG. 11B).

The layer 10 and the layer 20 are provided to overlap with each other in the semiconductor device 100A of one embodiment of the present invention; thus, the subject image taken using the layer 10 can be immediately displayed on the display unit 21 included in the layer 20. That is, a time lag between taking an image of a subject and displaying the image can be reduced. One embodiment of the present invention has an excellent effect when a moving subject is photographed.

In the semiconductor device 100A of one embodiment of the present invention, the imaging unit 11 and the display unit 21 can be operated independently of each other. For example, the semiconductor device 100A of one embodiment of the present invention can operate only the display unit 21 without operating the imaging unit 11. The semiconductor device 100 A of one embodiment of the present invention can operate only the imaging unit 11 without operating the display unit 21. The semiconductor device 100A of one embodiment of the present invention can take an image using the imaging unit 11 while displaying an image that differs from the taken image on the display unit 21.

The resolution, the pixel density, the diagonal size, and the like of the imaging unit 11 do not necessarily correspond to those of the display unit 21. Furthermore, when seen in the Z direction, the semiconductor device 100A may, but do not necessarily, include a region where the imaging unit 11 and the display unit 21 overlap with each other.

In this embodiment, the case where the semiconductor device 100A includes the layer 10, the layer 20, and the layer 60 is described. However, the semiconductor device 100A of one embodiment of the present invention is not limited thereto. A structure may be employed in which at least one of the layer 10, the layer 20, and the layer 60 included in the semiconductor device 100A is not provided. Furthermore, another layer including a functional circuit such as a storage circuit may be provided in addition to the layer 10, the layer 20, and the layer 60.

The structures described in this embodiment can be used in an appropriate combination with the structures described in the other embodiments and the like.

### Embodiment 2

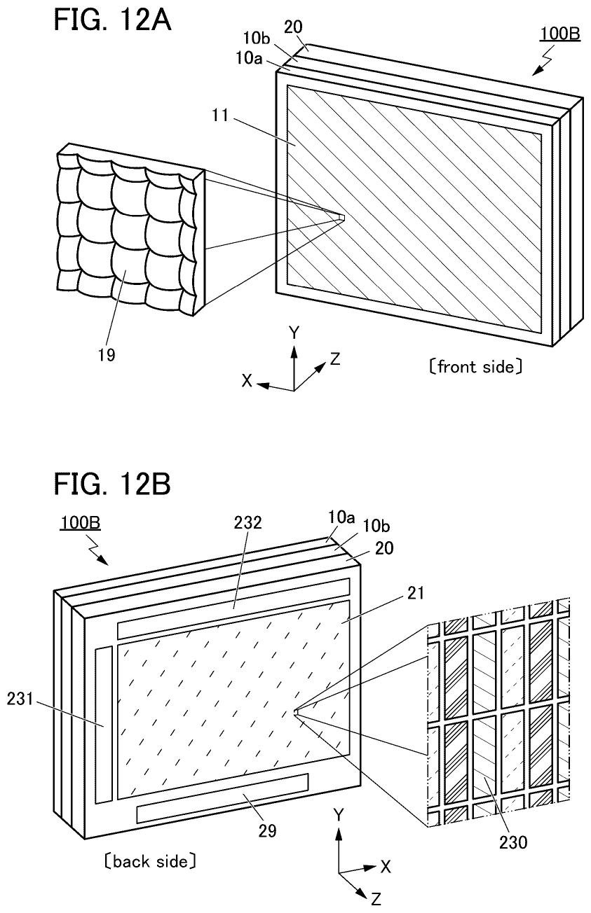

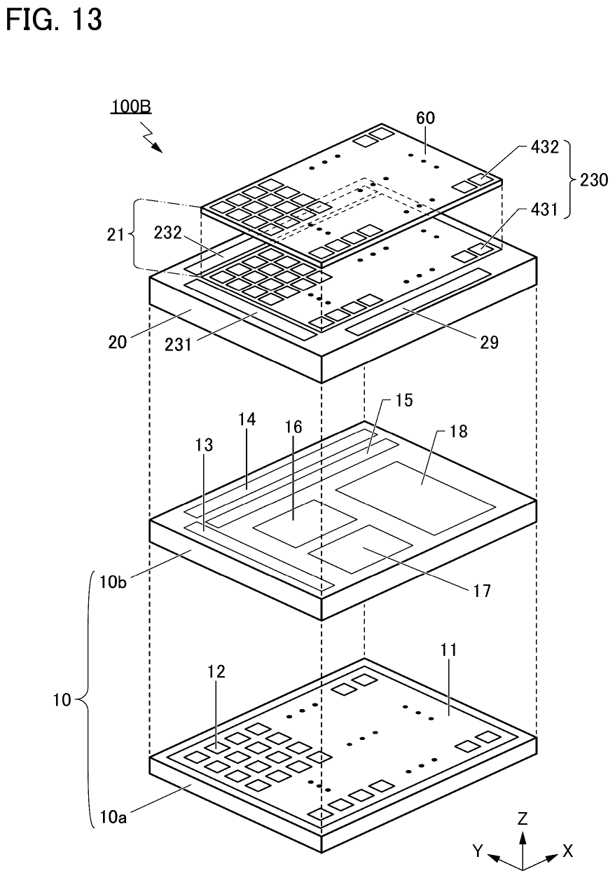

In this embodiment, a semiconductor device 100B, which is a modification example of the semiconductor device 100A, is described. The semiconductor device 100B differs from the semiconductor device 100A in the structure of the layer 10. FIG. 12 and FIG. 13 are perspective views illustrating a structure of the semiconductor device 100B. FIG. 12A is a perspective view of the front side of the semiconductor device 100B, and FIG. 12B is a perspective view of the back side of the semiconductor device 100B. In FIG. 13, the layer 10, the layer 20, and the like are separated and illustrated from each other for easy understanding of the structure of the semiconductor device 100B.

Note that in order to reduce repeated description, the structure of the semiconductor device 100B different from that of the semiconductor device 100A is mainly described in this embodiment. Descriptions in other embodiments and the like are referred to for the matters that are not described in this embodiment.

The layer 10 of the semiconductor device 100B includes a layer 10a and a layer 10b. The layer 10a and the layer 10b are provided to overlap with each other. The layer 10a includes the imaging unit 11, and the layer 10b includes the first driver circuit unit 13, the second driver circuit unit 14, the reading circuit unit 15, and the control circuit unit 16. The functional circuits provided in the same layer as the imaging unit 11 in the semiconductor device 100A are provided in a layer that differs from the layer in which the imaging unit 11 is provided, whereby the semiconductor device can be downsized.

When the imaging unit 11 and the functional circuit are stacked, the area occupied by the imaging unit 11 can be increased. Accordingly, the resolution of the imaging unit 11 can be increased. Furthermore, the area occupied by one pixel can be increased. Accordingly, the light sensitivity of the imaging element 11 can be increased. Moreover, the imaging quality of the semiconductor device 100B can be improved.

When the functional circuit is provided in a layer that differs from the layer in which the imaging unit 11 is provided, the area occupied by the functional circuit is decreased; thus, another functional circuit can also be mounted. FIG. 13 illustrates an example in which a DSP circuit unit 17 (Digital Signal Processor) and a storage circuit unit 18 are provided in the layer 10b. The DSP circuit unit 17 can perform various treatments on imaging data obtained by the imaging unit 11. The storage circuit unit 18 has a function of temporarily holding imaging data obtained by the imaging unit 11 and imaging data processed in the DSP circuit unit 17.

Storage devices of various storage systems can be used for the storage circuit unit 18. For example, a DRAM (Dynamic Random Access Memory), an SRAM (Static Random Access Memory), a phase-change memory (PCM), a resistive random access memory (ReRAM), a magnetoresistive random access memory (MRAM), a ferroelectric random access memory (FeRAM), an antiferroelectric memory, or the like may be used.

A flash memory may be used as the storage circuit unit 18. A NOSRAM (Nonvolatile Oxide Semiconductor Random Access Memory) or a DOSRAM (Dynamic Oxide Semiconductor Random Access Memory) may be used for the storage circuit unit 18. A NOSRAM and a DOSRAM are each a kind of storage devices using OS transistors.

The storage circuit unit 18 may include plural kinds of storage devices. For example, a nonvolatile storage device and a volatile storage device may be provided. The storage circuit unit 18 has a function of storing a variety of programs used in the semiconductor device 100B and holding data necessary for operating the semiconductor device 100B, and the like.

Note that the functional circuit included in the layer 10b does not necessarily include all the components described in this embodiment and the like, and can include components other than these. Some of the functional circuits may be provided in the layer 10a.

When the imaging unit 11, the first driver circuit unit 13, and the like are stacked, the wirings for electrical connection between them can be shortened. Thus, wiring resistance and parasitic capacitance can be lowered, so that the operation speed of the semiconductor device 100B can be increased. Furthermore, since wiring resistance and parasitic capacitance are lowered, the power consumption of the semiconductor device 100B is reduced.

### <Example of Stacked-Layer Structure>

Next, an example of a stacked-layer structure of the semiconductor device 100B is described with reference to a cross-sectional view.

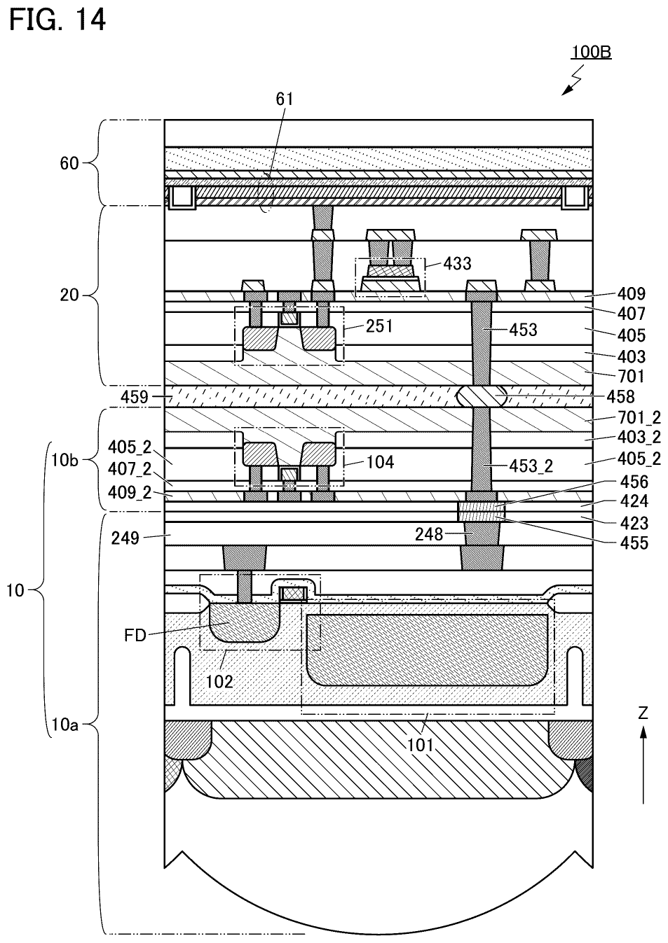

FIG. 14 is a cross-sectional view of part of the semiconductor device 100B. The semiconductor device 100B includes a bonding surface between the layer 10a and the layer 20 and a bonding surface between the layer 10a and the layer 10b. The bonding surface between the layer 10a and the layer 20 is similar to the bonding surface between the layer 10 and the layer 20 in the semiconductor device 100A.

The layer 10a has a structure in which an insulating layer 423 overlapping with the insulating layer 249 of the layer 10 is included and a conductive layer 455 is embedded in the insulating layer 423.

The layer 10b can have a structure similar to that of the layer 20. FIG. 14 illustrates an example in which a substrate 701_2, an element isolation layer 4032, an insulating layer 405_2, an insulating layer 4072, an insulating layer 4092, and a conductive layer 453_2 are included. The layer 10b includes the transistor 104. The transistor 104 can have a structure similar to that of the transistor 251. The layer 10b can include the other transistor, a capacitor, and the like.

The substrate 701_2 corresponds to the substrate 701, and the element isolation layer 403_2 corresponds to the element isolation layer 403. The same applies to the insulating layer 405_2, the insulating layer 4072, the insulating layer 4092, and the conductive layer 453_2.

The layer 10b has a structure in which an insulating layer 424 overlapping with the insulating layer 409_2 is provided and a conductive layer 456 is embedded in the insulating layer 424.

### [Bonding]

Next, bonding between the layer 10a and the layer 10b will be described.

Surfaces of the insulating layer 423 and the conductive layer 455 are planarized to be level with each other. Surfaces of the insulating layer 424 and the conductive layer 456 are planarized to be level with each other.

Here, main components of the conductive layer 455 and the conductive layer 456 are preferably the same metal element. Furthermore, the insulating layer 423 and the insulating layer 424 are preferably formed of the same component.

As the conductive layer 455 and the conductive layer 456, Cu, Al, Sn, Zn, W, Ag, Pt, or Au can be used, for example. Preferably, Cu, Al, W, or Au is used as easy bonding. In addition, for the insulating layer 423 and the insulating layer 424, silicon oxide, silicon oxynitride, silicon nitride oxide, silicon nitride, titanium nitride, or the like can be used.

That is, the same metal material described above is preferably used for the conductive layer 455 and the conductive layer 456. Furthermore, the same insulating material described above is preferably used for the insulating layer 423 and the insulating layer 424. With this structure, bonding where the boundary between the layer 10a and the layer 10b is a bonding position can be performed.

Note that the conductive layer 455 and the conductive layer 456 may each have a multilayer structure of a plurality of layers; in that case, outer layers (bonding surfaces) are formed of the same metal material. The insulating layer 423 and the insulating layer 424 may each have a multilayer structure of a plurality of layers; in that case, the outer layers (bonding surfaces) are formed of the same insulating material.

With the bonding, the electrical connection between the conductive layer 455 and the conductive layer 456 can be obtained. Moreover, the connection between the insulating layer 423 and the insulating layer 424 with mechanical strength can be obtained.

For bonding metal layers to each other, a surface activated bonding method in which an oxide film, a layer adsorbing impurities, and the like on surfaces are removed by sputtering treatment or the like and the cleaned and activated surfaces are brought into contact to be bonded to each other can be used. Alternatively, a diffusion bonding method in which the surfaces are bonded to each other by using temperature and pressure together can be used, for example. Both methods cause bonding at an atomic level, and therefore not only electrically but also mechanically excellent bonding can be obtained.

Furthermore, for bonding insulating layers to each other, a hydrophilic bonding method or the like can be used in which, after high planarity is obtained by polishing or the like, surfaces of the insulating layers subjected to hydrophilicity treatment with oxygen plasma or the like are brought into contact to be temporarily bonded to each other, and then dehydrated by heat treatment to perform final bonding. The hydrophilic bonding method can also cause bonding at an atomic level; thus, mechanically excellent bonding can be obtained.

When the layer 10a and the layer 10b are bonded to each other, the insulating layers and the metal layers coexist on their bonding surfaces; therefore, the surface activated bonding method and the hydrophilic bonding method are performed in combination, for example.

For example, it is possible to use a method in which the surfaces are made clean after polishing, the surfaces of the metal layers are subjected to antioxidant treatment and hydrophilicity treatment, and then bonding is performed. Furthermore, hydrophilicity treatment may be performed on the surfaces of the metal layers being hardly oxidizable metal such as Au. Note that a bonding method other than the above-mentioned methods may be used.

With the above bonding, the imaging unit 11 included in the layer 10a, the first driver circuit unit 13 included in the layer 10b, the second driver circuit unit 14, the reading circuit unit 15, and the like can be electrically connected to one another.

Note that when two layers are bonded to each other with the metal layers facing each other in this manner, Cu is often used for the metal layers. In this specification and the like, a structure in which two layers are bonded to each other with the metal layers included therein facing each other or bonding treatment thereof is referred to as a “Cu—Cu connection” or a “Cu—Cu junction” in some cases. Even when the metal layer does not contain Cu, the structure or the treatment is referred to as a “Cu—Cu connection” or a “Cu—Cu junction” in some cases.

Note that the layer 10b and the layer 20 may be bonded to each other by the Cu—Cu junction. The layer 10a and the layer 10b may be bonded to each other by the TSV junction.

The structures described in this embodiment can be used in an appropriate combination with the structures described in the other embodiments and the like.

### Embodiment 3

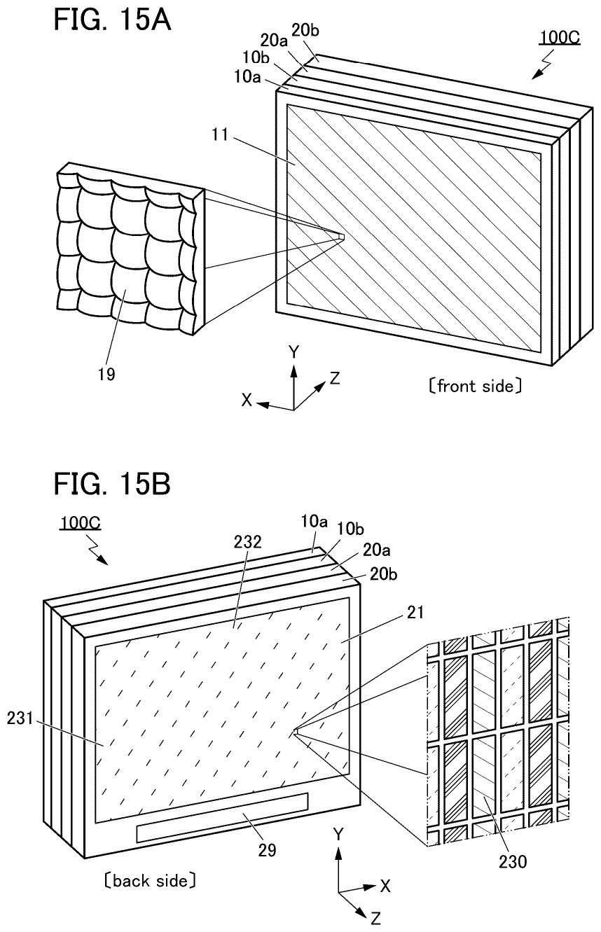

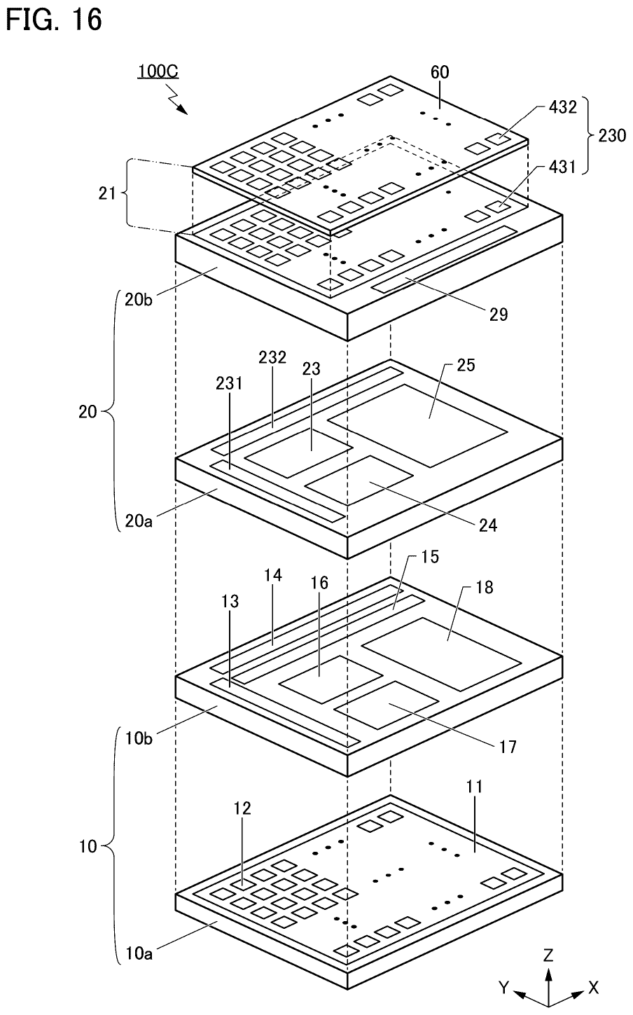

In this embodiment, a semiconductor device 100C, which is a modification example of the semiconductor device 100B, is described. The semiconductor device 100C differs from the semiconductor device 100B in the structure of the layer 20. FIG. 15 and FIG. 16 are perspective views illustrating a structure of the semiconductor device 100C. In FIG. 16, the layer 10 and the layer 20 and the like are separated and illustrated from each other for easy understanding of the structure of the semiconductor device 100C.

Note that in order to reduce repeated description, the structure of the semiconductor device 100C different from those of the semiconductor device 100A and the semiconductor device 100B is mainly described in this embodiment. Descriptions in other embodiments and the like are referred to for the matters that are not described in this embodiment.

The layer 20 of the semiconductor device 100C includes a layer 20a and a layer 20b. The layer 20a and the layer 20b are provided to overlap with each other. The layer 20a includes the first driver circuit unit 231 and the second driver circuit unit 232, and the layer 20b includes the display unit 21 and the input/output terminal unit 29. When the first driver circuit unit 231 and the second driver circuit unit 232 are provided in a layer that differs from the layer in which the display unit 21 is provided, the semiconductor device can be downsized.

The width of the bezel around the display unit 21 can be extremely small; thus, the area occupied by the display unit 21 can be increased. Consequently, the display quality of the semiconductor device 100C can be improved.

For example, the area occupied by one pixel can be increased. Accordingly, the emission luminance of the display unit 21 can be increased. In addition, the aperture ratio of the pixel can be increased. For example, the aperture ratio of the pixel can be greater than or equal to 40% and less than 100%, preferably greater than or equal to 50% and less than or equal to 95%, and further preferably greater than or equal to 60% and less than or equal to 95%. Moreover, an increase in the occupation area per pixel can reduce the density of current supplied to a pixel. Accordingly, the load applied to the pixel is reduced, so that the reliability of the semiconductor device 100C can be increased.

When the display unit 21, the peripheral driver circuit, and the like are stacked, the wirings for electrical connection between them can be shortened. Thus, wiring resistance and parasitic capacitance can be lowered, so that the operation speed of the semiconductor device 100C can be increased. Furthermore, the power consumption of the semiconductor device 100C is reduced.

The layer 20a includes a CPU (Central Processing Unit) 23, a GPU (Graphics Processing Unit) 24, and a storage circuit unit 25 in addition to the peripheral driver circuit.

The CPU 23 has a function of controlling operations of the GPU 24 and the circuit provided in the layer 20a, following the program stored in the storage circuit unit 25. The GPU 24 has a function of executing arithmetic processing for forming a video signal. Furthermore, the GPU 24 can execute a large number of matrix operations (product-sum operations) in parallel and thus, can execute arithmetic operation using a neural network at high speed, for example. The GPU 24 has a function of correcting a video signal using correction data stored in the storage circuit unit 25, for example. For example, the GPU 24 has a function of generating a video signal in which brightness, hue, and/or contrast, or the like is corrected.

Upconversion or downconversion of a video signal may be performed using the GPU 24. A super-resolution circuit may be provided in the layer 20a. The super-resolution circuit has a function of determining a potential of any pixel included in the display unit 21 by a product-sum operation of weights and potentials of pixels in the periphery of the pixel. The super-resolution circuit has a function of upconverting a video signal with a lower resolution than that of the display unit 21. The super-resolution circuit has a function of downconverting a video signal with a higher resolution than that of the display unit 21.

Providing the super-resolution circuit can reduce the load on the GPU 24. For example, the GPU 24 executes processing up to 2K resolution (or 4K resolution) and the super-resolution circuit performs upconversion to 4K resolution (or 8K resolution), whereby the load on the GPU 24 can be reduced. Consequently, the operating speed of the semiconductor device 100C can be increased. Down-conversion may be performed in a similar manner.

Note that the functional circuit included in the layer 20a does not necessarily include all of the circuits, and may include another structure. For example, a potential generating circuit that generate a plurality of different potentials, and/or a power management circuit for controlling supply and stop of electrical power for each circuit included in the semiconductor device 100C may be provided.

The supply and stop of electrical power may be performed per circuit included in the CPU 23. For example, power consumption can be reduced by stopping supply of electrical power to a circuit, which is determined to be not used for a while, of the circuits included in the CPU 23, and restarting the supply of electrical power to the circuit as needed. Data necessary for restarting supply of electrical power may be stored in a storage circuit in the CPU 23, the storage circuit unit 25, or the like before stopping the circuit. By storing data necessary for recovery of the circuit, high-speed recovery of the circuit stopped can be performed. Note that supply of a clock signal may be stopped to stop the circuit operation.

As the functional circuit, a DSP circuit, a sensor circuit, a communication circuit and/or FPGA (Field Programmable Gate Array) may be included, for example (not illustrated).

The sensor circuit has a function of obtaining information on one or more of the senses of sight, hearing, touch, taste, and smell of a human. Specifically, the sensor circuit has at least one of functions of sensing or measuring force, displacement, position, speed, acceleration, angular velocity, rotational frequency, distance, light, magnetism, temperature, sound, time, electric field, current, voltage, electric power, radiation, humidity, gradient, oscillation, a smell, and infrared rays. The sensor circuit may have a function other than sensing or measuring them.

The communication circuit has a wireless or wired communication function. In particular, the communication circuit preferably has a wireless communication function, in which case the number of parts such as a connection cable can be decreased.

In the case where the communication circuit has a wireless communication function, the communication circuit can perform communication via an antenna. As a communication protocol or a communication technology, a communications standard such as LTE (Long Term Evolution), GSM (Global System for Mobile Communication: registered trademark), EDGE (Enhanced Data Rates for GSM Evolution), CDMA2000 (Code Division Multiple Access 2000), or W-CDMA (registered trademark), or an IEEE communications standard such as Wi-Fi (registered trademark), Bluetooth (registered trademark), or ZigBee (registered trademark) can be used.

The communication circuit can perform input/output of information by connecting the semiconductor device 100C to another device via a computer network such as the Internet, which is an infrastructure of the World Wide Web (WWW), an intranet, an extranet, a PAN (Personal Area Network), a LAN (Local Area Network), a CAN (Campus Area Network), a MAN (Metropolitan Area Network), a WAN (Wide Area Network), or a GAN (Global Area Network).

As a transistor included in the layer 20b, an OS transistor is used in the semiconductor device 100C. The OS transistor has a feature of an extremely low off-state current. Consequently, the retention time for a video signal or the like can be increased, so that the frequency of the refresh operation can be reduced. Thus, the power consumption of the semiconductor device 100C can be reduced.

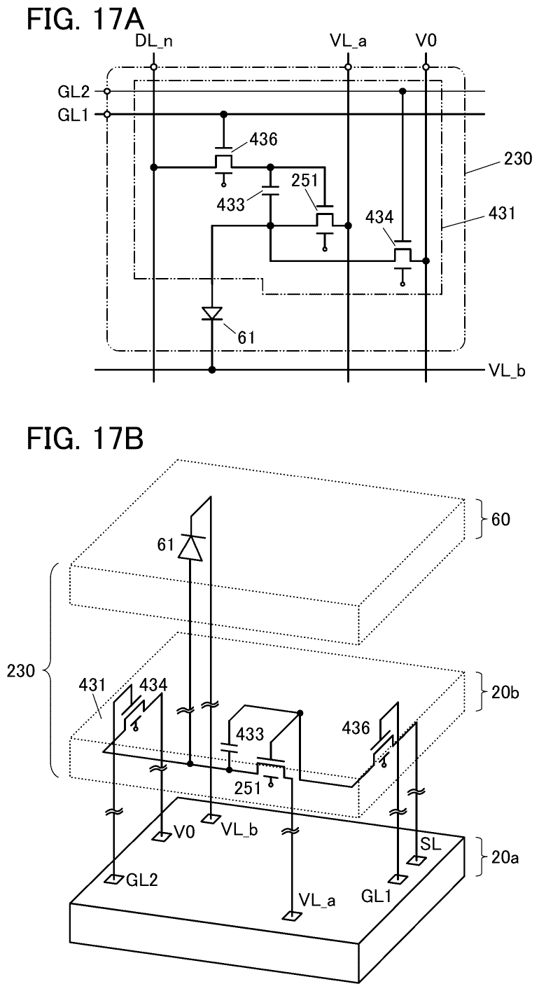

In FIG. 17A, an example of a circuit configuration of the display pixel 230 is illustrated. The display pixel 230 includes the display pixel circuit 431 and the light-emitting element 61. FIG. 17B schematically illustrates the vertical positional relation between the layer 20a including the peripheral driver circuit, the layer 20b including the display pixel circuit 431, and the layer 60 including the light-emitting element 61.

The display pixel circuit 431 illustrated as an example in FIG. 17A and FIG. 17B includes the transistor 436, the transistor 251, the transistor 434, and the capacitor 433. The transistor 436, the transistor 251, and the transistor 434 can be OS transistors. Each of the OS transistors of the transistor 436, the transistor 251, and the transistor 434 preferably includes a back gate electrode, in which case the back gate electrode can be supplied with the same signal as the gate electrode or the back gate electrode can be supplied with a signal different from that of the gate electrode.

The transistor 251 includes the gate electrode electrically connected to the transistor 436, a first terminal electrically connected to the light-emitting element 61, and a second terminal electrically connected to a potential supply line VL_a. The potential supply line VL_a is a wiring for supplying a potential for supplying current to the light-emitting element 61.

The transistor 436 includes a first terminal electrically connected to the gate electrode of the transistor 251 and a second terminal electrically connected to a wiring SL which functions as a source line, and the gate electrode which has a function of controlling its conduction state or non-conduction state on the basis of the potential of a wiring GL1 which functions as a gate line.

The transistor 434 includes a first terminal electrically connected to a wiring V0 and a second terminal electrically connected to the light-emitting element 61, and the gate electrode which has a function of controlling its conduction state or non-conduction state on the basis of the potential of a wiring GL2 which functions as a gate line. The wiring V0 is a wiring for supplying a reference potential and a wiring for outputting current flowing through the display pixel circuit 431 to the peripheral driver circuit.

The capacitor 433 includes a conductive film electrically connected to the gate electrode of the transistor 251 and a conductive film electrically connected to the second electrode of the transistor 434.

The light-emitting element 61 includes a first electrode electrically connected to the first terminal of the transistor 251 and a second electrode electrically connected to a potential supply line VL_b. The potential supply line VL_b is a wiring for supplying a potential for supplying current to the light-emitting element 61.

Accordingly, the intensity of light extracted from the light-emitting element 61 can be controlled in accordance with a video signal supplied to the gate electrode of the transistor 251. Furthermore, variations in the gate-source potential of the transistor 251 can be inhibited by the reference potential of the wiring V0 supplied through the transistor 434.

A current value that can be used for setting pixel parameters can be output from the wiring V0. Specifically, the wiring V0 can function as a monitor line for outputting a current flowing through the transistor 251 or a current flowing through the light-emitting element 61 to the outside. Current output to the wiring V0 may be converted into voltage by a source follower circuit or the like.

Note that in the structure example illustrated in FIG. 17B, the wiring electrically connecting the display pixel circuit 431 and the peripheral driver circuit can be shortened, so that wiring resistance of the wiring can be reduced. In addition, the parasitic capacitance of the wiring can be lowered. Thus, data can be written at high speed, which enables high-speed driving of the display unit 21. Therefore, even when the number of the display pixel circuit 431 is increased, a sufficient frame period can be ensured, and thus, the pixel density of the display unit 21 can be increased. In addition, the increased pixel density of the display unit 21 can increase the resolution of an image displayed on the display unit 21. For example, the pixel density of the display unit 21 can be higher than or equal to 1000 ppi, higher than or equal to 5000 ppi, or higher than or equal to 7000 ppi. Thus, the semiconductor device 100A can be used in display apparatuses for xR such as AR or VR, for example. The semiconductor device 100A of one embodiment of the present invention can be favorably used for an electronic apparatus whose display unit is close to a user, such as an HMD.

### <Example of Stacked-Layer Structure>

An example of a stacked-layer structure of the semiconductor device 100C is described with reference to a cross-sectional view.

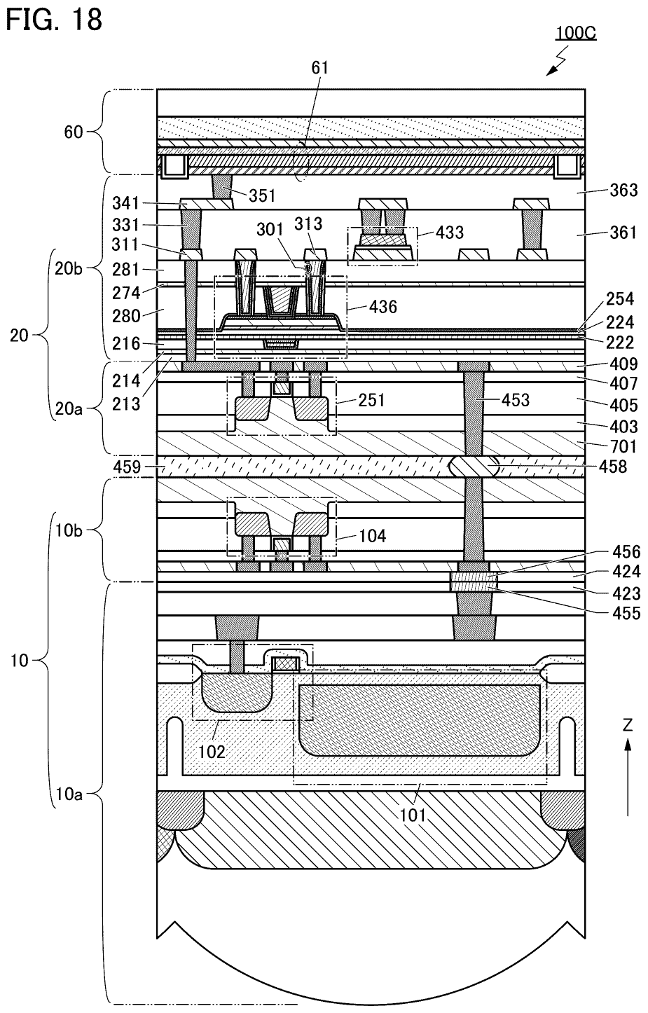

FIG. 18 is a cross-sectional view of part of the semiconductor device 100C. The layer 20a includes the substrate 701 and the transistor 251 is provided over the substrate 701. The layer 20a includes the element isolation layer 403, the insulating layer 405, the insulating layer 407, the insulating layer 409, and the conductive layer 453.

The layer 20b includes an insulating layer 213 and an insulating layer 214, and the transistor 436 is provided over the insulating layer 214. The transistor 436 is, for example, a transistor included in the display pixel circuit 431. An OS transistor can be suitably used as the transistor 436. The OS transistor has a feature of an extremely low off-state current. Consequently, the retention time for a video signal or the like can be increased, so that the frequency of the refresh operation can be reduced. Thus, the power consumption of the semiconductor device 100C can be reduced.

The layer 20b includes an insulating layer 216, an insulating layer 222, an insulating layer 224, an insulating layer 254, an insulating layer 280, an insulating layer 274, an insulating layer 281, the insulating layer 361, and the insulating layer 363. A conductive layer 301 is embedded in the insulating layer 254, the insulating layer 280, the insulating layer 274, and the insulating layer 281. The conductive layer 301 is electrically connected to one of the source and the drain of the transistor 436. Here, the top surface of the conductive layer 301 and the top surface of the insulating layer 281 can be substantially level with each other.

The conductive layer 311 and the conductive layer 313 are embedded in the insulating layer 361. The conductive layer 311 is electrically connected to one of the source and the drain of the transistor 251. The conductive layer 313 is electrically connected to the transistor 436 through the conductive layer 301. The conductive layer 313 has a function as a wiring.

The insulating layer 213, the insulating layer 214, the insulating layer 216, the insulating layer 280, the insulating layer 274, and the insulating layer 281 each have a function of an interlayer film and may each have a function of a planarization film that covers an uneven shape therebelow. For example, the top surface of the insulating layer 281 may be planarized by planarization treatment using a CMP method or the like to have the increased planarity.

Note that the semiconductor device 100C illustrated in FIG. 18 includes an OS transistor and a light-emitting device having an MML (metal maskless) structure. With this structure, the leakage current that might flow through the transistor and the leakage current that might flow between adjacent light-emitting elements (also referred to as a lateral leakage current, a side leakage current, or the like) can become extremely low. With the structure, a viewer can notice any one or more of the image crispness, the image sharpness, a high chroma, and a high contrast ratio in an image displayed on the display unit 21. When the leakage current that might flow through the transistor and the lateral leakage current that might flow between light-emitting elements are extremely low, display with little leakage of light at the time of black display (i.e., with few phenomena in which the black image looks whitish) (such display is also referred to as deep black display) can be achieved.

In particular, in the case where a light-emitting device having an MML structure employs the above-described SBS structure, a layer provided between light-emitting elements (for example, also referred to as an organic layer or a common layer which is commonly used between the light-emitting elements) is disconnected; accordingly, display with no or extremely small lateral leakage can be achieved.

The structures described in this embodiment can be used in an appropriate combination with the structures described in the other embodiments and the like.

### Embodiment 4

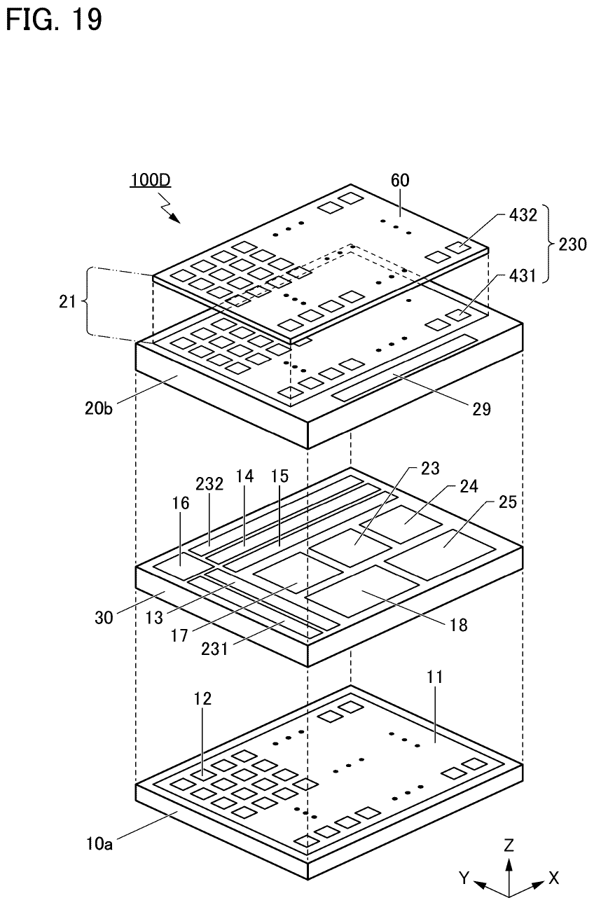

In this embodiment, a semiconductor device 100D, which is a modification example of the semiconductor device 100C, is described. The semiconductor device 100D includes a layer 30 in which the functions of the layer 10b and the layer 20a, which are described in the description of the semiconductor device 100C, are integrated. FIG. 19 is a perspective view illustrating a structure of the semiconductor device 100D. In FIG. 19, the layer 10a and the layer 30 and the like are separated and illustrated from each other for easy understanding of the structure of the semiconductor device 100D.

Note that in order to reduce repeated description, the structure of the semiconductor device 100D different from that of the semiconductor device 100C is mainly described in this embodiment. Descriptions in other embodiments and the like are referred to for the matters that are not described in this embodiment.

The layer 30 included in the semiconductor device 100D is provided between the layer 10a and the layer 20b. The layer 30 illustrated in FIG. 19 includes the first driver circuit unit 13, the second driver circuit unit 14, the reading circuit unit 15, the control circuit unit 16, the DSP circuit unit 17, the storage circuit unit 18, the first driver circuit unit 231, the second driver circuit unit 232, the CPU 23, the GPU 24, and the storage circuit unit 25. Note that the layer 30 does not necessarily include all of the above functional circuits. The layer 30 may be provided with a circuit other than the above. Some of the functional circuits may be provided in the layer 10a and/or the layer 20b.

When the layer 10b and the layer 20a are integrated into the layer 30, the number of the components of the semiconductor device 100D can be reduced. Thus, the productivity of the semiconductor device 100D can be increased. Furthermore, when the number of the components is reduced, the number of the connection portions between the components is reduced; thus, the reliability of the semiconductor device is improved.

### <Example of Stacked-Layer Structure>

An example of a stacked-layer structure of the semiconductor device 100D is described with reference to a cross-sectional view.

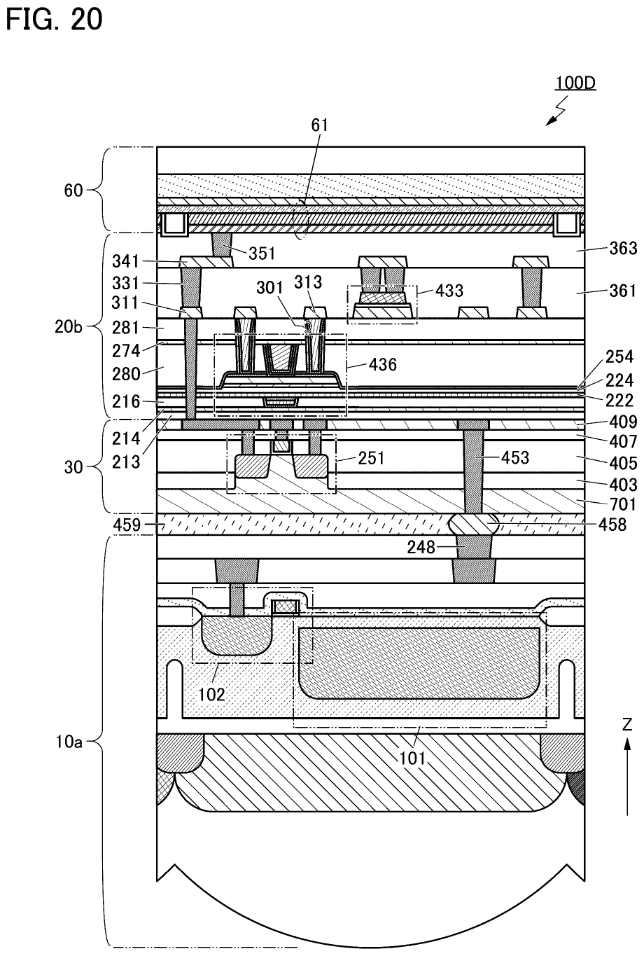

FIG. 20 is a cross-sectional view of part of the semiconductor device 100D. The layer 30 has a structure similar to that of the layer 20a. The layer 30 and the layer 10a are electrically connected to each other by the TSV junction. Note that the layer 30 and the layer 10a may be electrically connected to each other by the Cu—Cu junction.

The structures described in this embodiment can be used in an appropriate combination with the structures described in the other embodiments and the like.

### Embodiment 5

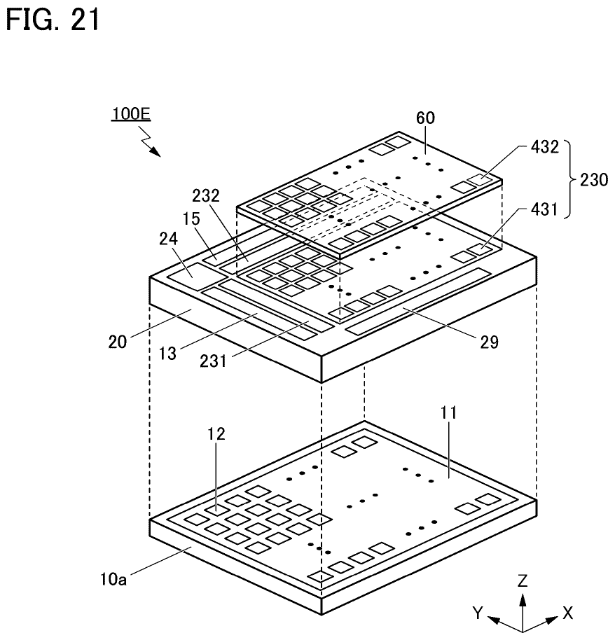

In this embodiment, a semiconductor device 100E, which is a modification example of the semiconductor device 100B, is described. The layer 20 of the semiconductor device 100E has the function of the layer 10b described in the description of the semiconductor device 100B. FIG. 21 is a perspective view illustrating a structure of the semiconductor device 100E. In FIG. 21, the layer 10a and the layer 20 and the like are separated and illustrated from each other for easy understanding of the structure of the semiconductor device 100E.

Although the control circuit unit 16, the DSP circuit unit 17, and the storage circuit unit 18 are not illustrated in the layer 20 in FIG. 21, the semiconductor device 100E may include some or all of the above functional circuits and other functional circuits.

### <Example of Stacked-Layer Structure>

The stacked-layer structure of the semiconductor device 100E is similar to that of the cross-sectional structure example of the semiconductor device 100A illustrated in FIG. 10; thus, detailed description thereof is omitted. Regarding an example of a stacked-layer structure of the semiconductor device 100E, the layer 10a illustrated in FIG. 10 may be replaced with the layer 10.

The structures described in this embodiment can be used in an appropriate combination with the structures described in the other embodiments and the like.

### Embodiment 6

In this embodiment, an example of a connection structure of the imaging unit 11 and the display unit 21 is described.

As described in the above embodiment, the semiconductor device 100 (the semiconductor device 100A to the semiconductor device 100E) of one embodiment of the present invention has a function of reading out a subject image projected onto the imaging unit 11 and displaying the subject image which is read out on the display unit 21. The imaging unit 11 and the display unit 21 include a region overlapping with each other in the Z direction.

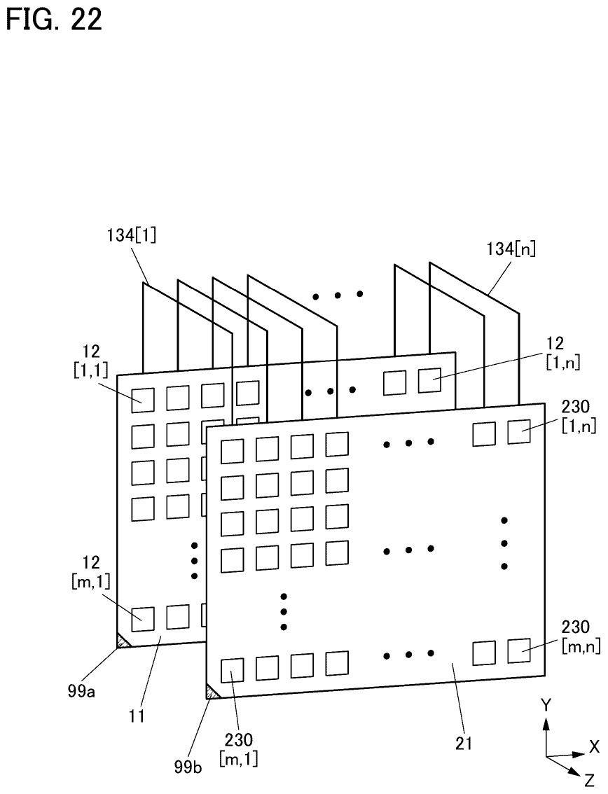

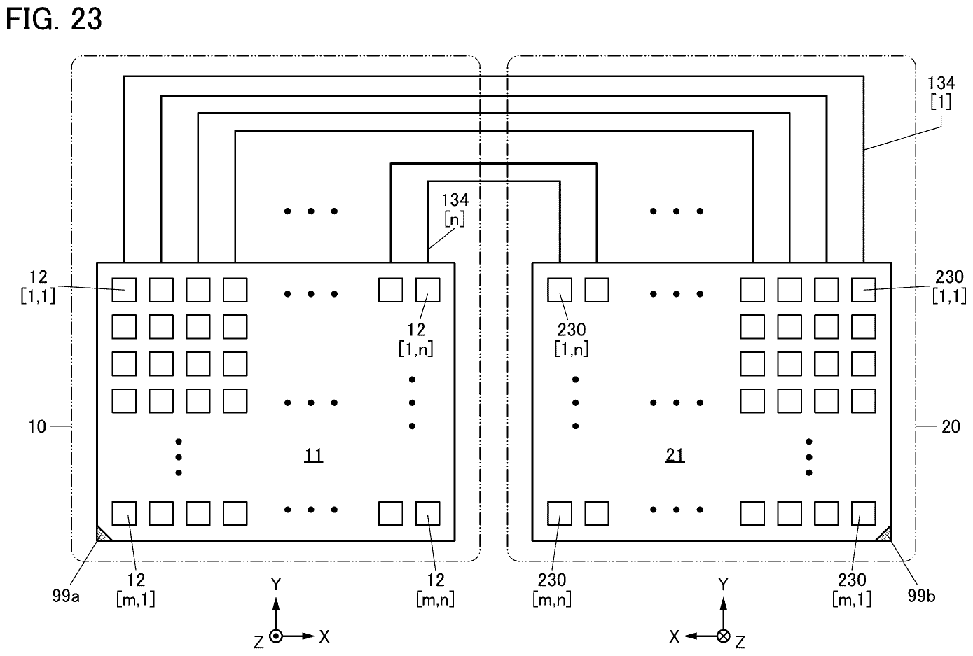

FIG. 22 is a perspective view illustrating a state in which the imaging unit 11 and the display unit 21 overlap with each other. FIG. 23 illustrates a state in which the imaging unit 11 and the display unit 21 in FIG. 22 are separated from each other. FIG. 22 and FIG. 23 each correspond to, for example, a structure example of the semiconductor device 100A. In this embodiment, for easy understanding of the state in which the imaging unit 11 and the display unit 21 overlap with each other, a corner of the imaging unit 11 is indicated by a mark 99a and a corner of the display unit 21 is indicated by a mark 99b. As illustrated in FIG. 22, in the case where the mark 99a is in the lower left of the imaging unit 11, the imaging unit 11 and the display unit 21 overlap with each other so that the mark 99b is to be also in the lower left of the display unit 21. In other words, the imaging unit 11 and the display unit 21 overlap with each other so that the mark 99a and the mark 99b correspond or substantially correspond to each other.

In the drawings used for this embodiment, the description of the peripheral driver circuit and the function circuit is not illustrated for easy understanding of the connection structure between the imaging unit 11 and the display unit 21.

FIG. 22 and FIG. 23 illustrate an example of a connection structure in which the imaging unit 11 and the display unit 21 have the same resolution. That is, the imaging unit 11 includes the imaging pixels 12 arranged in a matrix of m rows and n columns, and the display unit 21 includes the display pixels 230 arranged in a matrix of m rows and n columns.

In FIG. 22 and FIG. 23, the imaging unit 11 and the display unit 21 are electrically connected to each other through n wirings 134. Specifically, the imaging pixels 12 in the first column are electrically connected to the display pixels 230 in the first column through the first wiring 134 (wiring 134[1]). Similarly, the imaging pixels 12 in the n-th column are electrically connected to the display pixels 230 in the n-th column through the n-th wiring 134 (wiring 134[n]). Note that the wiring 134 may be formed in a manner similar to that of the conductive layer 248, the conductive layer 453, and the like described in the above embodiment. For example, the TSV junction, the Cu—Cu junction, or the like may be used. Alternatively, a wire bonding method or the like may be used.

When the imaging pixels 12 and the display pixels 230 are electrically connected to each other through the wiring 134 in each column, imaging data of all columns in each row obtained by the imaging unit 11 can be supplied to the display unit 21 as a video signal without change.

Specifically, imaging data of the n imaging pixels 12 (the imaging pixel 12[1,1] to the imaging pixel 12[1,n]) in the first row can be supplied to the n respective display pixels 230 (the display pixel 230[1,1] to the display pixel 230[1,n]) in the first row as video signals without change.

In the structure illustrated in FIG. 22 and FIG. 23, a subject image obtained by the imaging unit 11 can be immediately displayed on the display unit 21; thus, a time lag between taking an image and displaying the image can be reduced. Accordingly, deviation from proper photographing timing is reduced. Furthermore, having an accurate framework can be achieved.

### Modification Example 1

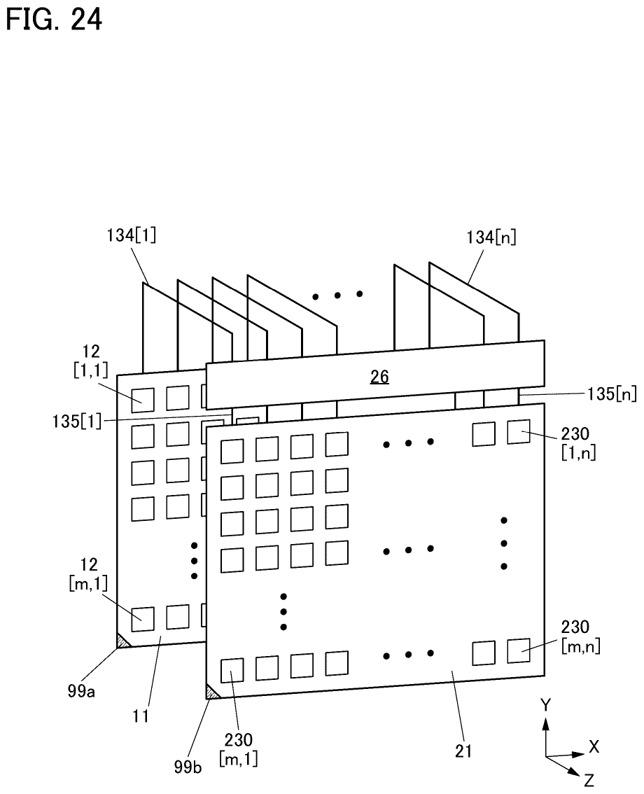

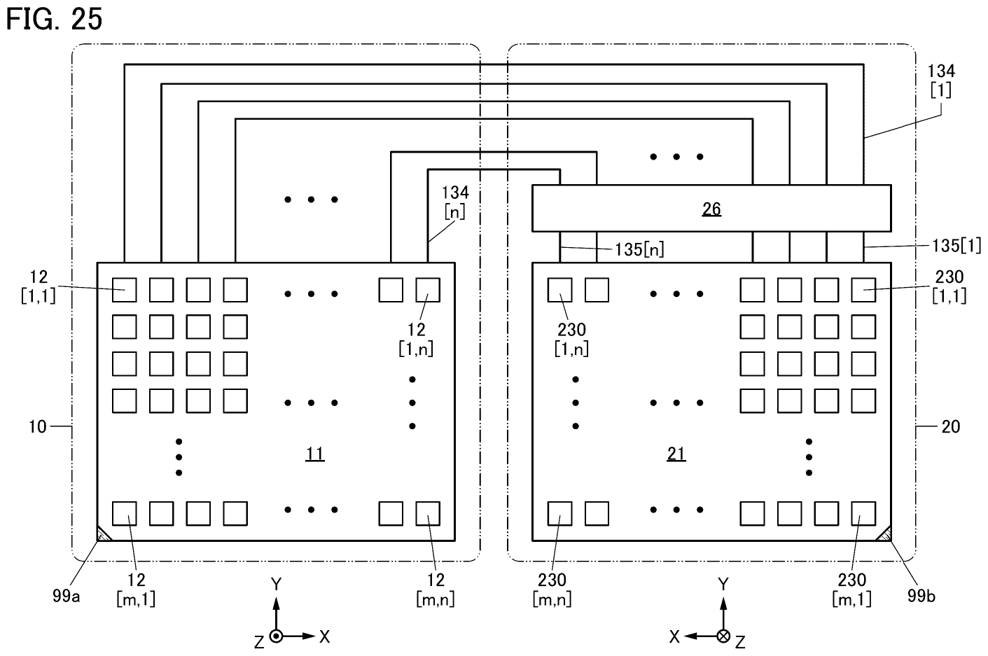

FIG. 24 and FIG. 25 illustrate a modification example of the structure illustrated in FIG. 22 and FIG. 23. FIG. 24 is a perspective view illustrating the state where the imaging unit 11 and the display unit 21 overlap with each other. FIG. 25 illustrates a state where the imaging unit 11 and the display unit 21 illustrated in FIG. 24 are separated from each other.

FIG. 24 and FIG. 25 illustrate a structure example in which an analog potential control circuit 26, which is a kind of a functional circuit, is included between the imaging unit 11 and the display unit 21. The n wirings 134 are each electrically connected to the analog potential control circuit 26. The analog potential control circuit 26 is electrically connected to the columns of a plurality of display pixels 230 included in the display unit 21 through n wirings 135.

The analog potential control circuit 26 has a function of performing voltage adjustment, polarity conversion, electric amplification, and the like of imaging data supplied from the imaging unit 11. Thus, the analog potential control circuit 26 can be regarded as having a function of converting an imaging signal into a video signal.

As the imaging data obtained by the imaging unit 11, imaging data of all columns is supplied to the analog potential control circuit 26 row by row. The analog potential control circuit 26 converts imaging data input through the wiring 134 into a video signal and supplies the video signal to the display unit 21 through the wiring 135. Specifically, imaging data supplied to the analog potential control circuit 26 through the wiring 134[1] is converted into a video signal by the analog potential control circuit 26 and supplied to the display unit 21 through the wiring 135[1]. Similarly, imaging data supplied to the analog potential control circuit 26 through the wiring 134[n] is converted into a video signal by the analog potential control circuit 26 and supplied to the display unit 21 through the wiring 135[n].

According to one embodiment of the present invention, imaging data obtained by the imaging unit 11 can be converted into a video signal more suitable for display in the display unit 21 by the analog potential control circuit 26. For example, a semiconductor device which is hardly affected by noise and has favorable display quality can be achieved.

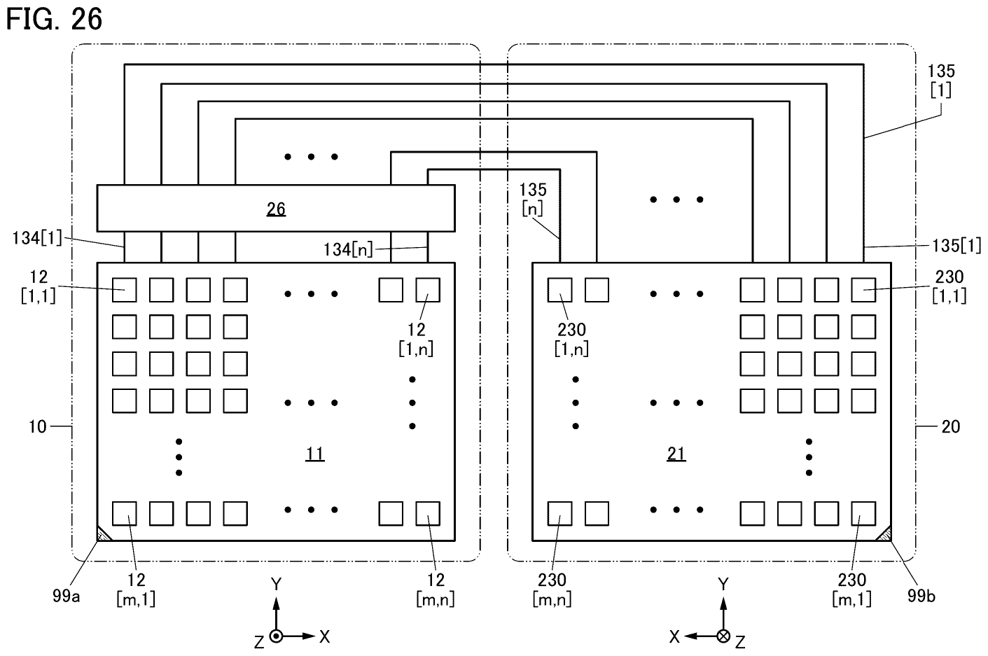

Note that although the example in which the analog potential control circuit 26 is provided in the layer 20 is described in this embodiment, the analog potential control circuit 26 may be provided in the layer 10 (see FIG. 26). The wiring 135 may be formed in a manner similar to that of the conductive layer 248, the conductive layer 453, and the like described in the above embodiment. For example, the TSV junction, the Cu—Cu junction, or the like may be used. Alternatively, a wire bonding method or the like may be used. The analog potential control circuit 26 may be provided in the layer 30 of the semiconductor device 100D described in the above embodiment, for example.

### Modification Example 2

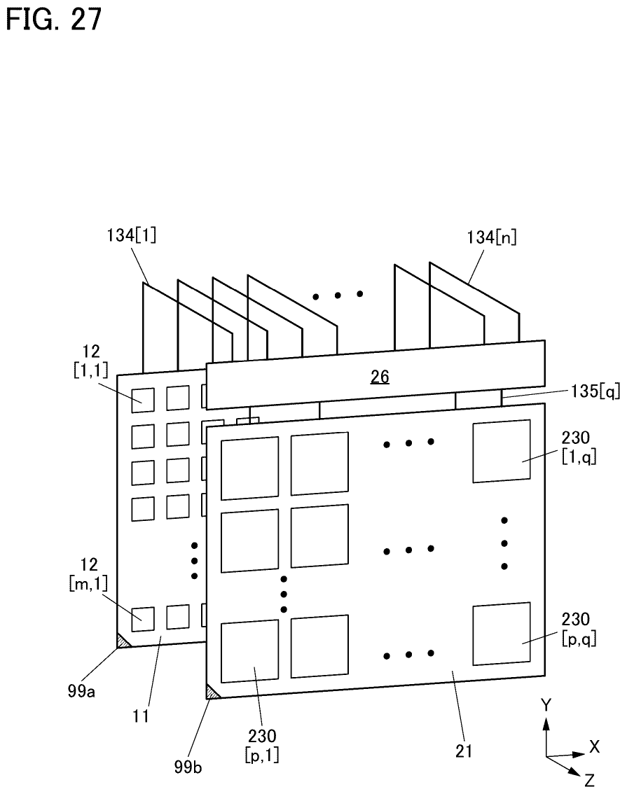

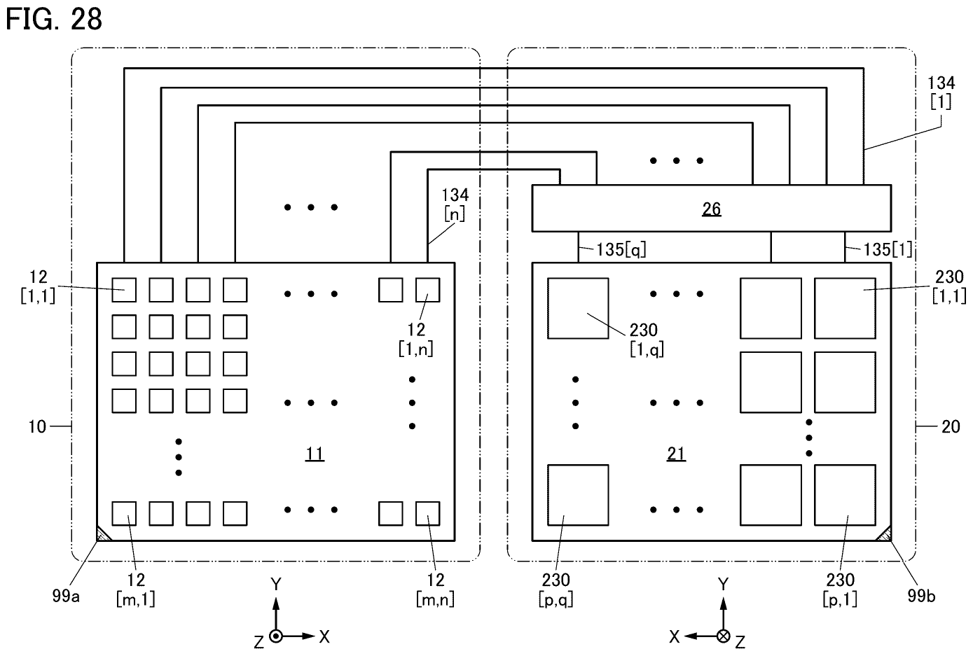

In addition, in the case where the resolution of the imaging unit 11 is different from that of the display unit 21, the number of video signals output in the analog potential control circuit 26 may be adjusted. FIG. 27 and FIG. 28 illustrate an example in which the imaging unit 11 includes the imaging pixels 12 arranged in a matrix of m rows and n columns, and the display unit 21 includes the display pixels 230 arranged in a matrix of p rows and q columns. Although FIG. 27 and FIG. 28 illustrate the case where p is smaller than m and q is smaller than n, the magnitude relation can be reversed, or p can be equal to m.

FIG. 27 and FIG. 28 illustrate a structure example in which imaging data is supplied to the analog potential control circuit 26 through the n wirings 134 and the video signal is supplied to the display unit 21 through the q wirings 135.

When q is smaller than n, for example, imaging data of the corresponding column may be deleted at given intervals. When q is larger than n, the average value, the weighted average value, or the like of a video signal of the column adjacent to an additional column can be used for a video signal of the additional column.

When p is smaller than m, for example, imaging data of the corresponding row may be deleted at given intervals. When p is larger than m, the average value, the weighted average value, or the like of a video signal of the row adjacent to an additional row can be used for a video signal of the additional row.

As described in the above embodiment, upconversion processing, downconversion processing, or the like of a video signal may be performed using the GPU, the super-resolution circuit, or the like.

### Modification Example 3

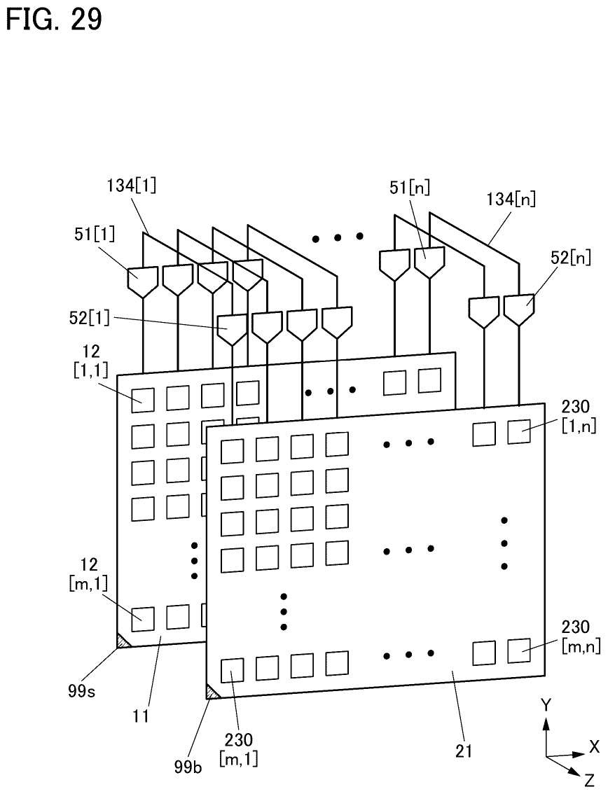

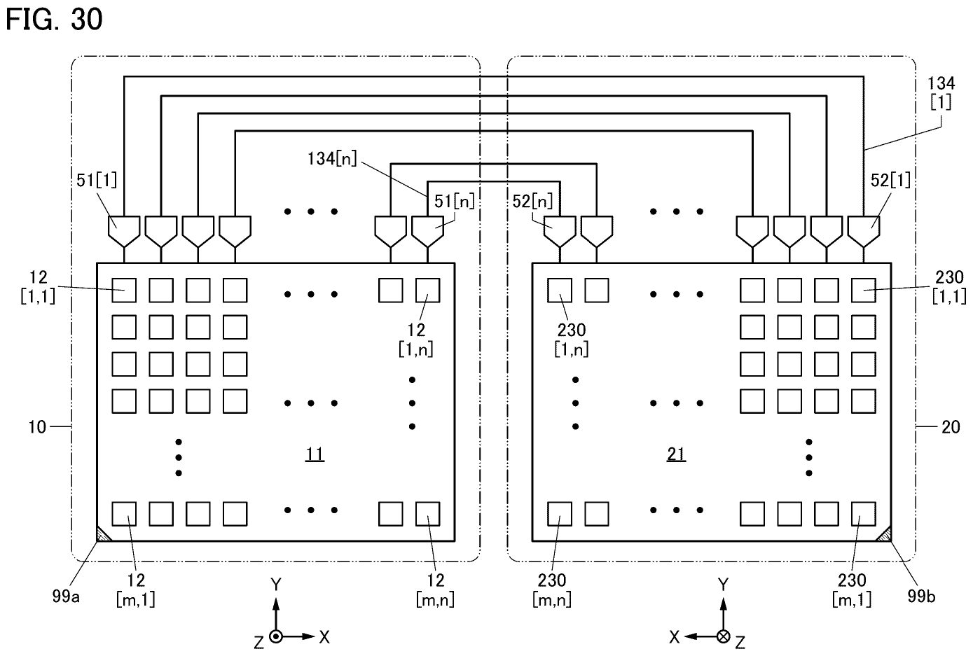

As shown in FIG. 29 and FIG. 30, an ADC (Analog-to-Digital Converter) 51 may be provided in each column of the imaging unit 11. As the ADC 51, a variety of ADCs such as a successive approximation-type ADC, a delta-sigma-type ADC, and a pipeline-type ADC can be used. Each column of the display unit 21 may include a DAC (Digital-to-Analog Converter) 52. As the DAC 52, a variety of DACs such as a segment-type DAC, a switched capacitor-type DAC, and a delta-sigma-type DAC can be used.

In FIG. 29 and FIG. 30, the ADC 51 provided between the imaging pixels 12 in the first column and the first wiring 134 is denoted as an ADC 51[1] and the ADC 51 provided between the imaging pixels 12 in the n-th column and the n-th wiring 134 is denoted as an ADC 51[n].

In FIG. 29 and FIG. 30, the DAC 52 provided between the display pixels 230 in the first column and the first wiring 134 is denoted as a DAC 52[1] and the DAC 52 provided between the display pixels 230 in the n-th column and the n-th wiring 134 is denoted as a DAC 52[n].

The imaging data of the imaging pixel 12 is an analog signal. The imaging data is converted into a digital signal by the ADC 51 and input to the DAC 52 through the wiring 134. The DAC 52 converts imaging data that is a digital signal into an analog signal. The imaging data converted into an analog signal is supplied as a video signal to the display pixel 230.

A digital signal has higher resistance to noise than an analog signal; accordingly, a stable data transfer can be achieved. Although FIG. 30 illustrates an example in which the ADC 51 is provided in the layer 10 and the DAC 52 is provided in the layer 20, one or both of the ADC 51 and the DAC 52 may be provided in the layer 30 of the semiconductor device 100D described in the above embodiment, for example.

### Modification Example 4

By converting an analog signal into a digital signal, arithmetic processing of imaging data (image processing) is facilitated, so that a variety of image processing can be performed. For example, it becomes easier to adjust contrast, luminance, and chroma and to execute arithmetic processing such as compressing/decompressing data and a product-sum operation.

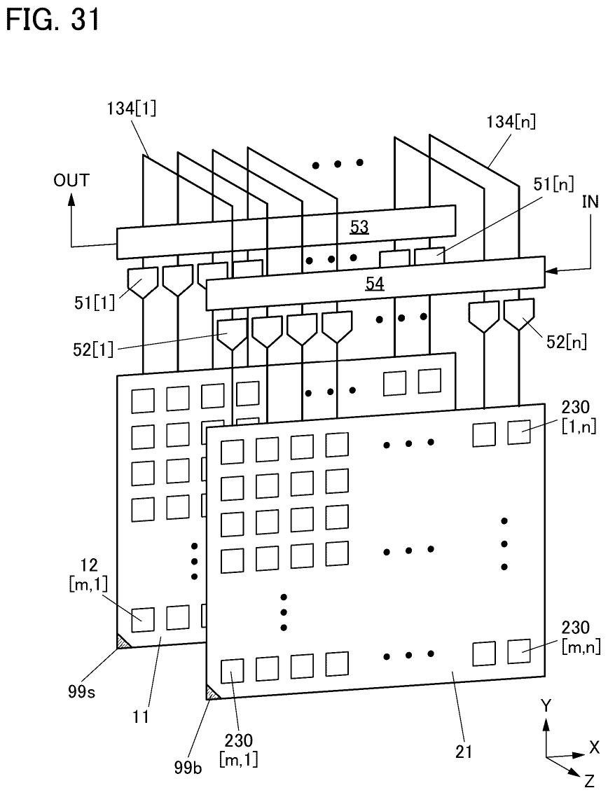

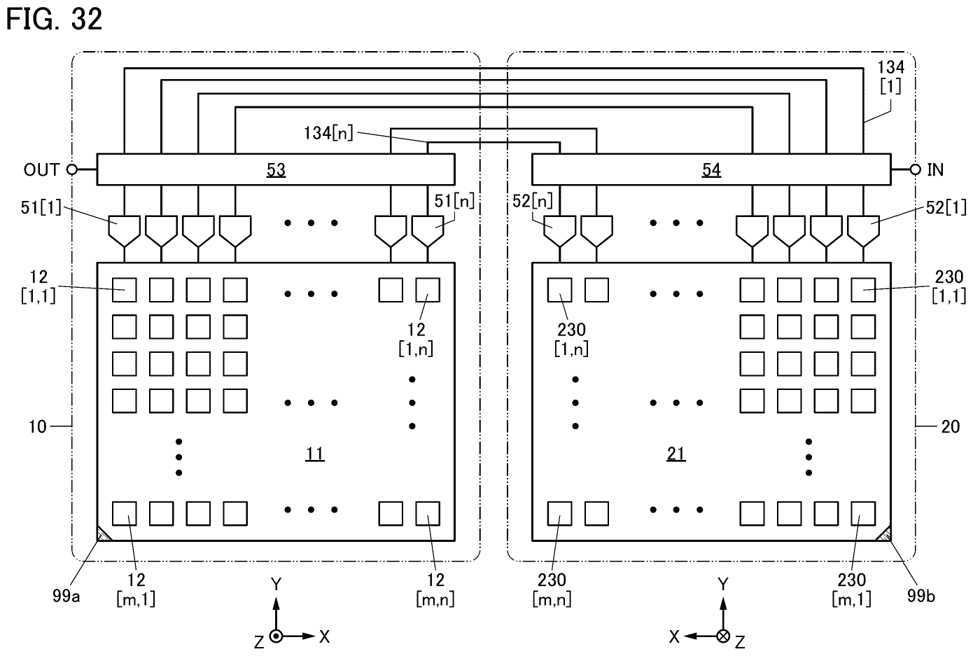

In the case where imaging data undergoes arithmetic processing, the imaging data converted into a digital signal needs to be once output to an arithmetic processing device (image processing device) or a storage device. Thus, as illustrated in FIG. 31 and FIG. 32, an output control circuit 53 may be provided on the output side of the ADC 51 and an input control circuit 54 may be provided on the input side of the DAC 52.

The output control circuit 53 has a function of selecting whether to output the imaging data supplied from the ADC 51 to the display unit 21 side or to output the data to the outside through an output terminal OUT. Both output to the outside and output to the display unit 21 side can be performed.

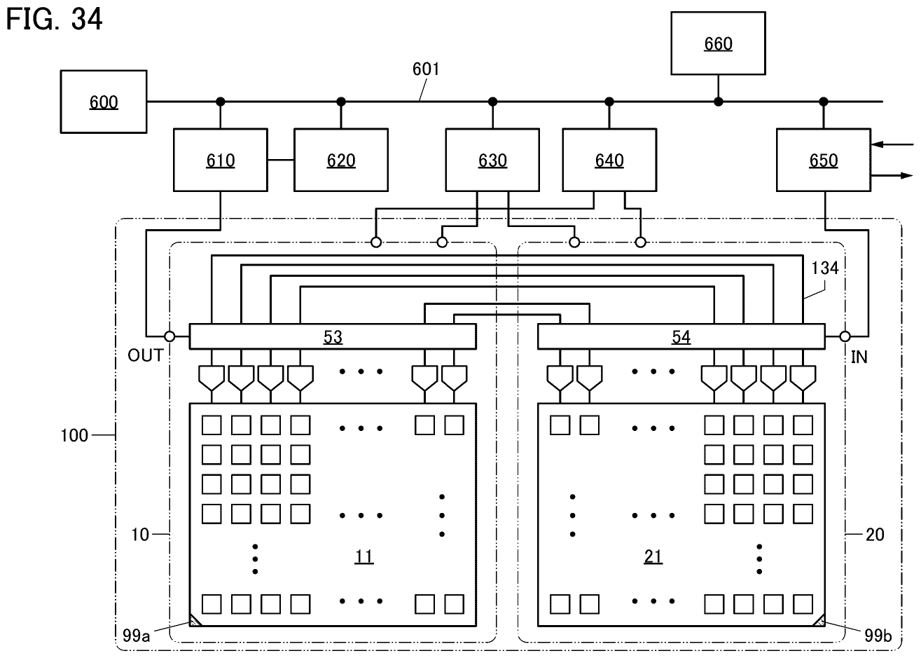

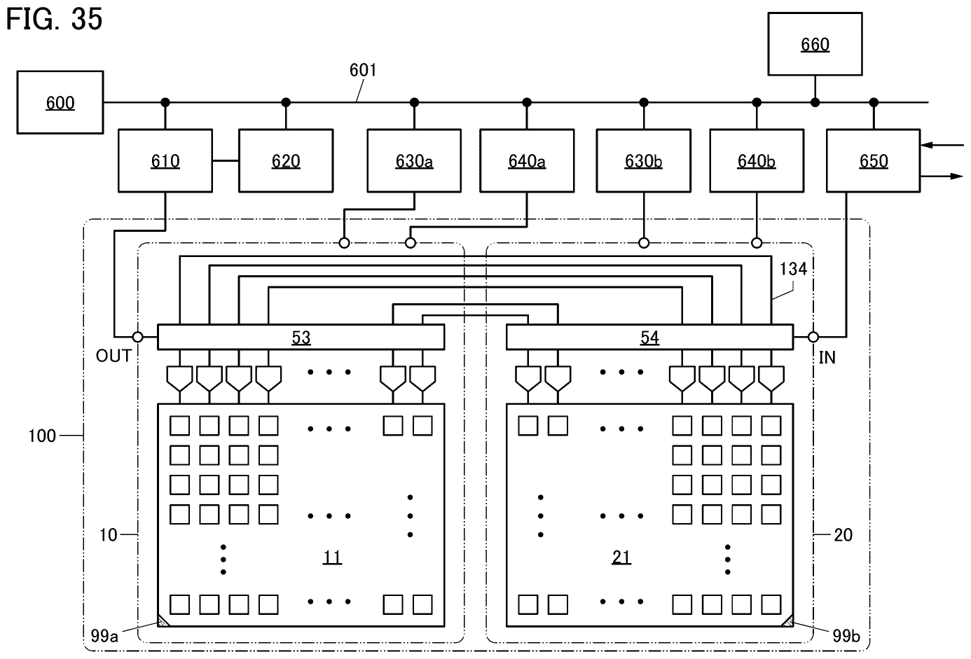

The imaging data output to the outside is supplied to a storage device 610 (see FIG. 34 and FIG. 35). The storage device 610 include, but not limited to the storage circuit unit 18 in the above embodiment, an HDD (Hard Disk Drive), an SSD (Solid State Drive), an FD (Floppy Disk), a magneto-optical disk (MO), a USB memory, an SD memory card, a CD (Compact Disc), a DVD (Digital Versatile Disc), a BD (Blu-ray Disc (registered trademark)), and the like.

The storage device 610 also functions as a temporary storage device for image processing of imaging data. As an image processing device executing arithmetic processing of imaging data, one or more selected from the CPU, the GPU, the DSP, and the super-resolution circuit described in the above embodiment can be given.

The input control circuit 54 has a function of selecting one of the imaging data supplied from the imaging unit 11 side through the ADC 51 and the digital signal supplied from the outside through an input terminal IN, and supplying the selected one to the DAC 52. Furthermore, the input control circuit 54 has a function of supplying the DAC 52 with a signal that is a combination of the imaging data supplied from the imaging unit 11 side through the ADC 51 and the digital signal input (IN) from the outside.

When the output control circuit 53 and the input control circuit 54 are included, imaging data subjected to image processing on the outside can be supplied to the display unit 21. Accordingly, a semiconductor device having a high display quality can be achieved.

Although FIG. 32 illustrates an example in which the ADC 51 and the output control circuit 53 are provided in the layer 10 and the DAC 52 and the input control circuit 54 are provided in the layer 20, one embodiment of the present invention is not limited thereto. For example, the layer 30 of the semiconductor device 100D described in the above embodiment may be provided with at least one of the ADC 51, the output control circuit 53, the DAC 52, and the input control circuit 54.

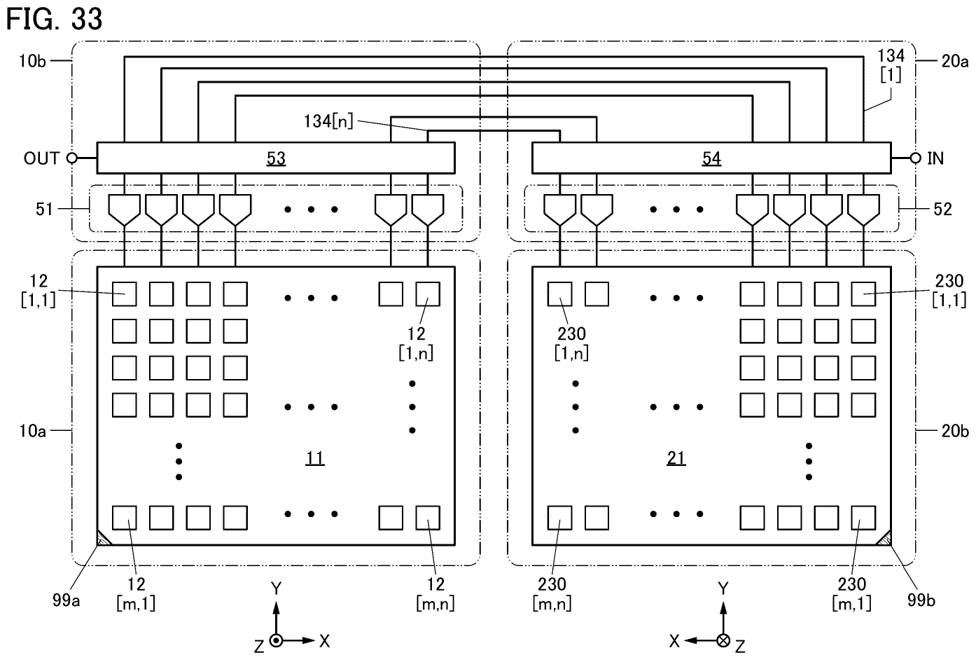

For example, the layer 10b of the semiconductor device 100C described in the above embodiment may be provided with the ADC 51 and the output control circuit 53, and the layer 20a may be provided with the DAC 52 and the input control circuit 54 (see FIG. 33).

FIG. 34 and FIG. 35 illustrate examples of the semiconductor device 100 including the layer 10 and the layer 20 illustrated in the FIG. 32 and an external device electrically connected to the semiconductor device 100. As examples of the external device, FIG. 34 and FIG. 35 illustrate a control device 600, a storage device 610, an image processing device 620, a power control device 630, a timing controller 640, an input/output device 650, and a communication device 660.

The control device 600, the storage device 610, the image processing device 620, the power control device 630, the timing controller 640, the input/output device 650, and the communication device 660 illustrated in FIG. 34 and FIG. 35 are electrically connected to each other through a bus line 601. The image processing device 620 may be electrically connected to the storage device 610 without through the bus line 601.

The control device 600 has a function of controlling the operation of each of the devices connected to each other through the bus line 601.

The image processing device 620 has a function of executing arithmetic processing of image data stored in the storage device 610. For example, the image processing device 620 has a function of performing contrast adjustment, gamma correction, and the like of the image data.

The power control device 630 has a function of supplying the layer 10 with power necessary for the layer 10 and a function of supplying the layer 20 with power necessary for the layer 20. The power control device 630 may supply the same power or may supply different kinds of power to the layer 10 and the layer 20. As illustrated in FIG. 35, the power control device 630 may be divided into a power control device 630a having a function of supplying power to the layer 10 and a power control device 630b having a function of supplying power to the layer 20.

The timing controller 640 has a function of synchronizing operation of a circuit included in the layer 10 and operation of a circuit included in the layer 20. For example, the timing controller 640 has a function of supplying a clock signal, a start signal, and the like having the same frequency to each of the layer 10 and the layer 20. As illustrated in FIG. 35, the timing controller 640 may be divided into a timing controller 640a having a function of supplying a clock signal, a start signal, and the like to the layer 10 and a timing controller 640b having a function of supplying a clock signal, a start signal, and the like to the layer 20.

The input/output device 650 has a function of inputting/outputting data from/to the outside. The input/output device 650 has a function of supplying data stored in the storage device 610 to the layer 20. The data input through the input/output device 650 may be stored in the storage device 610. The input/output device 650 has a function of supplying data processed by the image processing device 620 to the layer 20.

The communication device 660 can perform communication using a communication protocol or a communication technology similar to that used in the above-described communication circuit.

The structures described in this embodiment can be used in an appropriate combination with the structures described in the other embodiments and the like.

### Embodiment 7

In this embodiment, transistors that can be used in the semiconductor device of one embodiment of the present invention are described.

### <Structure Example of Transistor>

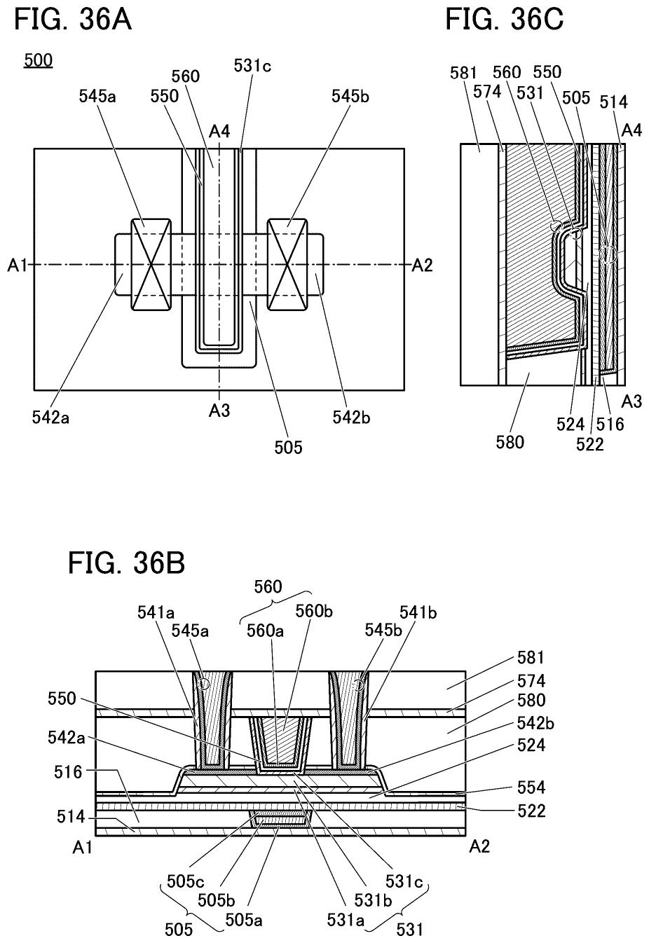

FIG. 36A, FIG. 36B, and FIG. 36C are a top view and cross-sectional views of a transistor 500 that can be used in the semiconductor device of one embodiment of the present invention. The transistor 500 can be used in the semiconductor device of one embodiment of the present invention. For example, the transistor 500 can be used as the transistor included in the layer 20.

FIG. 36A is atop view of the transistor 500. FIG. 36B and FIG. 36C are cross-sectional views of the transistor 500. Here, FIG. 36B is a cross-sectional view of a portion indicated by the dashed-dotted line A1-A2 in FIG. 36A and is a cross-sectional view of the transistor 500 in the channel length direction. FIG. 36C is a cross-sectional view of a portion indicated by the dashed-dotted line A3-A4 in FIG. 36A and is a cross-sectional view of the transistor 500 in the channel width direction. Note that some components are omitted in the top view of FIG. 36A for clarity of the drawing.

As illustrated in FIG. 36, the transistor 500 includes a metal oxide 531a placed over a substrate (not illustrated); a metal oxide 531b placed over the metal oxide 531a; a conductor 542a and a conductor 542b that are placed apart from each other over the metal oxide 531b; an insulator 580 that is placed over the conductor 542a and the conductor 542b and has an opening between the conductor 542a and the conductor 542b; a conductor 560 placed in the opening; an insulator 550 placed between the conductor 560 and the metal oxide 531b, the conductor 542a, the conductor 542b, and the insulator 580; and a metal oxide 531c placed between the insulator 550 and the metal oxide 531b, the conductor 542a, the conductor 542b, and the insulator 580. Here, as illustrated in FIG. 36B and FIG. 36C, preferably, the top surface of the conductor 560 is substantially aligned with the top surfaces of the insulator 550, the insulator 554, the metal oxide 531c, and the insulator 580. Hereinafter, the metal oxide 531a, the metal oxide 531b, and the metal oxide 531c may be collectively referred to as a metal oxide 531. The conductor 542a and the conductor 542b may be collectively referred to as a conductor 542.

In the transistor 500 illustrated in FIG. 36, side surfaces of the conductor 542a and the conductor 542b on the conductor 560 side are substantially perpendicular. Note that the transistor 500 illustrated in FIG. 36 is not limited thereto, and the angle formed between the side surfaces and the bottom surfaces of the conductor 542a and the conductor 542b may be greater than or equal to 100 and less than or equal to 80°, preferably greater than or equal to 30° and less than or equal to 60°. The side surfaces of the conductor 542a and the conductor 542b that face each other may have a plurality of surfaces.

As illustrated in FIG. 36, the insulator 554 is preferably placed between the insulator 580 and an insulator 524, the metal oxide 531a, the metal oxide 531b, the conductor 542a, the conductor 542b, and the metal oxide 531c. Here, as illustrated in FIG. 36B and FIG. 36C, the insulator 554 is preferably in contact with the side surface of the metal oxide 531c, the top surface and the side surface of the conductor 542a, the top surface and the side surface of the conductor 542b, the side surfaces of the metal oxide 531a and the metal oxide 531b, and the top surface of the insulator 524.

In the transistor 500, three layers of the metal oxide 531a, the metal oxide 531b, and the metal oxide 531c are stacked in and around the region where the channel is formed (hereinafter also referred to as channel formation region); however, the present invention is not limited thereto. For example, a two-layer structure of the metal oxide 531b and the metal oxide 531c or a stacked-layer structure of four or more layers may be employed. Although the conductor 560 is illustrated to have a stacked-layer structure of two layers in the transistor 500, the present invention is not limited thereto. For example, the conductor 560 can have a single-layer structure or a stacked-layer structure of three or more layers. Furthermore, each of the metal oxide 531a, the metal oxide 531b, and the metal oxide 531c may have a stacked-layer structure of two or more layers.

For example, in the case where the metal oxide 531c has a stacked-layer structure including a first metal oxide and a second metal oxide over the first metal oxide, the first metal oxide preferably has a composition similar to that of the metal oxide 531b and the second metal oxide preferably has a composition similar to that of the metal oxide 531a.

Here, the conductor 560 functions as a gate electrode of the transistor, and the conductor 542a and the conductor 542b each function as a source electrode or a drain electrode. As described above, the conductor 560 is formed to be embedded in the opening of the insulator 580 and the region interposed between the conductor 542a and the conductor 542b. Here, the positions of the conductor 560, the conductor 542a, and the conductor 542b are selected in a self-aligned manner with respect to the opening of the insulator 580. In other words, in the transistor 500, the gate electrode can be placed between the source electrode and the drain electrode in a self-aligned manner. Thus, the conductor 560 can be formed without an alignment margin, resulting in a reduction in the area occupied by the transistor 500. Accordingly, the display apparatus can have higher resolution. In addition, the display apparatus can have a narrow bezel.

As illustrated in FIG. 36, the conductor 560 preferably includes a conductor 560a provided on the inner side of the insulator 550 and a conductor 560b provided to be embedded on the inner side of the conductor 560a.

The transistor 500 preferably includes an insulator 514 placed over the substrate (not illustrated); an insulator 516 placed over the insulator 514; a conductor 505 placed to be embedded in the insulator 516; an insulator 522 placed over the insulator 516 and the conductor 505; and the insulator 524 placed over the insulator 522. The metal oxide 531a is preferably placed over the insulator 524.

An insulator 574 and an insulator 581 functioning as interlayer films are preferably placed over the transistor 500. Here, the insulator 574 is preferably placed in contact with the top surfaces of the conductor 560, the insulator 550, the insulator 554, the metal oxide 531c, and the insulator 580.

The insulator 522, the insulator 554, and the insulator 574 preferably have a function of inhibiting diffusion of hydrogen (at least one of a hydrogen atom, a hydrogen molecule, and the like). For example, the insulator 522, the insulator 554, and the insulator 574 preferably have a lower hydrogen permeability than the insulator 524, the insulator 550, and the insulator 580. Moreover, the insulator 522 and the insulator 554 preferably have a function of inhibiting diffusion of oxygen (e.g., at least one of an oxygen atom and an oxygen molecule). For example, the insulator 522 and the insulator 554 preferably have a lower oxygen permeability than the insulator 524, the insulator 550, and the insulator 580.

Here, the insulator 524, the metal oxide 531, and the insulator 550 are separated from the insulator 580 and the insulator 581 by the insulator 554 and the insulator 574. This can inhibit entry of impurities such as hydrogen contained in the insulator 580 and the insulator 581 and excess oxygen into the insulator 524, the metal oxide 531, and the insulator 550.

A conductor 545 (a conductor 545a and a conductor 545b) that is electrically connected to the transistor 500 and functions as a plug is preferably provided. Note that an insulator 541 (an insulator 541a and an insulator 541b) is provided in contact with a side surface of the conductor 545 functioning as a plug. In other words, the insulator 541 is provided in contact with the inner wall of an opening in the insulator 554, the insulator 580, the insulator 574, and the insulator 581. In addition, a structure may be employed in which a first conductor of the conductor 545 is provided in contact with the side surface of the insulator 541 and a second conductor of the conductor 545 is provided on the inner side of the first conductor. Here, the top surface of the conductor 545 and the top surface of the insulator 581 can be substantially level with each other. Although the transistor 500 has a structure in which the first conductor of the conductor 545 and the second conductor of the conductor 545 are stacked, the present invention is not limited thereto. For example, the conductor 545 may have a single-layer structure or a stacked-layer structure of three or more layers. In the case where a component has a stacked-layer structure, layers may be distinguished by ordinal numbers corresponding to the formation order.

In the transistor 500, a metal oxide functioning as an oxide semiconductor (hereinafter also referred to as an oxide semiconductor) is preferably used as the metal oxide 531 including the channel formation region (the metal oxide 531a, the metal oxide 531b, and the metal oxide 531c). For example, it is preferable to use a metal oxide having a band gap of 2 eV or more, preferably 2.5 eV or more as the metal oxide to be the channel formation region of the metal oxide 531.

The metal oxide preferably contains at least indium (In) or zinc (Zn). In particular, indium (In) and zinc (Zn) are preferably contained. In addition to them, an element M is preferably contained. As the element M, one or more of aluminum (Al), gallium (Ga), yttrium (Y), tin (Sn), boron (B), titanium (Ti), iron (Fe), nickel (Ni), germanium (Ge), zirconium (Zr), molybdenum (Mo), lanthanum (La), cerium (Ce), neodymium (Nd), hafnium (Hf), tantalum (Ta), tungsten (W), magnesium (Mg), and cobalt (Co) can be used. In particular, the element M is preferably one or more of aluminum (Al), gallium (Ga), yttrium (Y), and tin (Sn). Furthermore, the element M preferably contains one or both of gallium (Ga) and tin (Sn).

As illustrated in FIG. 36B, the metal oxide 531b in a region that does not overlap with the conductor 542 sometimes has a smaller thickness than the metal oxide 531b in a region that overlaps with the conductor 542. The thin region is formed when part of the top surface of the metal oxide 531b is removed at the time of forming the conductor 542a and the conductor 542b. When a conductive film to be the conductor 542 is formed, a low-resistance region is sometimes formed on the top surface of the metal oxide 531b in the vicinity of the interface with the conductive film. Removing the low-resistance region positioned between the conductor 542a and the conductor 542b on the top surface of the metal oxide 531b in the above manner can prevent formation of the channel in the region.

According to one embodiment of the present invention, a display apparatus that includes small-size transistors and has high resolution can be provided. A display apparatus that includes a transistor with a high on-state current and has high luminance can be provided. A display apparatus that includes a transistor operating at high speed and thus operates at high speed can be provided. A display apparatus that includes a transistor having stable electrical characteristics and is highly reliable can be provided. A display apparatus that includes a transistor with a low off-state current and has low power consumption can be provided.

The structure of the transistor 500 that can be used in the display apparatus of one embodiment of the present invention is described in detail.

The conductor 505 is placed to include a region overlapping with the metal oxide 531 and the conductor 560. Furthermore, the conductor 505 is preferably provided to be embedded in the insulator 516.

The conductor 505 includes a conductor 505a, a conductor 505b, and a conductor 505c. The conductor 505a is provided in contact with the bottom surface and a side wall of the opening provided in the insulator 516. The conductor 505b is provided to be embedded in a recessed portion formed by the conductor 505a. Here, the top surface of the conductor 505b is lower in level than the top surface of the conductor 505a and the top surface of the insulator 516. The conductor 505c is provided in contact with the top surface of the conductor 505b and the side surface of the conductor 505a. Here, the top surface of the conductor 505c is substantially level with the top surface of the conductor 505a and the top surface of the insulator 516. That is, the conductor 505b is surrounded by the conductor 505a and the conductor 505c.

Here, as the conductor 505a and the conductor 505c, it is preferable to use a conductive material having a function of inhibiting diffusion of impurities such as a hydrogen atom, a hydrogen molecule, a water molecule, a nitrogen atom, a nitrogen molecule, a nitrogen oxide molecule (N₂O, NO, NO₂, or the like), and a copper atom. Alternatively, it is preferable to use a conductive material having a function of inhibiting diffusion of oxygen (e.g., at least one of an oxygen atom and an oxygen molecule).

When the conductor 505a and the conductor 505c are formed using a conductive material having a function of inhibiting diffusion of hydrogen, impurities such as hydrogen contained in the conductor 505b can be inhibited from diffusing into the metal oxide 531 through the insulator 524 and the like. When the conductor 505a and the conductor 505c are formed using a conductive material having a function of inhibiting diffusion of oxygen, the conductivity of the conductor 505b can be inhibited from being lowered because of oxidation. As the conductive material having a function of inhibiting diffusion of oxygen, for example, titanium, titanium nitride, tantalum, tantalum nitride, ruthenium, ruthenium oxide, or the like is preferably used. Thus, the conductor 505a is a single layer or stacked layers of the above conductive materials. For example, titanium nitride is used for the conductor 505a.

For the conductor 505b, a conductive material containing tungsten, copper, or aluminum as its main component is preferably used. For example, tungsten may be used for the conductor 505b.

The conductor 560 sometimes functions as a first gate (also referred to as top gate) electrode. The conductor 505 sometimes functions as a second gate (also referred to as bottom gate) electrode. In that case, by changing a potential applied to the conductor 505 not in synchronization with and independently of a potential applied to the conductor 560, Vₜₕ of the transistor 500 can be controlled. In particular, by applying a negative potential to the conductor 505, Vₜₕ of the transistor 500 can be higher than 0 V and the off-state current can be made low. Thus, a drain current at the time when a potential applied to the conductor 560 is 0 V can be lower in the case where a negative potential is applied to the conductor 505 than in the case where the negative potential is not applied to the conductor 505.

The conductor 505 is preferably provided to be larger than the channel formation region in the metal oxide 531. In particular, it is preferable that the conductor 505 extend to the outside beyond an end portion of the metal oxide 531 that intersects with the channel width direction, as illustrated in FIG. 36C. In other words, the conductor 505 and the conductor 560 preferably overlap with each other with the insulator placed therebetween, in a region outside the side surface of the metal oxide 531 in the channel width direction.

With the above structure, the channel formation region of the metal oxide 531 can be electrically surrounded by electric fields of the conductor 560 having a function of the first gate electrode and electric fields of the conductor 505 having a function of the second gate electrode.

Furthermore, as illustrated in FIG. 36C, the conductor 505 extends so as to function as a wiring as well. However, without limitation to this structure, a structure in which a conductor functioning as a wiring is provided below the conductor 505 may be employed.

The insulator 514 preferably functions as a barrier insulating film that inhibits the entry of impurities such as water or hydrogen to the transistor 500 from the substrate side. Accordingly, it is preferable to use, for the insulator 514, an insulating material having a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom (an insulating material through which the impurities are less likely to pass). Alternatively, it is preferable to use an insulating material having a function of inhibiting diffusion of oxygen (e.g., at least one of an oxygen atom and an oxygen molecule) (an insulating material through which the oxygen is less likely to pass).

For example, aluminum oxide, silicon nitride, or the like is preferably used as the insulator 514. Accordingly, it is possible to inhibit diffusion of impurities such as water or hydrogen to the transistor 500 side from the substrate side through the insulator 514. Alternatively, it is possible to inhibit diffusion of oxygen contained in the insulator 524 and the like to the substrate side through the insulator 514.

The permittivity of each of the insulator 516, the insulator 580, and the insulator 581 functioning as an interlayer film is preferably lower than that of the insulator 514. When a material with a low permittivity is used for an interlayer film, the parasitic capacitance generated between wirings can be reduced. As the insulator 516, the insulator 580, and the insulator 581, for example, silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, or the like can be used as appropriate.

The insulator 522 and the insulator 524 have a function of a gate insulator.

Here, the insulator 524 in contact with the metal oxide 531 preferably releases oxygen by heating. In this specification, oxygen that is released by heating is referred to as excess oxygen in some cases. For example, silicon oxide, silicon oxynitride, or the like can be used as appropriate for the insulator 524. When an insulator containing oxygen is provided in contact with the metal oxide 531, oxygen vacancies in the metal oxide 531 can be reduced, leading to improved reliability of the transistor 500.

Specifically, an oxide material that releases part of oxygen by heating is preferably used for the insulator 524. An oxide that releases oxygen by heating is an oxide film in which the amount of released oxygen converted into oxygen atoms is greater than or equal to 1.0×10¹⁸ atoms/cm³, preferably greater than or equal to 1.0×10¹⁹ atoms/cm³, further preferably greater than or equal to 2.0×10¹⁹ atoms/cm³ or greater than or equal to 3.0×10²⁰ atoms/cm³ in TDS (Thermal Desorption Spectroscopy) analysis. Note that the temperature of the film surface in the TDS analysis is preferably in the range of 100° C. to 700° C., both inclusive or 100° C. to 400° C., both inclusive.

As illustrated in FIG. 36C, the insulator 524 is sometimes thinner in a region that overlaps with neither the insulator 554 nor the metal oxide 531b than in the other regions. In the insulator 524, the region that overlaps with neither the insulator 554 nor the metal oxide 531b preferably has a thickness with which the above oxygen can be adequately diffused.

Similarly to the insulator 514 and the like, the insulator 522 preferably functions as a barrier insulating film that inhibits the entry of impurities such as water or hydrogen into the transistor 500 from the substrate side. For example, the insulator 522 preferably has a lower hydrogen permeability than the insulator 524. When the insulator 524, the metal oxide 531, the insulator 550, and the like are surrounded by the insulator 522, the insulator 554, and the insulator 574, the entry of impurities such as water or hydrogen into the transistor 500 from outside can be inhibited.

Furthermore, it is preferable that the insulator 522 have a function of inhibiting diffusion of oxygen (e.g., at least one of an oxygen atom and an oxygen molecule) (it is preferable that the oxygen be less likely to pass through the insulator 522). For example, the insulator 522 preferably has a lower oxygen permeability than the insulator 524. The insulator 522 preferably has a function of inhibiting diffusion of oxygen and impurities, in which case oxygen contained in the metal oxide 531 is less likely to diffuse to the substrate side. Moreover, the conductor 505 can be inhibited from reacting with oxygen contained in the insulator 524 and the metal oxide 531.

As the insulator 522, an insulator containing an oxide of one or both of aluminum and hafnium, which is an insulating material, is preferably used. As the insulator containing an oxide of one or both of aluminum and hafnium, aluminum oxide, hafnium oxide, an oxide containing aluminum and hafnium (hafnium aluminate), or the like is preferably used. In the case where the insulator 522 is formed using such a material, the insulator 522 functions as a layer inhibiting release of oxygen from the metal oxide 531 and entry of impurities such as hydrogen into the metal oxide 531 from the periphery of the transistor 500.

Alternatively, aluminum oxide, bismuth oxide, germanium oxide, niobium oxide, silicon oxide, titanium oxide, tungsten oxide, yttrium oxide, or zirconium oxide may be added to these insulators, for example. Alternatively, these insulators may be subjected to nitriding treatment. Silicon oxide, silicon oxynitride, or silicon nitride may be stacked over the above insulator.

The insulator 522 may be a single layer or a stacked layer using an insulator containing a high-k material, such as aluminum oxide, hafnium oxide, tantalum oxide, zirconium oxide, lead zirconate titanate (PZT), strontium titanate (SrTiO₃), or (Ba,Sr)TiO₃ (BST). With further miniaturization and higher integration of a transistor, a problem such as generation of leakage current may arise because of a thinned gate insulator. When a high-k material is used for the insulator functioning as a gate insulator, a gate potential at the time of operation of the transistor can be reduced while the physical thickness is maintained.

Note that the insulator 522 and the insulator 524 may each have a stacked-layer structure of two or more layers. In that case, without limitation to a stacked-layer structure formed of the same material, a stacked-layer structure formed of different materials may be employed. For example, an insulator similar to the insulator 524 may be provided below the insulator 522.

The metal oxide 531 includes the metal oxide 531a, the metal oxide 531b over the metal oxide 531a, and the metal oxide 531c over the metal oxide 531b. When the metal oxide 531 includes the metal oxide 531a under the metal oxide 531b, it is possible to inhibit diffusion of impurities into the metal oxide 531b from the components formed below the metal oxide 531a. Moreover, when the metal oxide 531 includes the metal oxide 531c over the metal oxide 531b, it is possible to inhibit diffusion of impurities into the metal oxide 531b from the components formed above the metal oxide 531c.

Note that the metal oxide 531 preferably has a stacked-layer structure of a plurality of oxide layers that differ in the atomic ratio of metal atoms. For example, in the case where the metal oxide 531 contains at least indium (In) and the element M, the proportion of the number of atoms of the element M contained in the metal oxide 531a to the number of atoms of all elements that constitute the metal oxide 531a is preferably higher than the proportion of the number of atoms of the element M contained in the metal oxide 531b to the number of atoms of all elements that constitute the metal oxide 531b. In addition, the atomic ratio of the element M to In in the metal oxide 531a is preferably greater than the atomic ratio of the element M to In in the metal oxide 531b. Here, a metal oxide that can be used as the metal oxide 531a or the metal oxide 531b can be used as the metal oxide 531c.

The energy of the conduction band minimum of each of the metal oxide 531a and the metal oxide 531c is preferably higher than the energy of the conduction band minimum of the metal oxide 531b. In other words, the electron affinity of each of the metal oxide 531a and the metal oxide 531c is preferably smaller than the electron affinity of the metal oxide 531b. In this case, a metal oxide that can be used as the metal oxide 531a is preferably used as the metal oxide 531c. Specifically, the proportion of the number of atoms of the element M contained in the metal oxide 531c to the number of atoms of all elements that constitute the metal oxide 531c is preferably higher than the proportion of the number of atoms of the element M contained in the metal oxide 531b to the number of atoms of all elements that constitute the metal oxide 531b. In addition, the atomic ratio of the element M to In in the metal oxide 531c is preferably greater than the atomic ratio of the element M to In in the metal oxide 531b.

Here, the energy level of the conduction band minimum gently changes at junction portions between the metal oxide 531a, the metal oxide 531b, and the metal oxide 531c. In other words, at junction portions between the metal oxide 531a, the metal oxide 531b, and the metal oxide 531c, the energy level of the conduction band minimum continuously changes or the energy levels are continuously connected. This can be achieved by decreasing the density of defect states in a mixed layer formed at the interface between the metal oxide 531a and the metal oxide 531b and the interface between the metal oxide 531b and the metal oxide 531c.

Specifically, when the metal oxide 531a and the metal oxide 531b or the metal oxide 531b and the metal oxide 531c contain the same element (as a main component) in addition to oxygen, a mixed layer with a low density of defect states can be formed. For example, an In—Ga—Zn oxide, a Ga—Zn oxide, gallium oxide, or the like may be used as the metal oxide 531a and the metal oxide 531c, in the case where the metal oxide 531b is an In—Ga—Zn oxide. The metal oxide 531c may have a stacked-layer structure. For example, a stacked-layer structure of an In—Ga—Zn oxide and a Ga—Zn oxide over the In—Ga—Zn oxide or a stacked-layer structure of an In—Ga—Zn oxide and gallium oxide over the In—Ga—Zn oxide can be employed. In other words, the metal oxide 531c may have a stacked-layer structure of an In—Ga—Zn oxide and an oxide that does not contain In.

Specifically, as the metal oxide 531a, a metal oxide with In:Ga:Zn=1:3:4 [atomic ratio] or 1:1:0.5 [atomic ratio] can be used. As the metal oxide 531b, a metal oxide with In:Ga:Zn=4:2:3 [atomic ratio] or 3:1:2 [atomic ratio] can be used. As the metal oxide 531c, a metal oxide with In:Ga:Zn=1:3:4 [atomic ratio], In:Ga:Zn=4:2:3 [atomic ratio], Ga:Zn=2:1 [atomic ratio], or Ga:Zn=2:5 [atomic ratio] can be used. Specific examples of a stacked-layer structure of the metal oxide 531c include a stacked-layer structure of a layer with In:Ga:Zn=4:2:3 [atomic ratio] and a layer with Ga:Zn=2:1 [atomic ratio], a stacked-layer structure of a layer with In:Ga:Zn=4:2:3 [atomic ratio] and a layer with Ga:Zn=2:5 [atomic ratio], and a stacked-layer structure of a layer with In:Ga:Zn=4:2:3 [atomic ratio] and a layer of gallium oxide.

At this time, the metal oxide 531b serves as a main carrier path. When the metal oxide 531a and the metal oxide 531c have the above structure, the density of defect states at the interface between the metal oxide 531a and the metal oxide 531b and the interface between the metal oxide 531b and the metal oxide 531c can be made low. This reduces the influence of interface scattering on carrier conduction, and the transistor 500 can have a high on-state current and high frequency characteristics. Note that in the case where the metal oxide 531c has a stacked-layer structure, not only the effect of reducing the density of defect states at the interface between the metal oxide 531b and the metal oxide 531c, but also the effect of inhibiting diffusion of the constituent element contained in the metal oxide 531c to the insulator 550 side can be expected. Specifically, the metal oxide 531c has a stacked-layer structure in which an oxide not containing In is positioned in the upper layer of the stacked-layer structure, whereby the diffusion of In to the insulator 550 side can be inhibited. Since the insulator 550 functions as a gate insulator, the transistor has defects in characteristics when In diffuses. Thus, the metal oxide 531c having a stacked-layer structure allows a highly reliable display apparatus to be provided.

The conductor 542 (the conductor 542a and the conductor 542b) functioning as the source electrode and the drain electrode is provided over the metal oxide 531b. For the conductor 542, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, and lanthanum; an alloy containing any of the above metal elements; an alloy containing a combination of the above metal elements; or the like. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. Tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are oxidation-resistant conductive materials or materials that maintain their conductivity even after absorbing oxygen.

When the conductor 542 is provided in contact with the metal oxide 531, the oxygen concentration of the metal oxide 531 in the vicinity of the conductor 542 sometimes decreases. In addition, a metal compound layer that contains the metal contained in the conductor 542 and the component of the metal oxide 531 is sometimes formed in the metal oxide 531 in the vicinity of the conductor 542. In such cases, the carrier concentration of the region in the metal oxide 531 in the vicinity of the conductor 542 increases, and the region becomes a low-resistance region.

Here, the region between the conductor 542a and the conductor 542b is formed to overlap with the opening of the insulator 580. Accordingly, the conductor 560 can be placed in a self-aligned manner between the conductor 542a and the conductor 542b.

The insulator 550 functions as a gate insulator. The insulator 550 is preferably placed in contact with the top surface of the metal oxide 531c. For the insulator 550, silicon oxide, silicon oxynitride, silicon nitride oxide, silicon nitride, silicon oxide to which fluorine is added, silicon oxide to which carbon is added, silicon oxide to which carbon and nitrogen are added, or porous silicon oxide can be used. In particular, silicon oxide and silicon oxynitride, which are thermally stable, are preferable.

As in the insulator 524, the concentration of impurities such as water or hydrogen in the insulator 550 is preferably reduced. The thickness of the insulator 550 is preferably greater than or equal to 1 nm and less than or equal to 20 nm.

A metal oxide may be provided between the insulator 550 and the conductor 560. The metal oxide preferably inhibits oxygen diffusion from the insulator 550 into the conductor 560. Accordingly, oxidation of the conductor 560 due to oxygen in the insulator 550 can be inhibited.

The metal oxide functions as part of the gate insulator in some cases. Therefore, when silicon oxide, silicon oxynitride, or the like is used for the insulator 550, a metal oxide that is a high-k material with a high dielectric constant is preferably used as the metal oxide. When the gate insulator has a stacked-layer structure of the insulator 550 and the metal oxide, the stacked-layer structure can be thermally stable and have a high dielectric constant. Accordingly, a gate potential applied during operation of the transistor can be reduced while the physical thickness of the gate insulator is maintained. In addition, the equivalent oxide thickness (EOT) of the insulator functioning as the gate insulator can be reduced.

Specifically, a metal oxide containing one kind or two or more kinds selected from hafnium, aluminum, gallium, yttrium, zirconium, tungsten, titanium, tantalum, nickel, germanium, magnesium, and the like can be used. It is particularly preferable to use an insulator containing an oxide of one or both of aluminum and hafnium, such as aluminum oxide, hafnium oxide, or an oxide containing aluminum and hafnium (hafnium aluminate).

Although the conductor 560 is illustrated to have a two-layer structure in FIG. 36, the conductor 560 may have a single-layer structure or a stacked-layer structure of three or more layers.

The conductor 560a is preferably formed using the aforementioned conductor having a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom. Alternatively, it is preferable to use a conductive material having a function of inhibiting diffusion of oxygen (e.g., at least one of an oxygen atom and an oxygen molecule).

When the conductor 560a has a function of inhibiting diffusion of oxygen, the conductivity of the conductor 560b can be inhibited from being lowered by oxidation due to oxygen contained in the insulator 550. As a conductive material having a function of inhibiting oxygen diffusion, for example, tantalum, tantalum nitride, ruthenium, ruthenium oxide, or the like is preferably used.

Moreover, a conductive material containing tungsten, copper, or aluminum as its main component is preferably used for the conductor 560b. The conductor 560 also functions as a wiring and thus is preferably formed using a conductor having high conductivity. For example, a conductive material containing tungsten, copper, or aluminum as its main component can be used. The conductor 560b may have a stacked-layer structure, for example, a stacked-layer structure of titanium or titanium nitride and the above conductive material.

As illustrated in FIG. 36A and FIG. 36C, the side surface of the metal oxide 531 is covered with the conductor 560 in a region where the metal oxide 531b does not overlap with the conductor 542, that is, the channel formation region of the metal oxide 531. Accordingly, electric fields of the conductor 560 functioning as the first gate electrode are likely to act on the side surface of the metal oxide 531. Thus, the on-state current of the transistor 500 can be increased and the frequency characteristics can be improved.

The insulator 554, similarly to the insulator 514 and the like, preferably functions as a barrier insulating film that inhibits the entry of impurities such as water or hydrogen into the transistor 500 from the insulator 580 side. The insulator 554 preferably has a lower hydrogen permeability than the insulator 524, for example. Furthermore, as illustrated in FIG. 36B and FIG. 36C, the insulator 554 is preferably in contact with the side surface of the metal oxide 531c, the top and side surfaces of the conductor 542a, the top and side surfaces of the conductor 542b, side surfaces of the metal oxide 531a and the metal oxide 531b, and the top surface of the insulator 524. Such a structure can inhibit the entry of hydrogen contained in the insulator 580 into the metal oxide 531 through the top surfaces or side surfaces of the conductor 542a, the conductor 542b, the metal oxide 531a, the metal oxide 531b, and the insulator 524.

Furthermore, it is preferable that the insulator 554 have a function of inhibiting diffusion of oxygen (e.g., at least one of an oxygen atom and an oxygen molecule) (it is preferable that the oxygen be less likely to pass through the insulator 554). For example, the insulator 554 preferably has a lower oxygen permeability than the insulator 580 or the insulator 524.

The insulator 554 is preferably formed by a sputtering method. When the insulator 554 is formed by a sputtering method in an oxygen-containing atmosphere, oxygen can be added to the vicinity of a region of the insulator 524 that is in contact with the insulator 554. Thus, oxygen can be supplied from the region to the metal oxide 531 through the insulator 524. Here, with the insulator 554 having a function of inhibiting upward diffusion of oxygen, oxygen can be prevented from diffusing from the metal oxide 531 into the insulator 580. Moreover, with the insulator 522 having a function of inhibiting downward diffusion of oxygen, oxygen diffusion from the metal oxide 531 to the substrate side can be prevented. In the above manner, oxygen is supplied to the channel formation region of the metal oxide 531. Accordingly, oxygen vacancies in the metal oxide 531 can be reduced, so that the transistor can be inhibited from having normally-on characteristics.

As the insulator 554, an insulator containing an oxide of one or both of aluminum and hafnium is preferably formed, for example. Note that as the insulator containing an oxide of one or both of aluminum and hafnium, aluminum oxide, hafnium oxide, an oxide containing aluminum and hafnium (hafnium aluminate), or the like is preferably used.

The insulator 524, the insulator 550, and the metal oxide 531 are covered with the insulator 554 having a barrier property against hydrogen, whereby the insulator 580 is isolated from the insulator 524, the metal oxide 531, and the insulator 550 by the insulator 554. This can inhibit the entry of impurities such as hydrogen from outside of the transistor 500, resulting in favorable electrical characteristics and high reliability of the transistor 500.

The insulator 580 is provided over the insulator 524, the metal oxide 531, and the conductor 542 with the insulator 554 placed therebetween. The insulator 580 preferably includes, for example, silicon oxide, silicon oxynitride, silicon nitride oxide, silicon oxide to which fluorine is added, silicon oxide to which carbon is added, silicon oxide to which carbon and nitrogen are added, or porous silicon oxide. In particular, silicon oxide and silicon oxynitride, which are thermally stable, are preferable. In particular, materials such as silicon oxide, silicon oxynitride, and porous silicon oxide are preferably used, in which case a region containing oxygen to be released by heating can be easily formed.

The concentration of impurities such as water or hydrogen in the insulator 580 is preferably reduced. In addition, the top surface of the insulator 580 may be planarized.

Similarly to the insulator 514 and the like, the insulator 574 preferably functions as a barrier insulating film that inhibits the entry of impurities such as water or hydrogen into the insulator 580 from the above. As the insulator 574, for example, the insulator that can be used as the insulator 514, the insulator 554, and the like can be used.

The insulator 581 functioning as an interlayer film is preferably provided over the insulator 574. Similarly to the insulator 524 or the like, the concentration of impurities such as water or hydrogen in the insulator 581 is preferably reduced.

The conductor 545a and the conductor 545b are placed in openings formed in the insulator 581, the insulator 574, the insulator 580, and the insulator 554. The conductor 545a and the conductor 545b are placed to face each other with the conductor 560 placed therebetween. Note that the top surfaces of the conductor 545a and the conductor 545b may be on the same plane as the top surface of the insulator 581.

The insulator 541a is provided in contact with the inner wall of the opening in the insulator 581, the insulator 574, the insulator 580, and the insulator 554, and the first conductor of the conductor 545a is formed in contact with the side surface of the insulator 541a. The conductor 542a is positioned on at least part of the bottom portion of the opening, and the conductor 545a is in contact with the conductor 542a. Similarly, the insulator 541b is provided in contact with the inner wall of the opening in the insulator 581, the insulator 574, the insulator 580, and the insulator 554, and the first conductor of the conductor 545b is formed in contact with the side surface of the insulator 541b. The conductor 542b is positioned on at least part of the bottom portion of the opening, and the conductor 545b is in contact with the conductor 542b.

The conductor 545a and the conductor 545b are preferably formed using a conductive material containing tungsten, copper, or aluminum as its main component. The conductor 545a and the conductor 545b may have a stacked-layer structure.

In the case where the conductor 545 has a stacked-layer structure, the aforementioned conductor having a function of inhibiting diffusion of impurities such as water or hydrogen is preferably used as the conductor in contact with the metal oxide 531a, the metal oxide 531b, the conductor 542, the insulator 554, the insulator 580, the insulator 574, and the insulator 581. For example, tantalum, tantalum nitride, titanium, titanium nitride, ruthenium, ruthenium oxide, or the like is preferably used. The conductive material having a function of inhibiting diffusion of impurities such as water or hydrogen can be used as a single layer or stacked layers. The use of the conductive material can inhibit oxygen added to the insulator 580 from being absorbed by the conductor 545a and the conductor 545b. Moreover, impurities such as water or hydrogen can be inhibited from entering the metal oxide 531 through the conductor 545a and the conductor 545b from a layer above the insulator 581.

As the insulator 541a and the insulator 541b, for example, the insulator that can be used as the insulator 554 or the like can be used. Since the insulator 541a and the insulator 541b are provided in contact with the insulator 554, impurities such as water or hydrogen in the insulator 580 or the like can be inhibited from entering the metal oxide 531 through the conductor 545a and the conductor 545b. Furthermore, oxygen contained in the insulator 580 can be inhibited from being absorbed by the conductor 545a and the conductor 545b.

Although not illustrated, a conductor functioning as a wiring may be placed in contact with the top surface of the conductor 545a and the top surface of the conductor 545b. For the conductor functioning as a wiring, a conductive material containing tungsten, copper, or aluminum as its main component is preferably used. Furthermore, the conductor may have a stacked-layer structure and may be a stack of titanium or a titanium nitride and the above conductive material, for example. Note that the conductor may be formed to be embedded in an opening provided in an insulator.

### <Materials for Transistor>

Materials that can be used for the transistor will be described.

### [Substrate]

As a substrate where the transistor 500 is formed, an insulator substrate, a semiconductor substrate, or a conductor substrate may be used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate of silicon, germanium, or the like and a compound semiconductor substrate of silicon carbide, silicon germanium, gallium arsenide, indium phosphide, zinc oxide, or gallium oxide. Another example is a semiconductor substrate in which an insulator region is included in the semiconductor substrate, e.g., an SOI (Silicon On Insulator) substrate. Examples of the conductor substrate include a graphite substrate, a metal substrate, an alloy substrate, and a conductive resin substrate. Other examples include a substrate including a metal nitride and a substrate including a metal oxide. Other examples include an insulator substrate provided with a conductor or a semiconductor, a semiconductor substrate provided with a conductor or an insulator, and a conductor substrate provided with a semiconductor or an insulator. Alternatively, these substrates provided with elements may be used. Examples of the elements provided for the substrates include a capacitor, a resistor, a switching element, a light-emitting element, and a memory element.

### [Insulator]

Examples of an insulator include an oxide, a nitride, an oxynitride, a nitride oxide, a metal oxide, a metal oxynitride, and a metal nitride oxide, each of which has an insulating property.

With further miniaturization and higher integration of a transistor, for example, a problem such as generation of leakage current may arise because of a thinned gate insulator. When a high-k material is used for the insulator functioning as a gate insulator, the voltage at the time of operation of the transistor can be reduced while the physical thickness is maintained. By contrast, when a material with a low dielectric constant is used for the insulator functioning as an interlayer film, parasitic capacitance generated between wirings can be reduced. Thus, a material is preferably selected depending on the function of an insulator.

Examples of the insulator having a high dielectric constant include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of the insulator having a low dielectric constant include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, and a resin.

When a transistor including an oxide semiconductor is surrounded by insulators having a function of inhibiting the passage of oxygen and impurities such as hydrogen (e.g., the insulator 514, the insulator 522, the insulator 554, and the insulator 574), the electrical characteristics of the transistor can be stable. An insulator having a function of inhibiting the passage of oxygen and impurities such as hydrogen can be formed to have a single layer or a stacked layer including an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum. Specifically, as the insulator having a function of inhibiting the passage of oxygen and impurities such as hydrogen, a metal oxide such as aluminum oxide, magnesium oxide, gallium oxide, germanium oxide, yttrium oxide, zirconium oxide, lanthanum oxide, neodymium oxide, hafnium oxide, or tantalum oxide or a metal nitride such as aluminum nitride, aluminum titanium nitride, titanium nitride, silicon nitride oxide, or silicon nitride can be used.

An insulator functioning as a gate insulator is preferably an insulator including a region containing oxygen to be released by heating. For example, when a structure is employed in which silicon oxide or silicon oxynitride that includes a region containing oxygen to be released by heating is provided in contact with the metal oxide 531, oxygen vacancies included in the metal oxide 531 can be compensated.

### [Conductor]

For a conductor, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. Tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are oxidation-resistant conductive materials or materials that maintain their conductivity even after absorbing oxygen. A semiconductor having high electrical conductivity, typified by polycrystalline silicon containing an impurity element such as phosphorus, or silicide such as nickel silicide may be used.

A plurality of conductors formed using any of the above materials may be stacked. For example, a stacked-layer structure combining a material containing the above metal element and a conductive material containing oxygen may be employed. In addition, a stacked-layer structure combining a material containing the above metal element and a conductive material containing nitrogen may be employed. Furthermore, a stacked-layer structure combining a material containing the above metal element, a conductive material containing oxygen, and a conductive material containing nitrogen may be employed.

In the case where a metal oxide is used for the channel formation region of the transistor, the conductor functioning as the gate electrode preferably employs a stacked-layer structure combining a material containing the above metal element and a conductive material containing oxygen. In that case, the conductive material containing oxygen is preferably provided on the channel formation region side. When the conductive material containing oxygen is provided on the channel formation region side, oxygen released from the conductive material is easily supplied to the channel formation region.

It is particularly preferable to use, for the conductor functioning as the gate electrode, a conductive material containing oxygen and a metal element contained in the metal oxide where the channel is formed. A conductive material containing the above metal element and nitrogen may be used. For example, a conductive material containing nitrogen, such as titanium nitride or tantalum nitride, may be used. Indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon is added may be used. Indium gallium zinc oxide containing nitrogen may be used. With the use of such a material, hydrogen contained in the metal oxide where the channel is formed can be captured in some cases. Alternatively, hydrogen entering from an external insulator or the like can be captured in some cases.

At least part of this embodiment can be implemented in combination with any of the other embodiments described in this specification as appropriate.

The structures described in this embodiment can be used in an appropriate combination with any of the structures described in the other embodiments and the like.

### Embodiment 8

In this embodiment, a metal oxide (hereinafter also referred to as an oxide semiconductor) that can be used in an OS transistor described in the above embodiment is described.

<Classification of crystal structure>

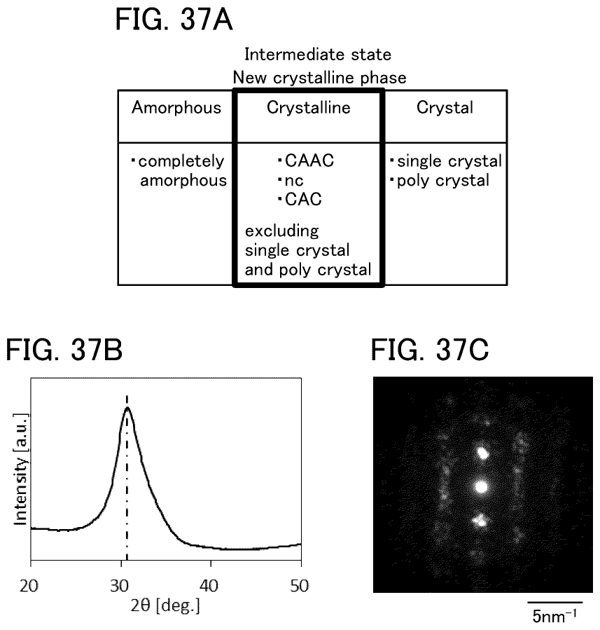

First, the classification of crystal structures of an oxide semiconductor is described with reference to FIG. 37A. FIG. 37A is a diagram showing classification of crystal structures of an oxide semiconductor, typically IGZO (a metal oxide containing In, Ga, and Zn).

As shown in FIG. 37A, an oxide semiconductor is roughly classified into “Amorphous”, “Crystalline”, and “Crystal”. “Amorphous” includes completely amorphous. The term “Crystalline” includes CAAC (c-axis-aligned crystalline), nc (nanocrystalline), and CAC (Cloud-Aligned Composite) (excluding single crystal and poly crystal). Note that in the classification of “Crystalline,” single crystal, poly crystal, and completely amorphous are excluded. The term “Crystal” includes single crystal and poly crystal.

Note that the structures in the thick frame in FIG. 37A are in an intermediate state between “Amorphous” and “Crystal”, and belong to a new crystalline phase. That is, these structures are completely different from “Crystal” and “Amorphous”, which is energetically unstable.

A crystal structure of a film or a substrate can be evaluated with an X-Ray Diffraction (XRD) spectrum. FIG. 37B shows an XRD spectrum, which is obtained using GIXD (Grazing-Incidence XRD) measurement, of a CAAC-IGZO film classified into “Crystalline”. Note that a GIXD method is also referred to as a thin film method or a Seemann-Bohlin method. The XRD spectrum that is shown in FIG. 37B and obtained by GIXD measurement is hereinafter simply referred to as an XRD spectrum. The CAAC-IGZO film in FIG. 37B has a composition in the vicinity of In:Ga:Zn=4:2:3 [atomic ratio]. The CAAC-IGZO film in FIG. 37B has a thickness of 500 nm.

As shown in FIG. 37B, a clear peak indicating crystallinity is detected in the XRD spectrum of the CAAC-IGZO film. Specifically, a peak indicating c-axis alignment is detected at 2θ of around 31° in the XRD spectrum of the CAAC-IGZO film. As shown in FIG. 37B, the peak at 2θ of around 31° is asymmetric with respect to the axis of the angle at which the peak intensity (Intensity) is detected.

A crystal structure of a film or a substrate can also be evaluated with a diffraction pattern obtained by a nanobeam electron diffraction (NBED) method (such a pattern is also referred to as a nanobeam electron diffraction pattern). FIG. 37C shows a diffraction pattern of a CAAC-IGZO film. FIG. 37C shows a diffraction pattern obtained with the NBED method in which an electron beam is incident in the direction parallel to the substrate. The CAAC-IGZO film in FIG. 37C has a composition in the vicinity of In:Ga:Zn=4:2:3 [atomic ratio]. In the nanobeam electron diffraction method, electron diffraction is performed with a probe diameter of 1 nm.

As shown in FIG. 37C, a plurality of spots indicating c-axis alignment are observed in the diffraction pattern of the CAAC-IGZO film.

### [Structure of Oxide Semiconductor]

Oxide semiconductors may be classified in a manner different from that in FIG. 37A when classified in terms of the crystal structure. Oxide semiconductors are classified into a single crystal oxide semiconductor and a non-single-crystal oxide semiconductor, for example. Examples of the non-single-crystal oxide semiconductor include the above-described CAAC-OS and nc-OS. Other examples of the non-single-crystal oxide semiconductor include a polycrystalline oxide semiconductor, an amorphous-like oxide semiconductor (a-like OS), and an amorphous oxide semiconductor.

Here, the CAAC-OS, the nc-OS, and the a-like OS will be described in detail.

### [CAAC-OS]

The CAAC-OS is an oxide semiconductor that has a plurality of crystal regions each of which has c-axis alignment in a particular direction. Note that the particular direction refers to the film thickness direction of a CAAC-OS film, the normal direction of the surface where the CAAC-OS film is formed, or the normal direction of the surface of the CAAC-OS film. The crystal region refers to a region having a periodic atomic arrangement. When an atomic arrangement is regarded as a lattice arrangement, the crystal region also refers to a region with a uniform lattice arrangement. The CAAC-OS has a region where a plurality of crystal regions are connected in the a-b plane direction, and the region has distortion in some cases. Note that the distortion refers to a portion where the direction of a lattice arrangement changes between a region with a uniform lattice arrangement and another region with a uniform lattice arrangement in a region where a plurality of crystal regions are connected. That is, the CAAC-OS is an oxide semiconductor having c-axis alignment and having no clear alignment in the a-b plane direction.

Note that each of the plurality of crystal regions is formed of one or more minute crystals (crystals each of which has a maximum diameter of less than 10 nm). In the case where the crystal region is formed of one minute crystal, the maximum diameter of the crystal region is less than 10 nm. In the case where the crystal region is formed of a large number of minute crystals, the size of the crystal region may be approximately several tens of nanometers.

In the case of an In-M-Zn oxide (the element M is one or more kinds selected from aluminum, gallium, yttrium, tin, titanium, and the like), the CAAC-OS tends to have a layered crystal structure (also referred to as a layered structure) in which a layer containing indium (In) and oxygen (hereinafter, an In layer) and a layer containing the element M, zinc (Zn), and oxygen (hereinafter, an (M,Zn) layer) are stacked. Indium and the element M can be replaced with each other. Therefore, indium may be contained in the (M,Zn) layer. In addition, the element M may be contained in the In layer. Note that Zn may be contained in the In layer. Such a layered structure is observed as a lattice image in a high-resolution TEM image, for example.

When the CAAC-OS film is subjected to structural analysis by out-of-plane XRD measurement with an XRD apparatus using θ/2θ scanning, for example, a peak indicating c-axis alignment is detected at 2θ of 31° or around 31°. Note that the position of the peak indicating c-axis alignment (the value of 20) may change depending on the kind, composition, or the like of the metal element contained in the CAAC-OS.

For example, a plurality of bright spots are observed in the electron diffraction pattern of the CAAC-OS film. Note that one spot and another spot are observed point-symmetrically with a spot of the incident electron beam passing through a sample (also referred to as a direct spot) as the symmetric center.

When the crystal region is observed from the particular direction, a lattice arrangement in the crystal region is basically a hexagonal lattice arrangement; however, a unit lattice is not always a regular hexagon and is a non-regular hexagon in some cases. A pentagonal lattice arrangement, a heptagonal lattice arrangement, and the like are included in the distortion in some cases. Note that a clear crystal grain boundary (grain boundary) cannot be observed even in the vicinity of the distortion in the CAAC-OS. That is, formation of a crystal grain boundary is inhibited by the distortion of lattice arrangement. This is probably because the CAAC-OS can tolerate distortion owing to a low density of arrangement of oxygen atoms in the a-b plane direction, an interatomic bond distance changed by substitution of a metal atom, and the like.

A crystal structure in which a clear crystal grain boundary is observed is what is called polycrystal. It is highly probable that the grain boundary becomes a recombination center and captures carriers and thus decreases the on-state current and field-effect mobility of a transistor, for example. Thus, the CAAC-OS in which no clear crystal grain boundary is observed is one of crystalline oxides having a crystal structure suitable for a semiconductor layer of a transistor. Note that Zn is preferably contained to form the CAAC-OS. For example, an In—Zn oxide and an In—Ga—Zn oxide are suitable because they can inhibit generation of a crystal grain boundary as compared with an In oxide.

The CAAC-OS is an oxide semiconductor with high crystallinity in which no clear crystal grain boundary is observed. Thus, in the CAAC-OS, reduction in electron mobility due to the crystal grain boundary is less likely to occur. Moreover, since the crystallinity of an oxide semiconductor might be decreased by entry of impurities, formation of defects, and/or the like, the CAAC-OS can be regarded as an oxide semiconductor that has small amounts of impurities and defects (e.g., oxygen vacancies). Thus, an oxide semiconductor including the CAAC-OS is physically stable. Therefore, the oxide semiconductor including the CAAC-OS is resistant to heat and has high reliability. In addition, the CAAC-OS is stable with respect to high temperatures in the manufacturing process (what is called thermal budget). Accordingly, the use of the CAAC-OS for the OS transistor can extend the degree of freedom of the manufacturing process.

[nc-OS]

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. In other words, the nc-OS includes a minute crystal. Note that the size of the minute crystal is, for example, greater than or equal to 1 nm and less than or equal to 10 nm, particularly greater than or equal to 1 nm and less than or equal to 3 nm; thus, the minute crystal is also referred to as a nanocrystal. Furthermore, there is no regularity of crystal orientation between different nanocrystals in the nc-OS. Thus, the orientation in the whole film is not observed. Accordingly, the nc-OS cannot be distinguished from an a-like OS or an amorphous oxide semiconductor by some analysis methods. For example, when an nc-OS film is subjected to structural analysis using out-of-plane XRD measurement with an XRD apparatus using θ/2θ scanning, a peak indicating crystallinity is not detected. Furthermore, a diffraction pattern like a halo pattern is observed when the nc-OS film is subjected to electron diffraction (also referred to as selected-area electron diffraction) using an electron beam with a probe diameter greater than the diameter of a nanocrystal (e.g., greater than or equal to 50 nm). Meanwhile, in some cases, a plurality of spots in a ring-like region with a direct spot as the center are observed in the obtained electron diffraction pattern when the nc-OS film is subjected to electron diffraction (also referred to as nanobeam electron diffraction) using an electron beam with a probe diameter nearly equal to or less than the diameter of a nanocrystal (e.g., greater than or equal to 1 nm and less than or equal to 30 nm).

[a-Like OS]

The a-like OS is an oxide semiconductor having a structure between those of the nc-OS and the amorphous oxide semiconductor. The a-like OS includes a void or a low-density region. That is, the a-like OS has lower crystallinity than the nc-OS and the CAAC-OS. Moreover, the a-like OS has higher hydrogen concentration in the film than the nc-OS and the CAAC-OS.

### [Structure of Oxide Semiconductor]

Next, the above-described CAC-OS is described in detail. Note that the CAC-OS relates to the material composition.

### [CAC-OS]

The CAC-OS refers to one composition of a material in which elements constituting a metal oxide are unevenly distributed with a size greater than or equal to 0.5 nm and less than or equal to 10 nm, preferably greater than or equal to 1 nm and less than or equal to 3 nm, or a similar size, for example. Note that a state in which one or more metal elements are unevenly distributed and regions including the metal elements are mixed with a size greater than or equal to 0.5 nm and less than or equal to 10 nm, preferably greater than or equal to 1 nm and less than or equal to 3 nm, or a similar size in a metal oxide is hereinafter referred to as a mosaic pattern or a patch-like pattern.

In addition, the CAC-OS has a composition in which materials are separated into a first region and a second region to form a mosaic pattern, and the first regions are distributed in the film (this composition is hereinafter also referred to as a cloud-like composition). That is, the CAC-OS is a composite metal oxide having a composition in which the first regions and the second regions are mixed.

Here, the atomic ratios of In, Ga, and Zn to the metal elements contained in the CAC-OS in an In—Ga—Zn oxide are denoted by [In], [Ga], and [Zn], respectively. For example, the first region in the CAC-OS in the In—Ga—Zn oxide has [In] higher than [In] in the composition of the CAC-OS film. Moreover, the second region has [Ga] higher than [Ga] in the composition of the CAC-OS film. For example, the first region has higher [In] than the second region and has lower [Ga] than the second region. Moreover, the second region has higher [Ga] than the first region and has lower [In] than the first region.

Specifically, the first region includes indium oxide, indium zinc oxide, or the like as its main component. The second region includes gallium oxide, gallium zinc oxide, or the like as its main component. That is, the first region can be referred to as a region containing In as its main component. The second region can be referred to as a region containing Ga as its main component.

Note that a clear boundary between the first region and the second region cannot be observed in some cases.

For example, energy dispersive X-ray spectroscopy (EDX) is used to obtain EDX mapping, and according to the EDX mapping, the CAC-OS in the In—Ga—Zn oxide has a structure in which the region containing In as its main component (the first region) and the region containing Ga as its main component (the second region) are unevenly distributed and mixed.

In the case where the CAC-OS is used for a transistor, a switching function (on/off switching function) can be given to the CAC-OS owing to the complementary action of the conductivity derived from the first region and the insulating property derived from the second region. That is, the CAC-OS has a conducting function in part of the material and has an insulating function in another part of the material; as a whole, the CAC-OS has a function of a semiconductor. Separation of the conducting function and the insulating function can maximize each function. Accordingly, when the CAC-OS is used for a transistor, high on-state current (Iₒₙ), high field-effect mobility (μ), and excellent switching operation can be achieved.

An oxide semiconductor has various structures with different properties. Two or more kinds of the amorphous oxide semiconductor, the polycrystalline oxide semiconductor, the a-like OS, the CAC-OS, the nc-OS, and the CAAC-OS may be included in the oxide semiconductor of one embodiment of the present invention.

### <Transistor Including Oxide Semiconductor>

Next, the case where the above oxide semiconductor is used for a transistor is described.

When the above oxide semiconductor is used for a transistor, a transistor with high field-effect mobility can be achieved. In addition, a transistor having high reliability can be achieved.

An oxide semiconductor with a low carrier concentration is preferably used for a transistor. For example, the carrier concentration of an oxide semiconductor is lower than or equal to 1×10¹⁷ cm⁻³, preferably lower than or equal to 1×10¹⁵ cm⁻³, further preferably lower than or equal to 1×10¹³ cm⁻³, still further preferably lower than or equal to 1×10¹¹ cm⁻³, yet further preferably lower than 1×10¹⁰ cm⁻³, and higher than or equal to 1×10⁻⁹ cm⁻³. In order to reduce the carrier concentration in an oxide semiconductor, the impurity concentration in the oxide semiconductor is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor has a low density of defect states and accordingly has a low density of trap states in some cases.

Electric charge trapped by the trap states in the oxide semiconductor takes a long time to disappear and might behave like fixed electric charge. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in a proximate film be also reduced. Examples of impurities include hydrogen, nitrogen, an alkali metal, an alkaline earth metal, iron, nickel, and silicon.

### <Impurities>

Here, the influence of each impurity in the oxide semiconductor is described.

When silicon and/or carbon, which are each one of Group 14 elements, is contained in the oxide semiconductor, defect states are formed in the oxide semiconductor. Thus, the concentration of silicon and carbon in the oxide semiconductor and the concentration of silicon and carbon in the vicinity of an interface with the oxide semiconductor (the concentrations obtained by SIMS) are each set lower than or equal to 2×10¹⁸ atoms/cm³, preferably lower than or equal to 2×10¹⁷ atoms/cm³.

When the oxide semiconductor contains an alkali metal or an alkaline earth metal, defect states are formed and carriers are generated in some cases. Accordingly, a transistor including an oxide semiconductor that contains an alkali metal or an alkaline earth metal tends to have normally-on characteristics. Thus, the concentration of an alkali metal or an alkaline earth metal in the oxide semiconductor, which is obtained by SIMS, is set lower than or equal to 1×10¹⁸ atoms/cm³, preferably lower than or equal to 2×10¹⁶ atoms/cm³.

Furthermore, when the oxide semiconductor contains nitrogen, the oxide semiconductor easily becomes n-type by generation of electrons serving as carriers and an increase in carrier concentration. As a result, a transistor including an oxide semiconductor containing nitrogen as a semiconductor is likely to have normally-on characteristics. When nitrogen is contained in the oxide semiconductor, a trap state is sometimes formed. This might make the electrical characteristics of the transistor unstable. Therefore, the concentration of nitrogen in the oxide semiconductor, which is obtained using SIMS, is set lower than 5×10¹⁹ atoms/cm³, preferably lower than or equal to 5×10¹⁸ atoms/cm³, further preferably lower than or equal to 1×10¹⁸ atoms/cm³, still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding between part of hydrogen and oxygen bonded to a metal atom causes generation of an electron serving as a carrier in some cases. Thus, a transistor using an oxide semiconductor containing hydrogen is likely to have normally-on characteristics. Accordingly, hydrogen in the oxide semiconductor is preferably reduced as much as possible. Specifically, the hydrogen concentration in the oxide semiconductor, which is obtained using SIMS, is set lower than 1×10²⁰ atoms/cm³, preferably lower than 1×10¹⁹ atoms/cm³, further preferably lower than 5×10¹⁸ atoms/cm³, still further preferably lower than 1×10¹⁸ atoms/cm³.

When an oxide semiconductor with sufficiently reduced impurities is used for the channel formation region of the transistor, stable electrical characteristics can be given.

The structures described in this embodiment can be used in an appropriate combination with any of the structures described in the other embodiments and the like.

### Embodiment 9

In this embodiment, electronic apparatuses that can include the semiconductor device of one embodiment of the present invention are described.

The semiconductor device of one embodiment of the present invention can be used for a display unit of an electronic apparatus. Therefore, an electronic apparatus having high display quality can be obtained. Alternatively, an electronic apparatus with extremely high resolution can be obtained. Alternatively, a highly reliable electronic apparatus can be obtained.

Examples of the electronic apparatuses including any of the semiconductor devices of one embodiment of the present invention are as follows: display apparatuses such as televisions and monitors, lighting devices, desktop personal computers, notebook personal computers, word processors, image reproduction devices which reproduce still images and moving images stored in recording media such as DVDs (Digital Versatile Discs), portable CD players, radios, tape recorders, headphone stereos, stereos, table clocks, wall clocks, cordless phone handsets, transceivers, car phones, mobile phones, portable information terminals, tablet terminals, portable game machines, stationary game machines such as pachinko machines, calculators, electronic notebooks, e-book readers, electronic translators, audio input devices, video cameras, digital still cameras, electric shavers, high-frequency heating appliances such as microwave ovens, electric rice cookers, electric washing machines, electric vacuum cleaners, water heaters, electric fans, hair dryers, air-conditioning systems such as air conditioners, humidifiers, and dehumidifiers, dishwashers, dish dryers, clothes dryers, futon dryers, electric refrigerators, electric freezers, electric refrigerator-freezers, freezers for preserving DNA, flashlights, electrical tools such as chain saws, smoke detectors, and medical equipment such as dialyzers. Further examples include the following industrial equipment: guide lights, traffic lights, belt conveyors, elevators, escalators, industrial robots, power storage systems, and power storage devices for leveling the amount of power supply and smart grid. In addition, moving objects and the like driven by fuel engines and electric motors using power from power storage units, and the like may also be included in the range of electronic apparatuses. Examples of the moving objects include electric vehicles (EV), hybrid electric vehicles (HV) which include both an internal-combustion engine and a motor, plug-in hybrid electric vehicles (PHV), tracked vehicles in which caterpillar tracks are substituted for wheels of these vehicles, motorized bicycles including motor-assisted bicycles, motorcycles, electric wheelchairs, golf carts, boats, ships, submarines, helicopters, aircraft, rockets, artificial satellites, space probes, planetary probes, and spacecraft.

The electronic apparatus of one embodiment of the present invention may include a secondary battery. It is preferable that the secondary battery be capable of being charged by non-contact power transmission.

Examples of the secondary battery include a lithium ion secondary battery, a nickel-hydride battery, a nickel-cadmium battery, an organic radical battery, a lead-acid battery, an air secondary battery, a nickel-zinc battery, and a silver-zinc battery.

The electronic apparatus of one embodiment of the present invention may include an antenna. With the antenna receiving a signal, the electronic apparatus can display a video, information, and the like on a display unit. When the electronic apparatus includes an antenna and a secondary battery, the antenna may be used for contactless power transmission.

The electronic apparatus of one embodiment of the present invention may include a sensor (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic apparatus of one embodiment of the present invention can have a variety of functions. For example, the electronic apparatus of one embodiment of the present invention can have a function of displaying a variety of data (a still image, a moving image, a text image, and the like) on the display unit, a touch panel function, a function of displaying a calendar, date, time, and the like, a function of executing a variety of software (programs), a wireless communication function, and a function of reading out a program or data stored in a recording medium.

Furthermore, the electronic apparatus including a plurality of display units can have a function of displaying image data mainly on one display unit while displaying text data mainly on another display unit, a function of displaying a three-dimensional image by displaying images on a plurality of display units with a parallax taken into account, or the like. Furthermore, the electronic apparatus including an image receiving unit can have a function of photographing a still image or a moving image, a function of automatically or manually correcting a photographed image, a function of storing a photographed image in a recording medium (an external recording medium or a recording medium incorporated in the electronic apparatus), a function of displaying a photographed image on a display unit, or the like. Note that the functions of the electronic apparatuses of embodiments of the present invention are not limited to these, and the electronic apparatuses can have a variety of functions. The semiconductor device of one embodiment of the present invention can display a high-resolution image. For this reason, the display apparatus can be used particularly for portable electronic apparatuses, wearable electronic apparatuses, e-book readers, and the like. For example, the display apparatus can be suitably used for xR devices such as a VR device, an AR device, and the like.

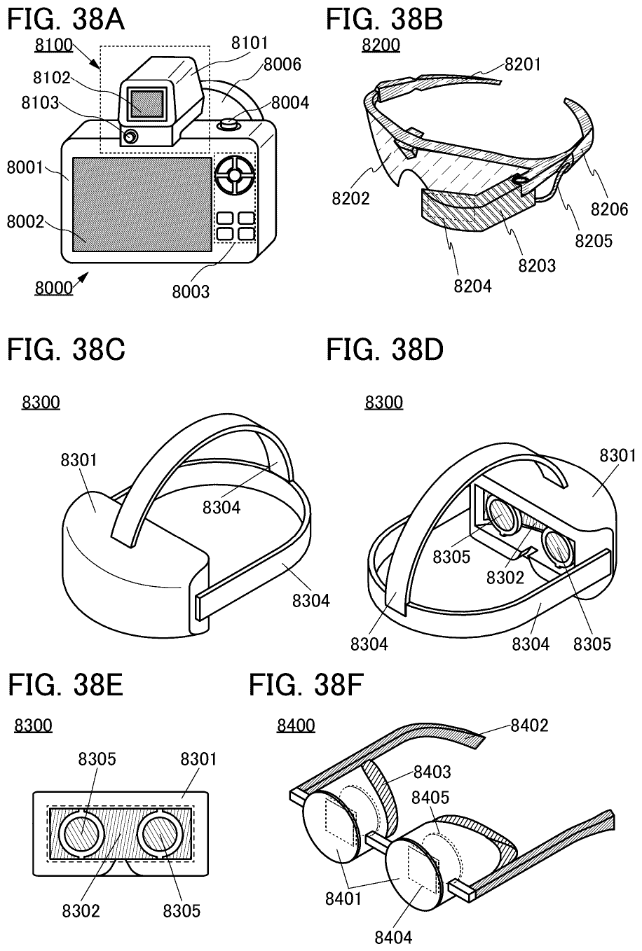

FIG. 38A is an external view of a camera 8000 to which a finder 8100 is attached.

The camera 8000 includes a housing 8001, a display unit 8002, operation buttons 8003, a shutter button 8004, and the like. Furthermore, a detachable lens 8006 is attached to the camera 8000. Note that the lens 8006 and the housing may be integrated with each other in the camera 8000.

Images can be taken with the camera 8000 at the press of the shutter button 8004 or the touch of the display unit 8002 serving as a touch panel.

The housing 8001 includes a mount including an electrode, so that the finder 8100, a stroboscope, or the like can be connected to the housing.

The finder 8100 includes a housing 8101, a display unit 8102, a button 8103, and the like.

The housing 8101 is attached to the camera 8000 by a mount for engagement with the mount of the camera 8000. The finder 8100 can display a video received from the camera 8000 and the like on the display unit 8102.

The button 8103 functions as a power supply button or the like.

The semiconductor device of one embodiment of the present invention can be used in the display unit 8002 of the camera 8000 and the display unit 8102 of the finder 8100. Note that the finder 8100 may be incorporated in the camera 8000.

FIG. 38B is an external view of a head-mounted display 8200.

The head-mounted display 8200 includes a mounting unit 8201, a lens 8202, a main body 8203, a display unit 8204, a cable 8205, and the like. A battery 8206 is incorporated in the mounting unit 8201. Note that the battery 8206 can be an external battery instead of being incorporated in the head-mounted display 8200.

The cable 8205 supplies electric power from the battery 8206 to the main body 8203. The main body 8203 includes a wireless receiver or the like to receive video data and display it on the display unit 8204. The main body 8203 includes a camera, and information on the movement of the eyeballs or the eyelids of the user obtained through the lens 8202 can be used as an input means. Note that the semiconductor device of one embodiment of the present invention can be applied to the above camera. That is, one embodiment of the present invention is an electronic apparatus that includes at least one of a mounting unit, a lens, a body, and a cable and has a function of obtaining user information through the lens 8202.

The mounting unit 8201 may include a plurality of electrodes capable of sensing current flowing accompanying with the movement of the user's eyeball at a position in contact with the user to recognize the user's sight line. The mounting unit 8201 may also have a function of monitoring the user's pulse with the use of current flowing in the electrodes. The mounting unit 8201 may include sensors such as a temperature sensor, a pressure sensor, and an acceleration sensor so that the user's biological information can be displayed on the display unit 8204 and a video displayed on the display unit 8204 can be changed in accordance with the movement of the user's head.

The semiconductor device of one embodiment of the present invention can be used in the display unit 8204.

FIG. 38C to FIG. 38E are external views of a head-mounted display 8300. The head-mounted display 8300 includes the housing 8301, the display unit 8302, the band-like fixing member 8304, and a pair of lenses 8305.

A user can see display on the display unit 8302 through the lenses 8305. The display unit 8302 is preferably curved because the user can feel high realistic sensation. Another image displayed in another region of the display unit 8302 is viewed through the lenses 8305, so that three-dimensional display using parallax or the like can be performed. Note that the number of the display unit 8302 is not limited to one; two display units 8302 may be provided for user's respective eyes.

The semiconductor device of one embodiment of the present invention can be used for the display unit 8302. The semiconductor device of one embodiment of the present invention achieves extremely high resolution. For example, a pixel is not easily seen by the user even when the user sees display that is magnified by the use of the lenses 8305 as illustrated in FIG. 38E. In other words, a video with a strong sense of reality can be seen by the user with the use of the display unit 8302.

FIG. 38F is an external view of a goggle-type head-mounted display 8400. The head-mounted display 8400 includes a pair of housings 8401, a mounting unit 8402, and a cushion 8403. A display unit 8404 and a lens 8405 are provided in each of the pair of housings 8401. Furthermore, when the pair of display units 8404 display different images, three-dimensional display using parallax can be performed.

A user can see display on the display unit 8404 through the lens 8405. The lens 8405 has a focus adjustment mechanism and can adjust the position according to the user's eyesight. The display unit 8404 is preferably a square or a horizontal rectangle. This can improve a realistic sensation.

The mounting unit 8402 preferably has flexibility and elasticity so as to be adjusted to fit the size of the user's face and not to slide down. In addition, part of the mounting unit 8402 preferably has a vibration mechanism functioning as a bone conduction earphone. Thus, audio devices such as an earphone and a speaker are not necessarily provided separately, and the user can enjoy videos and sounds only when wearing the head-mounted display 8400. Note that the housing 8401 may have a function of outputting sound data by wireless communication.

The mounting unit 8402 and the cushion 8403 are units in contact with the user's face (forehead, cheek, or the like). The cushion 8403 is in close contact with the user's face, so that light leakage can be prevented, which increases the sense of immersion. The cushion 8403 is preferably formed using a soft material so that the head-mounted display 8400 is in close contact with the user's face when being worn by the user. For example, a material such as rubber, silicone rubber, urethane, or sponge can be used. Furthermore, when a sponge or the like whose surface is covered with cloth, leather (natural leather or synthetic leather), or the like is used, a gap is unlikely to be generated between the user's face and the cushion 8403, whereby light leakage can be suitably prevented. Furthermore, using such a material is preferable because it has a soft texture and the user does not feel cold when wearing the device in a cold season, for example. The member in contact with user's skin, such as the cushion 8403 or the mounting unit 8402, is preferably detachable because cleaning or replacement can be easily performed.

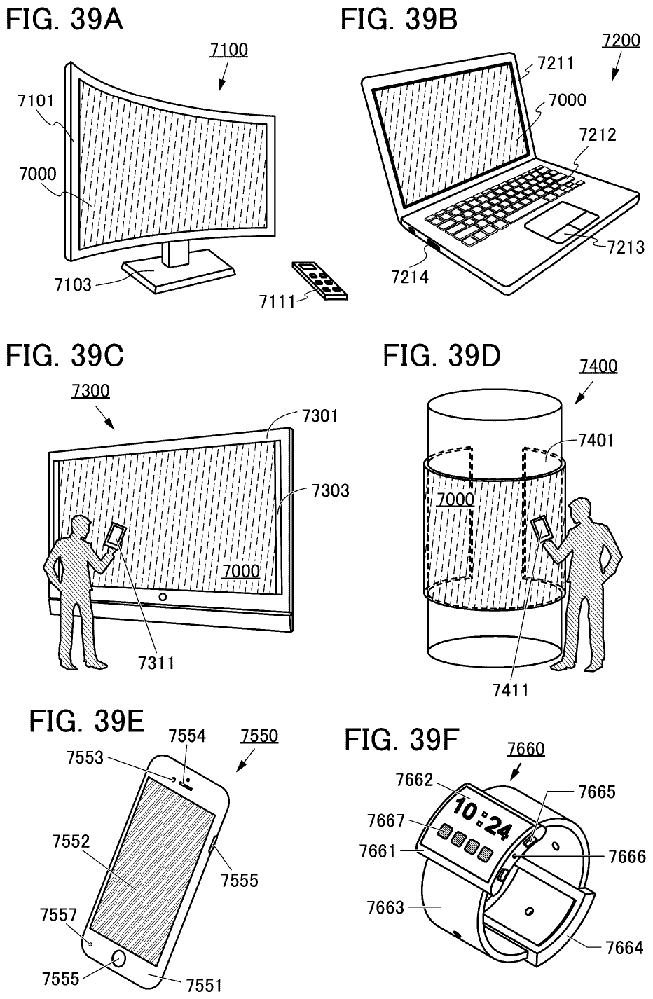

FIG. 39A illustrates an example of a television device. In a television device 7100, a display unit 7000 is incorporated in a housing 7101. Here, the housing 7101 is supported by a stand 7103.

The semiconductor device of one embodiment of the present invention can be used for the display unit 7000.

Operation of the television device 7100 illustrated in FIG. 39A can be performed with an operation switch provided in the housing 7101 and a separate remote controller 7111. Alternatively, the display unit 7000 may include a touch sensor, and the television device 7100 may be operated by touch on the display unit 7000 with a finger or the like. The remote controller 7111 may be provided with a display unit for displaying information output from the remote controller 7111. With operation keys or a touch panel provided in the remote controller 7111, channels and volume can be operated and videos displayed on the display unit 7000 can be operated.

Note that the television device 7100 has a structure in which a receiver, a modem, and the like are provided. A general television broadcast can be received with the receiver. When the television device is connected to a communication network with or without wires via the modem, one-way (from a transmitter to a receiver) or two-way (between a transmitter and a receiver or between receivers, for example) data communication can be performed.

FIG. 39B illustrates an example of a notebook personal computer. The notebook personal computer 7200 includes a housing 7211, a keyboard 7212, a pointing device 7213, an external connection port 7214, and the like. In the housing 7211, the display unit 7000 is incorporated.

The semiconductor device of one embodiment of the present invention can be used for the display unit 7000.

FIG. 39C and FIG. 39D illustrate examples of digital signage.

A digital signage 7300 illustrated in FIG. 39C includes a housing 7301, the display unit 7000, a speaker 7303, and the like. The digital signage 7300 can also include an LED lamp, an operation key (including a power switch or an operation switch), a connection terminal, a variety of sensors, a microphone, and the like.

FIG. 39D illustrates a digital signage 7400 mounted on a cylindrical pillar 7401. The digital signage 7400 includes the display unit 7000 provided along a curved surface of the pillar 7401.

In FIG. 39C and FIG. 39D, the semiconductor device of one embodiment of the present invention can be used for the display unit 7000.

A larger area of the display unit 7000 can increase the amount of data that can be provided at a time. The larger display unit 7000 attracts more attention, so that the effectiveness of the advertisement can be increased, for example.

The use of a touch panel in the display unit 7000 is preferable because in addition to display of a still image or a moving image on the display unit 7000, intuitive operation by a user is possible. Moreover, for an application for providing information such as route information or traffic information, usability can be enhanced by intuitive operation.

As illustrated in FIG. 39C and FIG. 39D, it is preferable that the digital signage 7300 or the digital signage 7400 can work with an information terminal 7311 or an information terminal 7411 such as a smartphone a user has through wireless communication. For example, information of an advertisement displayed on the display unit 7000 can be displayed on a screen of the information terminal 7311 or the information terminal 7411. By operation of the information terminal 7311 or the information terminal 7411, display on the display unit 7000 can be switched.

It is possible to make the digital signage 7300 or the digital signage 7400 execute a game with the use of the screen of the information terminal 7311 or the information terminal 7411 as an operation means (controller). Thus, an unspecified number of users can join in and enjoy the game concurrently.

An information terminal 7550 illustrated in FIG. 39E includes a housing 7551, a display unit 7552, a microphone 7557, a speaker unit 7554, a camera 7553, an operation switch 7555, and the like. The semiconductor device of one embodiment of the present invention can be used for the display unit 7552. The display unit 7552 has a function of a touch panel. In addition, the information terminal 7550 includes an antenna, a battery, and the like inside the housing 7551. The information terminal 7550 can be used as, for example, a smartphone, a mobile phone, a tablet information terminal, a tablet personal computer, or an e-book reader.

FIG. 39F illustrates an example of a watch-type information terminal. An information terminal 7660 includes a housing 7661, a display unit 7662, a band 7663, a buckle 7664, an operation switch 7665, an input/output terminal 7666, and the like. In addition, the information terminal 7660 includes an antenna, a battery, and the like inside the housing 7661. The information terminal 7660 is capable of executing a variety of applications such as mobile phone calls, e-mailing, text viewing and editing, music reproduction, Internet communication, and computer games.

The display unit 7662 includes a touch sensor, and operation can be performed by touching the screen with a finger, a stylus, or the like. For example, by touching an icon 7667 displayed on the display unit 7662, application can be started. With the operation switch 7665, a variety of functions such as time setting, power on/off, on/off of wireless communication, setting and cancellation of a silent mode, and setting and cancellation of a power saving mode can be performed. For example, the functions of the operation switch 7665 can be set by setting the operating system incorporated in the information terminal 7660.

The information terminal 7660 can employ near field communication that is a communication method based on an existing communication standard. In that case, for example, mutual communication between the information terminal 7660 and a headset capable of wireless communication can be performed, and thus hands-free calling is possible. The information terminal 7660 includes the input/output terminal 7666, and can transmit and receive data to/from another information terminal through the input/output terminal 7666. Power charging through the input/output terminal 7666 is also possible. The charging operation may be performed by wireless power feeding without using the input/output terminal 7666.

The structures described in this embodiment can be used in combination with any of the structures described in the other embodiments and the like as appropriate.

10: layer, 11: imaging unit, 12: imaging pixel, 13: driver circuit unit, 14: driver circuit unit, 15: circuit unit, 16: control circuit unit, 17: DSP circuit unit, 18: memory circuit unit, 19: microlens, 20: layer, 21: display unit, 23: CPU, 24: GPU, 25: storage circuit unit, 29: input/output terminal unit, 30: layer, 40: sealing substrate, 60: layer, 61: light-emitting element

1. A semiconductor device comprising:
an imaging unit; and
a display unit,
wherein the imaging unit comprises a plurality of photoelectric conversion elements arranged in a matrix,
wherein the display unit comprises a plurality of display pixel circuits arranged in a matrix and a plurality of display elements arranged in a matrix,
wherein the plurality of photoelectric conversion elements are provided in a first layer,
wherein the plurality of display pixel circuits are provided in a second layer over the first layer,
wherein the plurality of display elements are provided in a third layer over the second layer, and
wherein one of the plurality of display pixel circuits is electrically connected to one of the plurality of display elements.

2. The semiconductor device according to claim 1,
wherein the semiconductor device is configured to obtain imaging data using the plurality of photoelectric conversion elements, and
wherein the semiconductor device is configured to supply the imaging data of all columns to the display unit row by row.

3. The semiconductor device according to claim 2,
wherein the semiconductor device is configured to adjust a voltage of the imaging data and supplying the imaging data to the display unit.

4. The semiconductor device according to claim 1,
wherein the display pixel circuit is configured to control emission luminance of the display element.

5. The semiconductor device according to claim 1,
wherein the display element is an organic EL element.

6. The semiconductor device according to claim 1,
wherein the display pixel circuit comprises a transistor comprising an oxide semiconductor.

7. The semiconductor device according to claim 1,
wherein the first layer and the second layer are connected to each other by an adhesive layer and a bump.

8. An electronic apparatus comprising:
the semiconductor device according to claim 1, and
at least one of an antenna, a battery, and a microphone.

9. An electronic apparatus comprising:
the semiconductor device according to claim 1, and
at least one of a mounting unit, a lens, a main body, and a cable,
wherein the electronic apparatus is configured to obtain user information through the lens.
